(19) United States
(12) Patent Application Publication
(10) Pub. No.: US 2017/0062659 A1
(43) Pub. Date: Mar. 2, 2017

(54) LIGHT-EMITTING DEVICE HAVING PHOTOLUMINESCENT LAYER

(71) Applicant: Panasonic Intellectual Property Management Co., Ltd., Osaka (JP)

(72) Inventors: YASUHISA INADA, Osaka (JP); TAKU HIRASAWA, Kyoto (JP)

(21) Appl. No.: 15/219,462

(22) Filed: Jul. 26, 2016

(30) Foreign Application Priority Data
Aug. 27, 2015 (JP) 2015-167926
Aug. 27, 2015 (JP) 2015-167927
Feb. 15, 2016 (JP) 2016-025893

(51) Int. Cl. H01L 33/24; H01L 33/50; H01L 33/58

(52) U.S. Cl. CPC H01L 33/24; H01L 33/58; H01L 33/502

(57) ABSTRACT

A light-emitting device includes: a light-transmissive layer having a first surface; and a photoluminescent layer located on the first surface. The photoluminescent layer has a second surface facing the light-transmissive layer and a third surface opposite the second surface, and emits light containing first light having a wavelength X, in air from the third surface. The photoluminescent layer has a first surface structure located on the third surface, the first surface structure having an array of projections. The light-transmissive layer has a second surface structure located on the first surface, the second surface structure having projections corresponding to the projections of the first surface structure. The first surface structure and the second surface structure limit a directional angle of the first light emitted from the third surface. The projections of the first surface structure include a first projection, and the first projection has a base width greater than a top width.

### BACKGROUND

1. Technical Field

The present disclosure relates to a light-emitting device and more particularly to a light-emitting device having a photoluminescent layer.

2. Description of the Related Art

Optical devices, such as lighting fixtures, displays, and projectors, that emit light in a necessary direction are required for many applications. Photoluminescent materials, such as those used for fluorescent lamps and white light-emitting diodes (LEDs), emit light in all directions. Thus, those materials are used in combination with an optical element, such as a reflector or lens, to emit light only in a particular direction. For example, Japanese Unexamined Patent Application Publication No. 2010-231941 discloses a lighting system including a light distributor and an auxiliary reflector to provide sufficient directionality.

### SUMMARY

In one general aspect, the techniques disclosed here feature a light-emitting device that includes a light-transmissive layer having a first surface and a photoluminescent layer located on the first surface. The photoluminescent layer has a second surface facing the light-transmissive layer and a third surface opposite the second surface. The photoluminescent layer emits light containing first light having a wavelength λₐ in air from the third surface upon receiving excitation light. The photoluminescent layer has a first surface structure located on the third surface. The first surface structure has an array of projections. The light-transmissive layer has a second surface structure located on the first surface. The second surface structure has projections corresponding to the projections of the first surface structure. The first surface structure and the second surface structure limit a directional angle of the first light emitted from the third surface. The projections of the first surface structure include a first projection. The first projection has a base width greater than a top width in a cross-section perpendicular to the photoluminescent layer and parallel to an array direction of the projections of the first surface structure.

An embodiment of the present disclosure can provide a light-emitting device having a novel structure that utilizes a photoluminescent material.

It should be noted that general or specific embodiments may be implemented as a device, an apparatus, a system, a method, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a perspective view of the structure of a light-emitting device according to an embodiment;

FIG. 1B is a fragmentary cross-sectional view of the light-emitting device illustrated in FIG. 1A;

FIG. 1C is a perspective view of the structure of a light-emitting device according to another embodiment;

FIG. 1D is a fragmentary cross-sectional view of the light-emitting device illustrated in FIG. 1C;

FIG. 2 is a graph showing the calculation results of enhancement of light emitted in the front direction with varying emission wavelengths and varying a period of a periodic structure;

FIG. 3 is a graph illustrating the conditions for m=1 and m=3 in the formula (10);

FIG. 4 is a graph showing the calculation results of enhancement of light emitted in the front direction with varying emission wavelengths and varying thicknesses t of a photoluminescent layer;

FIG. 5A is a graph showing the calculation results of the electric field distribution of a mode to guide light in the x direction for a thickness t of 238 nm;

FIG. 5B is a graph showing the calculation results of the electric field distribution of a mode to guide light in the x direction for a thickness t of 539 nm;

FIG. 5C is a graph showing the calculation results of the electric field distribution of a mode to guide light in the x direction for a thickness t of 300 nm;

FIG. 6 is a graph showing the calculation results of enhancement of light under the same conditions as in FIG. 2 except that the polarization of light is in the TE mode, which has an electric field component perpendicular to the y direction;

FIG. 7A is a plan view of a two-dimensional periodic structure;

FIG. 7B is a graph showing the results of calculations performed as in FIG. 2 for the two-dimensional periodic structure;

FIG. 8 is a graph showing the calculation results of enhancement of light emitted in the front direction with varying emission wavelengths and varying refractive indices of the periodic structure;

FIG. 9 is a graph showing the results obtained under the same conditions as in FIG. 8 except that the photoluminescent layer has a thickness of 1,000 nm;

FIG. 10 is a graph showing the calculation results of enhancement of light emitted in the front direction with varying emission wavelengths and varying heights of the periodic structure;

FIG. 11 is a graph showing the results of calculations performed under the same conditions as in FIG. 10 except that the periodic structure has a refractive index nₚ of 2.0;

FIG. 12 is a graph showing the results of calculations performed under the same conditions as in FIG. 9 except that the polarization of the light is in the TE mode, which has an electric field component perpendicular to the y direction;

FIG. 13 is a graph showing the results of calculations performed under the same conditions as in FIG. 9 except that the photoluminescent layer has a refractive index n_{wav} of 1.5;

FIG. 14 is a graph showing the results of calculations performed under the same conditions as in FIG. 2 except that the photoluminescent layer and the periodic structure are located on a transparent substrate having a refractive index of 1.5;

FIG. 15 is a graph illustrating the condition represented by the formula (15); FIG. 16 is a schematic view of a light-emitting apparatus including a light-emitting device illustrated in FIGS. 1A and 1B and a light source that emits excitation light toward a photoluminescent layer;

FIG. 17A is a schematic view of a one-dimensional periodic structure having a period in the x direction;

FIG. 17B is a schematic view of a two-dimensional periodic structure having a period in the x direction and a period in the y direction;

FIG. 17C is a graph showing the wavelength dependence of light absorptivity in the structure illustrated in FIG. 17A;

FIG. 17D is a graph showing the wavelength dependence of light absorptivity in the structure illustrated in FIG. 17B;

FIG. 18A is a schematic view of a two-dimensional periodic structure;

FIG. 18B is a schematic view of another two-dimensional periodic structure;

FIG. 19A is a schematic view of a modified example in which a periodic structure is formed on a transparent substrate;

FIG. 19B is a schematic view of another modified example in which a periodic structure is formed on a transparent substrate;

FIG. 19C is a graph showing the calculation results of enhancement of light emitted from the structure illustrated in FIG. 19A in the front direction with varying emission wavelengths and varying periods of the periodic structure;

FIG. 20 is a schematic view of a mixture of light-emitting devices in powder form;

FIG. 21 is a plan view of a two-dimensional array of periodic structures having different periods on a photoluminescent layer;

FIG. 22 is a schematic view of a light-emitting device including photoluminescent layers each having a textured surface;

FIG. 23 is a cross-sectional view of a structure including a protective layer between a photoluminescent layer and a periodic structure;

FIG. 24 is a cross-sectional view of a structure including a periodic structure formed by processing only a portion of a photoluminescent layer;

FIG. 25 is a cross-sectional transmission electron microscopy (TEM) image of a photoluminescent layer formed on a glass substrate having a periodic structure;

FIG. 26 is a graph showing the measurement results of the spectrum of light emitted from a sample light-emitting device in the front direction;

FIG. 27A is a schematic view of a light-emitting device that can emit linearly polarized light in the TM mode, rotated about an axis parallel to the line direction of the one-dimensional periodic structure;

FIG. 27B is a graph showing the measurement results of the angular dependence of light emitted from the sample light-emitting device rotated as illustrated in FIG. 27A;

FIG. 27C is a graph showing the calculation results of the angular dependence of light emitted from the sample light-emitting device rotated as illustrated in FIG. 27A;

FIG. 27D is a schematic view of a light-emitting device that can emit linearly polarized light in the TE mode, rotated about an axis parallel to the line direction of the one-dimensional periodic structure;

FIG. 27E is a graph showing the measurement results of the angular dependence of light emitted from the sample light-emitting device rotated as illustrated in FIG. 27D;

FIG. 27F is a graph showing the calculation results of the angular dependence of light emitted from the sample light-emitting device rotated as illustrated in FIG. 27D;

FIG. 28A is a schematic view of a light-emitting device that can emit linearly polarized light in the TE mode, rotated about an axis perpendicular to the line direction of the one-dimensional periodic structure;

FIG. 28B is a graph showing the measurement results of the angular dependence of light emitted from the sample light-emitting device rotated as illustrated in FIG. 28A;

FIG. 28C is a graph showing the calculation results of the angular dependence of light emitted from the sample light-emitting device rotated as illustrated in FIG. 28A;

FIG. 28D is a schematic view of a light-emitting device that can emit linearly polarized light in the TM mode, rotated about an axis parallel to the line direction of the one-dimensional periodic structure;

FIG. 28E is a graph showing the measurement results of the angular dependence of light emitted from the sample light-emitting device rotated as illustrated in FIG. 28D;

FIG. 28F is a graph showing the calculation results of the angular dependence of light emitted from the sample light-emitting device rotated as illustrated in FIG. 28D;

FIG. 29 is a graph showing the measurement results of the angular dependence of light (wavelength: 610 nm) emitted from a sample light-emitting device;

FIG. 30 is a schematic perspective view of a slab waveguide;

FIG. 31 is a schematic view illustrating the relationship between the wavelength and output direction of light under the emission enhancement effect in a light-emitting device having a periodic structure on a photoluminescent layer;

FIG. 32A is a schematic plan view of an example structure of an array of periodic structures having different wavelengths at which the light enhancement effect is produced;

FIG. 32B is a schematic plan view of an example structure that includes an array of one-dimensional periodic structures having projections extending in different directions;

FIG. 32C is a schematic plan view of an example structure that includes an array of two-dimensional periodic structures;

FIG. 33 is a schematic cross-sectional view of a light-emitting device including microlenses;

FIG. 34A is a schematic cross-sectional view of a light-emitting device that includes photoluminescent layers having different emission wavelengths;

FIG. 34B is a schematic cross-sectional view of another light-emitting device that includes photoluminescent layers having different emission wavelengths;

FIG. 35A is a schematic cross-sectional view of a light-emitting device that includes a diffusion-barrier layer (barrier layer) under a photoluminescent layer;

FIG. 35B is a schematic cross-sectional view of a light-emitting device that includes a diffusion-barrier layer (barrier layer) under a photoluminescent layer;

FIG. 35C is a schematic cross-sectional view of a light-emitting device that includes a diffusion-barrier layer (barrier layer) under a photoluminescent layer;

FIG. 35D is a schematic cross-sectional view of a light-emitting device that includes a diffusion-barrier layer (barrier layer) under a photoluminescent layer;

FIG. 36A is a schematic cross-sectional view of a light-emitting device that includes a crystal growth layer (seed layer) under a photoluminescent layer;

FIG. 36B is a schematic cross-sectional view of a light-emitting device that includes a crystal growth layer (seed layer) under a photoluminescent layer;

FIG. 36C is a schematic cross-sectional view of a light-emitting device that includes a crystal growth layer (seed layer) under a photoluminescent layer;

FIG. 37A is a schematic cross-sectional view of a light-emitting device that includes a surface protective layer for protecting a periodic structure;

FIG. 37B is a schematic cross-sectional view of a light-emitting device that includes a surface protective layer for protecting a periodic structure;

FIG. 38A is a schematic cross-sectional view of a light-emitting device that includes a transparent thermally conductive layer;

FIG. 38B is a schematic cross-sectional view of a light-emitting device that includes a transparent thermally conductive layer;

FIG. 38C is a schematic cross-sectional view of a light-emitting device that includes a transparent thermally conductive layer;

FIG. 38D is a schematic cross-sectional view of a light-emitting device that includes a transparent thermally conductive layer;

FIG. 39 is a graph showing the calculation results of a trigonometric series including only a first-order term (a sine wave) or including up to third-, fifth-, or 11th-order terms;

FIG. 40 is a schematic cross-sectional view of a periodic structure including projections having a rectangular cross-section;

FIG. 41A is a schematic cross-sectional view of a periodic structure including projections having a triangular cross-section;

FIG. 41B is a schematic cross-sectional view of a periodic structure having a sine wave cross-section;

FIG. 42 is a schematic cross-sectional view of a light-emitting device according to another embodiment of the present disclosure;

FIG. 43 is a schematic view of part of a vertical cross-section of a periodic structure having projections;

FIG. 44 is a graph showing the calculation results of enhancement of light emitted in the front direction for different inclination angles of each side surface of projections of a periodic structure;

FIG. 45 is a schematic cross-sectional view of a modified example of a light-emitting device that includes a periodic structure including projections having inclined side surfaces on a photoluminescent layer;

FIG. 46 is a graph showing the calculation results of enhancement of light emitted in the front direction for different inclination angles of each side surface of projections of a periodic structure located on a photoluminescent layer and of a periodic structure located on a substrate;

FIG. 47 is a graph showing the calculation results for the case that each projection of a periodic structure on a photoluminescent layer has a rectangular cross-section and each projection of a periodic structure on a substrate has a trapezoidal cross-section;

FIG. 48A is a schematic cross-sectional view of a periodic structure having another cross-section;

FIG. 48B is a schematic cross-sectional view of a periodic structure having still another cross-section;

FIG. 48C is a schematic cross-sectional view of a periodic structure having still another cross-section;

FIG. 48D is a schematic cross-sectional view of a periodic structure having still another cross-section;

FIG. 49A is a schematic view of material particles emitted from a target at a relatively low sputtering pressure and colliding with a substrate;

FIG. 49B is a schematic view of material particles emitted from a target at a relatively high sputtering pressure and colliding with a substrate;

FIG. 50A is a cross-sectional image of a sample produced by depositing YAG:Ce by sputtering on a quartz substrate having a periodic structure including projections having a rectangular cross-section and having a height of 170 nm;

FIG. 50B is a cross-sectional image of a sample produced by depositing YAG:Ce by sputtering on a quartz substrate having a periodic structure including projections having a rectangular cross-section and having a height of 170 nm;

FIG. 51A is a schematic cross-sectional view of a photoluminescent material film on a substrate having a periodic structure including relatively low projections;

FIG. 51B is a schematic cross-sectional view of a photoluminescent material film on a substrate having a periodic structure including relatively low projections;

FIG. 51C is a cross-sectional image of a sample produced by depositing YAG:Ce by sputtering on a quartz substrate having a periodic structure including projections having a rectangular cross-section and having a height of 60 nm;

FIG. 52A is a schematic cross-sectional view of a photoluminescent material film on a substrate having a periodic structure including relatively high projections;

FIG. 52B is a schematic cross-sectional view of a photoluminescent material film on a substrate having a periodic structure including relatively high projections;

FIG. 52C is a cross-sectional image of a sample produced by depositing YAG:Ce by sputtering on a quartz substrate having a periodic structure including projections having a rectangular cross-section and having a height of 200 nm;

FIG. 53 is a schematic cross-sectional view illustrating the difference in position between periodic structures;

FIG. 54 is a graph showing the calculation results of enhancement of light emitted in the front direction for various differences in position between periodic structures;

FIG. 55 is a perspective view of a structure that includes a first member having a surface structure including two projections and a second member covering the first member;

FIG. 56 is a schematic cross-sectional view of a multilayer structure that includes a first member having a surface structure including projections and a second member covering the first member;

FIG. 57 is a schematic cross-sectional view of another multilayer structure that includes a first member having a surface structure including projections and a second member covering the first member; and

FIG. 58 is a schematic cross-sectional view of a surface structure having projections or recesses or both.

### DETAILED DESCRIPTION

### 1. OUTLINE OF EMBODIMENTS OF PRESENT DISCLOSURE

The present disclosure includes the following light-emitting devices:
[Item 1] A light-emitting device comprising:

a light-transmissive layer having a first surface; and

a photoluminescent layer located on the first surface, wherein

the photoluminescent layer has a second surface facing the light-transmissive layer and a third surface opposite the second surface, and emits light containing first light having a wavelength λₐ in air from the third surface upon receiving excitation light,

the photoluminescent layer has a first surface structure located on the third surface, the first surface structure having an array of projections,

the light-transmissive layer has a second surface structure located on the first surface, the second surface structure having projections corresponding to the projections of the first surface structure,

the first surface structure and the second surface structure limit a directional angle of the first light emitted from the third surface,

the projections of the first surface structure include a first projection, and

the first projection has a base width greater than a top width in a cross-section perpendicular to the photoluminescent layer and parallel to an array direction of the projections of the first surface structure.
[Item 2] The light-emitting device according to Item 1, wherein each of the projections of the first surface structure has a base wider than a top of the projection.
[Item 3] The light-emitting device according to Item 1 or 2, wherein side surfaces of the projections of the first surface structure have a smaller inclination angle than side surfaces of the projections of the second surface structure.
[Item 4] The light-emitting device according to any one of Items 1 to 3, wherein the second surface structure has a second projection corresponding to the first projection, and

the first projection has a base width smaller than a top width of the second projection in the cross-section.
[Item 5] The light-emitting device according to any one of Items 1 to 3, wherein the second surface structure has a second projection corresponding to the first projection, and

the first projection has a base width greater than a top width of the second projection in the cross-section.
[Item 6] The light-emitting device according to Item 1, wherein

the projections of the second surface structure include a second projection corresponding to the first projection, and

the second projection has a base width greater than a top width of the second projection in the cross-section.
[Item 7] The light-emitting device according to Item 6, wherein each of the projections of the first surface structure has a base wider than a top of the projection in the cross-section.
[Item 8] The light-emitting device according to Item 6 or 7, wherein each of the projections of the second surface structure has a base wider than a top of the projection in the cross-section.
[Item 9] The light-emitting device according to any one of Items 6 to 8, wherein

at least part of the side surfaces of the projections of the first surface structure are inclined with respect to a direction perpendicular to the photoluminescent layer, and

at least part of the side surfaces of the projections of the second surface structure are inclined with respect to the direction perpendicular to the photoluminescent layer.
[Item 10] The light-emitting device according to any one of Items 6 to 9, wherein at least part of the side surfaces of the projections of the first surface structure, or at least part of the side surfaces of the projections of the second surface structure, or both are stepped.
[Item 11] The light-emitting device according to any one of Items 1 to 10, wherein a distance D1ᵢₙₜ between two adjacent projections of the first surface structure, a distance D2ᵢₙₜ between two adjacent projections of the second surface structure, and a refractive index n_{wav-a} of the photoluminescent layer for the light having a wavelength λₐ in air satisfy λₐ/n_{wav-a}<D1ᵢₙₜ<λₐ and λₐ/n_{wav-a}<D2ᵢₙₜ<λₐ.
[Item 12] A light-emitting device including

a light-transmissive layer, and

a photoluminescent layer that is located on the light-transmissive layer and emits light having a wavelength λₐ in air upon receiving excitation light,

wherein the photoluminescent layer has a first surface structure located on its surface opposite the light-transmissive layer and having recesses,

the light-transmissive layer has a second surface structure on its surface facing the photoluminescent layer, the second surface structure having recesses corresponding to the recesses of the first surface structure,

the first surface structure and the second surface structure limit the directional angle of the light having a wavelength λₐ in air emitted from the photoluminescent layer,

the recesses of the first surface structure include a first recess, and

the first recess has an opening width greater than a bottom width in a cross-section perpendicular to the photoluminescent layer and parallel to an array direction of the recesses of the first surface structure.
[Item 13] The light-emitting device according to Item 12, wherein each of the recesses of the first surface structure has an opening wider than a bottom of the recess.
[Item 14] The light-emitting device according to Item 12 or 13, wherein side surfaces of the recesses of the first surface structure have a smaller inclination angle than side surfaces of the recesses of the second surface structure.
[Item 15] The light-emitting device according to any one of Items 12 to 14, wherein

the second surface structure has a second recess corresponding to the first recess, and

the first recess has a bottom width smaller than an opening width of the second recess in the cross-section.
[Item 16] The light-emitting device according to any one of Items 12 to 14, wherein

the second surface structure has a second recess corresponding to the first recess, and

the first recess has a bottom width greater than an opening width of the second recess in the cross-section.
[Item 17] The light-emitting device according to Item 12, wherein

the recesses of the second surface structure include a second recess corresponding to the first recess, and

the second recess has an opening width greater than a bottom width of the second recess in the cross-section.
[Item 18] The light-emitting device according to Item 17, wherein each of the recesses of the first surface structure has an opening wider than a bottom of the recess.

[Item 19] The light-emitting device according to Item 17 or 18, wherein each of the recesses of the second surface structure has an opening wider than a bottom of the recess.
[Item 20] The light-emitting device according to any one of Items 17 to 19, wherein

at least part of the side surfaces of the recesses of the first surface structure are inclined with respect to a direction perpendicular to the photoluminescent layer, and

at least part of the side surfaces of the recesses of the second surface structure are inclined with respect to the direction perpendicular to the photoluminescent layer.
[Item 21] The light-emitting device according to any one of Items 17 to 20, wherein at least part of the side surfaces of the recesses of the first surface structure, or at least part of the side surfaces of the recesses of the second surface structure, or both are stepped.
[Item 22] The light-emitting device according to any one of Items 12 to 21, wherein a distance D1ᵢₙₜ between two adjacent recesses of the first surface structure, a distance D2ᵢₙₜ between two adjacent recesses of the second surface structure, and a refractive index n_{wav-a} of the photoluminescent layer for the light having a wavelength λₐ in air satisfy λₐ/n_{wav-a}<D1ᵢₙₜ<λₐ and λₐ/n_{wav-a}<D2ᵢₙₜ<λₐ.
[Item 23] The light-emitting device according to Item 11 or 22, wherein the D1ᵢₙₜ is equal to the D2ᵢₙₜ.
[Item 24] The light-emitting device according to any one of Items 1 to 23, wherein

the first surface structure has at least one first periodic structure,

the second surface structure has at least one second periodic structure, and

a period p1ₐ of the at least one first periodic structure, a period p2ₐ of the at least one second periodic structure, and a refractive index n_{wav-a} of the photoluminescent layer for the light having a wavelength λₐ in air satisfy λₐ/n_{wav-a}<p1ₐ<λₐ and λₐ/n_{wav-a}<p2ₐ<λₐ.
[Item 25] The light-emitting device according to any one of Items 1 to 24, wherein the first surface structure and the second surface structure form a quasi-guided mode in the photoluminescent layer, and

the quasi-guided mode causes the light having a wavelength λₐ in air emitted from the photoluminescent layer to have a maximum intensity in a first direction defined by the first surface structure and the second surface structure.
[Item 26] The light-emitting device according to any one of Items 1 to 24, wherein the light having a wavelength λₐ in air has a maximum intensity in a first direction defined by the first surface structure and the second surface structure.
[Item 27] The light-emitting device according to Item 25 or 26, wherein the light having a wavelength λₐ in air emitted in the first direction is linearly polarized light.
[Item 28] The light-emitting device according to any one of Items 1 to 27, wherein the first surface structure and the second surface structure limit the directional angle of the light having a wavelength λₐ in air emitted from the photoluminescent layer to less than 15 degrees.
[Item 29] The light-emitting device according to any one of Items 1 to 27, wherein the directional angle of the light having a wavelength λₐ in air with respect to the first direction is less than 15 degrees.

A light-emitting device according to an embodiment of the present disclosure includes a light-transmissive layer and a photoluminescent layer located on the light-transmissive layer. The photoluminescent layer emits light having a wavelength λₐ in air upon receiving excitation light. The photoluminescent layer has a first surface structure on its surface opposite the light-transmissive layer, and the light-transmissive layer has a second surface structure facing the photoluminescent layer. The first surface structure has projections, and the second surface structure has projections corresponding to the projections of the first surface structure. Alternatively, the first surface structure has recesses, and the second surface structure has recesses corresponding to the recesses of the first surface structure. The first surface structure and the second surface structure limit the directional angle of the light having a wavelength λₐ in air emitted from the photoluminescent layer.

The wavelength λₐ may be in the visible wavelength range (for example, 380 to 780 nm). When infrared light is used, the wavelength λₐ may be more than 780 nm. When ultraviolet light is used, the wavelength λₐ may be less than 380 nm. In the present disclosure, all electromagnetic waves, including infrared light and ultraviolet light, are referred to as “light” for convenience.

The photoluminescent layer contains a photoluminescent material. The term “photoluminescent material” refers to a material that emits light in response to excitation light. The term “photoluminescent material” encompasses fluorescent materials and phosphorescent materials in a narrow sense, encompasses inorganic materials and organic materials (for example, dyes), and encompasses quantum dots (that is, tiny semiconductor particles). The photoluminescent layer may contain a matrix material (host material) in addition to the photoluminescent material. Examples of matrix materials include resins and inorganic materials, such as glasses and oxides.

The light-transmissive layer may be a substrate that supports the photoluminescent layer. For example, the light-transmissive layer is located on or near the photoluminescent layer and is formed of a material, for example, an inorganic material or resin, having high transmittance to light emitted from the photoluminescent layer. For example, the light-transmissive layer can be formed of a dielectric material (particularly, an insulator having low light absorptivity). If the surface of the photoluminescent layer exposed to air has a submicron structure described later, an air layer can serve as a light-transmissive layer.

A surface structure having projections or recesses or both is formed on a surface of at least one of the photoluminescent layer and the light-transmissive layer. The term “surface”, as used herein, refers to a portion in contact with another substance (that is, an interface). If the light-transmissive layer is a gas layer, such as air, the interface between the gas layer and another substance (for example, the photoluminescent layer) is a surface of the light-transmissive layer. This surface structure can also be referred to as a “texture”. The surface structure typically has projections or recesses periodically arranged in one or two dimensions. Such a surface structure can be referred to as a “periodic structure”. The projections and recesses are formed at the boundary between two adjoining members (or media) having different refractive indices. Thus, the “periodic structure” has a refractive index that varies periodically in a certain direction. The term “periodically” refers not only to periodically in the strict sense but also to approximately periodically. In the present specification, the distance between any two adjacent centers (hereinafter also referred to as the “center distance”) of continuous projections or recesses of a periodic structure having a period p varies within ±15% of p.

The term “projection”, as used herein, refers to a raised portion higher than a reference level. The term “recess”, as used herein, refers to a recessed portion lower than a reference level. FIG. 55 illustrates a structure that includes a member 601 having a surface structure including two projections and a member 602 covering the member 601. For reference, FIG. 55 shows x-, y-, and z-axes intersecting at right angles. For convenience of explanation, another figure may also show the x-, y-, and z-axes intersecting at right angles.

The members 601 and 602 are generally flat and extend on the xy plane. In FIG. 55, the members 601 and 602 are stacked in the z direction. FIG. 55 also schematically illustrates an xz cross-section of the multilayer structure of the members 601 and 602.

In FIG. 55, the surface structure of the member 601 has two projections Pr1 and Pr2, and the “array direction” of these projections is defined. Also in the case that the surface structure has two or more recesses, the “array direction” of these recesses is defined. The “array direction”, as used herein, refers to the direction in which two or more projections or recesses of the surface structure are arrayed. In FIG. 55, when stripe-shaped two projections extending in the y direction are arrayed in the x direction, the x direction is the “array direction” of these projections. If a surface structure is formed at the interface between two members, at least one of which is flat, a cross-section perpendicular to the flat member and parallel to the array direction on the surface structure (the xz cross-section in this case) is hereinafter also referred to as a “vertical cross-section”. The length in the array direction on the surface structure is hereinafter also referred to as a “width”.

In FIG. 55, the projections Pr1 and Pr2 rise in the z direction from the interface between the members 601 and 602. Thus, the height reference for the projections is the interface between the members 601 and 602. A portion of a projection positioned at a reference level in a vertical cross-section is herein referred to as a “base” of the projection. As schematically illustrated in FIG. 55, for example, a base B1 of the projection Pr1 is a portion of the projection Pr1 in contact with a reference plane (the interface between the members 601 and 602) and is a portion of the projection Pr1 closest to the interface between the members 601 and 602. A highest portion of a projection with respect to a reference level in a vertical cross-section is referred to as a “top” of the projection. In the figure, the width Bs of the base B1 of the projection Pr1 is equal to the width Tp of the top T1. A surface between the top and the base is hereinafter also referred to as a “side surface” of each projection. In a vertical cross-section, a side surface may not be straight. A side surface in a vertical cross-section may be curved or stepped.

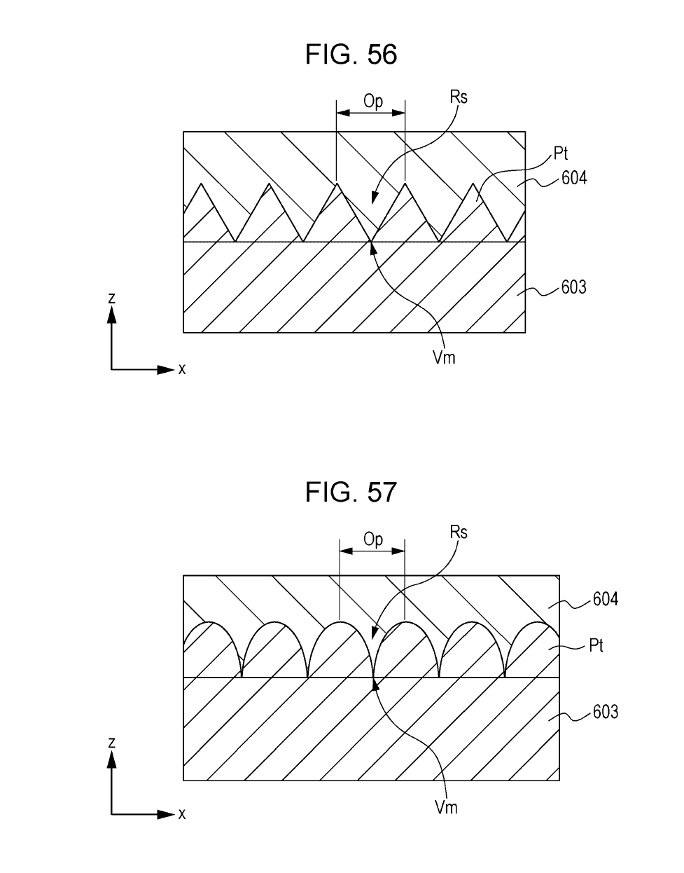

As will be described in detail below, in an embodiment of the present disclosure, the shape (hereinafter also referred to simply as a “cross-section”) of projections (or recesses) of a surface structure in a vertical cross-section is not limited to rectangular as illustrated in FIG. 55. FIGS. 56 and 57 illustrate a cross-section of a multilayer structure that includes a member 603 having a surface structure including projections Pt and a member 604 covering the member 603. In FIG. 56, each of the projections Pt of the surface structure has a triangular cross-section. Each of the projections Pt of the surface structure has a top width of 0. When each of the projections Pt of the surface structure has a convex parabolic cross-section as illustrated in FIG. 57, the projections also have a top width of 0. As in these embodiments, the projections may have a top width of 0.

In a vertical cross-section of the surface structures illustrated in FIGS. 56 and 57, it can be understood that if the top of each projection Pt is positioned at a reference level, then the surface structure has recesses. More specifically, in FIGS. 56 and 57, it can be understood that the member 603 has a surface structure including recesses Rs. Each recess Rs is located between two adjacent portions positioned at a reference level (the top of each projection Pt).

A portion of a recess of a surface structure farthest from a reference level in a vertical cross-section is herein referred to as a “bottom” of the recess. The “bottom” is the lowest portion of a recess with respect to a reference level. In FIGS. 56 and 57, the bottom Vm of each recess Rs has a width of 0. As described above, each recess of a surface structure is defined by two adjacent portions each positioned at a reference level. A space between these two portions that define a recess in a vertical cross-section is herein referred to as an “opening” of the recess. The width Op in FIGS. 56 and 57 schematically represents the opening width of each recess Rs. The opening is located between points at which the height begins to decrease from the reference level to the bottom of each recess in a surface structure. A surface between the opening and the bottom is hereinafter also referred to as a “side surface” of each recess. Like projections, each recess in a vertical cross-section may have a straight, curved, stepped, or irregular side surface.

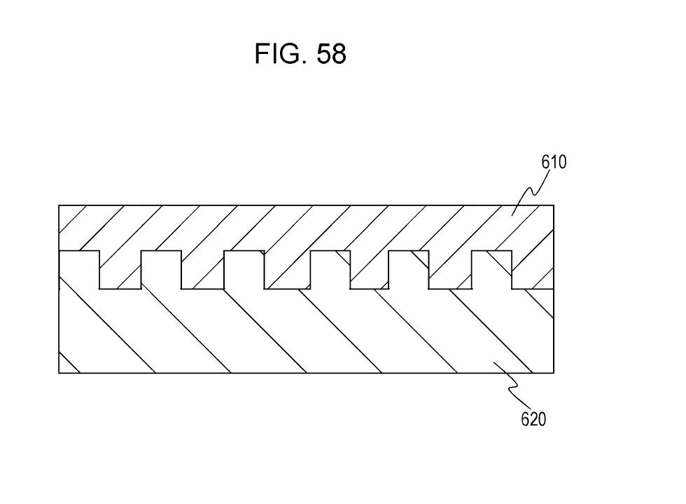

When projections and recesses have a particular shape, size, or distribution, it may be difficult to distinguish between projections and recesses. For example, in a cross-sectional view of FIG. 58, a member 610 has recesses, and a member 620 has projections, or alternatively the member 610 has projections, and the member 620 has recesses. In either case, each of the member 610 and the member 620 has projections or recesses or both. Also in the structure illustrated in FIG. 55, it can be understood that the member 602 has a surface structure including two recesses. In this case, a portion of the member 602 in contact with the top T1 corresponds to the bottom of the left recess in FIG. 55. The bottom has a width Tp, and the recess has an opening width Bs.

The distance between the centers of two adjacent projections or recesses of the surface structure (the period p in the case of a periodic structure) is typically shorter than the wavelength λₐ in air of light emitted from the photoluminescent layer. The distance is submicron if light emitted from the photoluminescent layer is visible light, near-infrared light having a short wavelength, or ultraviolet light. Thus, such a surface structure is sometimes referred to as a “submicron structure”. The “submicron structure” may partly have a center distance or period of more than 1 micrometer (μm). In the following description, it is assumed that the photoluminescent layer principally emits visible light, and the surface structure is principally a “submicron structure”. However, the following description can also be applied to a surface structure having a micrometer structure (for example, a micrometer structure used in combination with infrared light).

In a light-emitting device according to an embodiment of the present disclosure, a unique electric field distribution is formed within at least the photoluminescent layer, as described in detail later with reference to the calculation and experimental results. Such an electric field distribution is formed by an interaction between guided light and a submicron structure (that is, a surface structure). Such an electric field distribution is formed in an optical mode referred to as a “quasi-guided mode”. A quasi-guided mode can be utilized to improve the luminous efficiency, directionality, and polarization selectivity of photoluminescence, as described later. The term “quasi-guided mode” may be used in the following description to describe novel structures and/or mechanisms contemplated by the present inventors. Such a description is for illustrative purposes only and is not intended to limit the present disclosure in any way.

For example, the submicron structure has projections and satisfies λₐ/λ_{wav-a}<Dᵢₙₜ<λₐ, wherein Dᵢₙₜ is the center-to-center distance between adjacent projections. The first surface structure of the photoluminescent layer and the second surface structure of the light-transmissive layer may satisfy λₐ/n_{wav-a}<Dᵢₙₜ<λₐ. The submicron structure may have recesses, instead of the projections. More specifically, the first surface structure and the second surface structure may have recesses and satisfy λₐ/n_{wav-a}<Dᵢₙₜ<λₐ, wherein Dᵢₙₜ denotes the center-to-center distance between adjacent recesses. For simplicity, the following description will be directed to a submicron structure having projections. The symbol λ denotes the wavelength of light, and the symbol λₐ denotes the wavelength of light in air. The symbol n_{wav} denotes the refractive index of the photoluminescent layer. If the photoluminescent layer is formed of a medium containing a mixture of materials, the refractive index n_{wav} is the average of the refractive indices of the materials weighted by their respective volume fractions. Although it is desirable to use the symbol n_{wav-a} to refer to the refractive index for light having a wavelength λₐ because the refractive index n generally depends on the wavelength, it may be abbreviated for simplicity. The symbol n_{wav} basically denotes the refractive index of the photoluminescent layer; however, if a layer having a higher refractive index than the photoluminescent layer is adjacent to the photoluminescent layer, the refractive index n_{wav} is the average of the refractive indices of the layer having the higher refractive index and the photoluminescent layer weighted by their respective volume fractions. This situation is optically equivalent to a photoluminescent layer composed of layers of different materials.

The effective refractive index n_{eff} of the medium for light in a quasi-guided mode satisfies nₐ<n_{eff}<n_{wav}, wherein nₐ denotes the refractive index of air. If light in a quasi-guided mode propagates through the photoluminescent layer while being totally reflected at an incident angle θ, the effective refractive index n_{eff} can be written as n_{eff}=n_{wav} sin θ. The effective refractive index n_{eff} is determined by the refractive index of the medium present in the region where the electric field of a quasi-guided mode is distributed. For example, if the submicron structure is formed in the light-transmissive layer, the effective refractive index n_{eff} depends not only on the refractive index of the photoluminescent layer but also on the refractive index of the light-transmissive layer. Because the electric field distribution also varies with the polarization direction of the quasi-guided mode (TE mode or TM mode), the effective refractive index n_{eff} can differ between the TE mode and the TM mode.

The submicron structure is formed on at least one of the photoluminescent layer and the light-transmissive layer. If the photoluminescent layer and the light-transmissive layer are in contact with each other, the submicron structure may be formed at the interface between the photoluminescent layer and the light-transmissive layer. In such a case, it can be said that the photoluminescent layer and the light-transmissive layer have the submicron structure. A light-transmissive layer having a submicron structure may be located on or near the photoluminescent layer. A phrase like “a light-transmissive layer (or its submicron structure) located on or near the photoluminescent layer”, as used herein, typically means that the distance between these layers is less than half the wavelength λₐ. This allows the electric field in a guided mode to reach the submicron structure, thus forming a quasi-guided mode. However, the distance between the submicron structure of the light-transmissive layer and the photoluminescent layer may exceed half the wavelength λₐ if the light-transmissive layer has a higher refractive index than the photoluminescent layer, because light reaches the light-transmissive layer even if the above relationship is not satisfied. In the present specification, if the photoluminescent layer and the light-transmissive layer have a positional relationship that allows the electric field in a guided mode to reach the submicron structure and form a quasi-guided mode, they may be associated with each other.

The submicron structure that satisfies λₐ/n_{wav-a}<Dᵢₙₜ<λₐ as described above is characterized by a submicron size in applications utilizing visible light. The submicron structure can include at least one periodic structure, as in the light-emitting devices according to the embodiments described in detail later. The at least one periodic structure has a period pₐ that satisfies λₐ/n_{wav-a}<pₐ<λₐ. Thus, the submicron structure can include a periodic structure in which the distance Dᵢₙₜ between adjacent projections is constant at pₐ. The relationship λₐ/n_{wav-a}<pₐ<λₐ may be satisfied in the first surface structure of the photoluminescent layer and the second surface structure of the light-transmissive layer. The first surface structure and the second surface structure may have recesses and satisfy λₐ/n_{wav-a}<pₐ<λₐ, wherein pₐ denotes the period of the center-to-center distance between adjacent recesses. If the submicron structure includes such a periodic structure, light in a quasi-guided mode propagates while repeatedly interacting with the periodic structure so that the light is diffracted by the submicron structure. Unlike the phenomenon in which light propagating through free space is diffracted by a periodic structure, this is the phenomenon in which light is guided (that is, repeatedly totally reflected) while interacting with the periodic structure. This can efficiently diffract light even if the periodic structure causes a small phase shift (that is, even if the periodic structure has a small height).

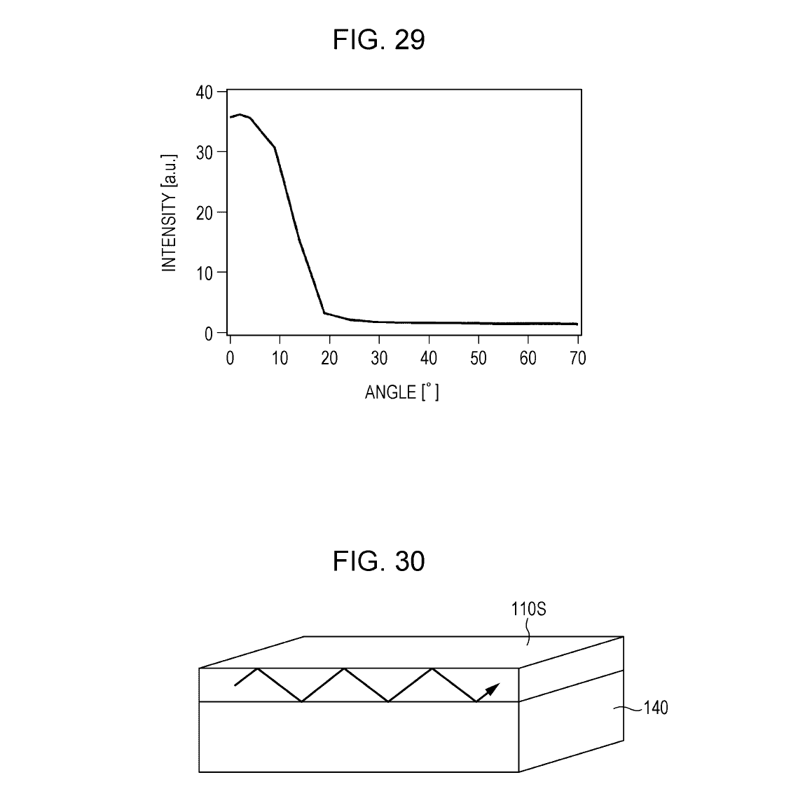

The above mechanism can be utilized to improve the luminous efficiency of photoluminescence by the enhancement of the electric field due to a quasi-guided mode and also to couple emitted light to the quasi-guided mode. The angle of travel of light in a quasi-guided mode is changed by the angle of diffraction determined by the periodic structure. This can be utilized to emit light of a particular wavelength in a particular direction. This can significantly improve directionality compared with submicron structures including no periodic structure. Furthermore, high polarization selectivity can be simultaneously achieved because the effective refractive index n_{eff} (=n_{wav} sin θ) differs between the TE mode and the TM mode. For example, as demonstrated by the experimental examples below, a light-emitting device can be provided that emits intense linearly polarized light (for example, the TM mode) of a particular wavelength (for example, 610 nm) in the front direction. The directional angle of light emitted in the front direction is less than 15 degrees, for example. The term “directional angle”, as used herein, refers to the angle between the direction of maximum intensity and the direction of 50% of the maximum intensity of linearly polarized light having a particular wavelength to be emitted. In other words, the term “directional angle” refers to the angle of one side with respect to the direction of maximum intensity, which is assumed to be 0 degrees. Thus, the periodic structure (that is, surface structure) in an embodiment of the present disclosure limits the directional angle of light having a particular wavelength λₐ. In other words, the distribution of light having the wavelength λₐ is narrowed compared with submicron structures including no periodic structure. Such a light distribution in which the directional angle is narrowed compared with submicron structures including no periodic structure is sometimes referred to as a “narrow-angle light distribution”. Although the periodic structure in an embodiment of the present disclosure limits the directional angle of light having the wavelength λₐ, the periodic structure does not necessarily emit the entire light having the wavelength λₐ at narrow angles. For example, in an embodiment described later in FIG. 29, light having the wavelength λₐ is slightly emitted in a direction (for example, at an angle in the range of 20 to 70 degrees) away from the direction of maximum intensity. However, as a whole, emitted light having the wavelength λₐ mostly has an angle in the range of 0 to 20 degrees and has limited directional angles.

Unlike general diffraction gratings, the periodic structure in a typical embodiment of the present disclosure has a shorter period than the light wavelength λₐ. General diffraction gratings have a sufficiently longer period than the light wavelength λₐ, and consequently light of a particular wavelength is divided into diffracted light emissions, such as zero-order light (that is, transmitted light) and ±1-order diffracted light. In such diffraction gratings, higher-order diffracted light is generated on both sides of zero-order light. Higher-order diffracted light generated on both sides of zero-order light in diffraction gratings makes it difficult to provide a narrow-angle light distribution. In other words, known diffraction gratings do not have the effect of limiting the directional angle of light to a predetermined angle (for example, approximately 15 degrees), which is a characteristic effect of an embodiment of the present disclosure. In this regard, the periodic structure according to an embodiment of the present disclosure is significantly different from known diffraction gratings.

A submicron structure having lower periodicity results in lower directionality, luminous efficiency, polarization, and wavelength selectivity. The periodicity of the submicron structure may be adjusted depending on the need. The periodic structure may be a one-dimensional periodic structure, which has higher polarization selectivity, or a two-dimensional periodic structure, which allows for lower polarization.

The submicron structure may include periodic structures. For example, these periodic structures may have different periods or different periodic directions (axes). The periodic structures may be formed on the same plane or may be stacked on top of each other. As a matter of course, the light-emitting device may include photoluminescent layers and light-transmissive layers, and each of the layers may have submicron structures.

The submicron structure can be used not only to control light emitted from the photoluminescent layer but also to efficiently guide excitation light into the photoluminescent layer. That is, excitation light can be diffracted by the submicron structure and coupled to a quasi-guided mode that guides light in the photoluminescent layer and the light-transmissive layer and thereby can efficiently excite the photoluminescent layer. The submicron structure satisfies λₑₓ/n_{wav-ex}≦Dᵢₙₜ<λₑₓ, wherein λₑₓ denotes the wavelength of excitation light in air, the excitation light exciting the photoluminescent material, and n_{wav-ex} denotes the refractive index of the photoluminescent layer for the excitation light. The symbol n_{wav-ex} denotes the refractive index of the photoluminescent layer at the emission wavelength of the photoluminescent material. Alternatively, the submicron structure may include a periodic structure having a period pₑₓ that satisfies λₑₓ/n_{wav-ex}<pₑₓ<λₑₓ. The excitation light has a wavelength λₑₓ of 450 nm, for example, but may have a shorter wavelength than visible light. If the excitation light has a wavelength in the visible range, the excitation light may be emitted together with light emitted from the photoluminescent layer.

### 2. UNDERLYING KNOWLEDGE FORMING BASIS OF THE PRESENT DISCLOSURE

The underlying knowledge forming the basis for the present disclosure will be described before describing specific embodiments of the present disclosure. As described above, photoluminescent materials, such as those used for fluorescent lamps and white light-emitting diodes (LEDs), emit light in all directions. Thus, an optical element, such as a reflector or lens, is required to emit light in a particular direction. Such an optical element, however, can be eliminated (or the size thereof can be reduced) if the photoluminescent layer itself emits directional light. This results in a significant reduction in the size of optical devices and equipment. With this idea in mind, the present inventors have conducted a detailed study on the photoluminescent layer to achieve directional light emission.

The present inventors have investigated the possibility of inducing light emission with particular directionality so that light emitted from the photoluminescent layer is localized in a particular direction. Based on Fermi's golden rule, the emission rate F, which is a measure characterizing light emission, is represented by the formula (1):

$$Γ ( r ) = \frac{2 π}{\overline{h}} {〈 ( d \cdot E ( r ) ) 〉}^{2} ρ ( λ ) \qquad ( 1 )$$

In the formula (1), r denotes the vector indicating the position, λ denotes the wavelength of light, d denotes the dipole vector, E denotes the electric field vector, and ρ denotes the density of states. In many substances other than some crystalline substances, the dipole vector d is randomly oriented. The magnitude of the electric field E is substantially constant irrespective of the direction if the size and thickness of the photoluminescent layer are sufficiently larger than the wavelength of light. Hence, in most cases, the value of <(d·E(r))>² is independent of the direction. Accordingly, the emission rate F is constant irrespective of the direction. Thus, in most cases, the photoluminescent layer emits light in all directions.

As can be seen from the formula (1), to achieve anisotropic light emission, it is necessary to align the dipole vectors d in a particular direction or to enhance a component of the electric field vector in a particular direction. One of these approaches can be employed to achieve directional light emission. Embodiments of the present disclosure utilize a quasi-guided mode in which an electric field component in a particular direction is enhanced by confinement of light in a photoluminescent layer. Structures for utilizing a quasi-guided mode have been studied and analyzed in detail as described below.

### 3. STRUCTURE FOR ENHANCING ELECTRIC FIELD ONLY IN PARTICULAR DIRECTION

The present inventors have investigated the possibility of controlling light emission using a guided mode with an intense electric field. Light can be coupled to a guided mode using a waveguide structure that itself contains a photoluminescent material. However, a waveguide structure simply formed from a photoluminescent material emits little or no light in the front direction because the emitted light is coupled to a guided mode. Accordingly, the present inventors have investigated the possibility of combining a waveguide containing a photoluminescent material with a periodic structure. When the electric field of light is guided in a waveguide while overlapping a periodic structure located on or near the waveguide, a quasi-guided mode is formed by the effect of the periodic structure. That is, the quasi-guided mode is a guided mode restricted by the periodic structure and is characterized in that the antinodes of the amplitude of the electric field have the same period as the periodic structure. Light in this mode is confined in the waveguide structure to enhance the electric field in a particular direction. This mode also interacts with the periodic structure and undergoes diffraction, so that light in this mode is converted into light propagating in a particular direction and can be emitted from the waveguide. The electric field of light other than quasi-guided modes is not enhanced because little or no such light is confined in the waveguide. Thus, most light is coupled to a quasi-guided mode with a large electric field component.

That is, the present inventors have investigated the possibility of using a photoluminescent layer containing a photoluminescent material as a waveguide (or a waveguide layer including a photoluminescent layer) in combination with a periodic structure located on or near the waveguide to couple light to a quasi-guided mode in which the light is converted into light propagating in a particular direction, thereby providing a directional light source.

As a simple waveguide structure, the present inventors have studied slab waveguides. Slab waveguides have a planar structure in which light is guided. FIG. 30 is a schematic perspective view of a slab waveguide 110S. There is a mode of light propagating through the waveguide 110S if the waveguide 110S has a higher refractive index than a transparent substrate 140 that supports the waveguide 110S. If such a slab waveguide includes a photoluminescent layer, the electric field of light emitted from an emission point overlaps largely with the electric field of a guided mode. This allows most of the light emitted from the photoluminescent layer to be coupled to the guided mode. If the photoluminescent layer has a thickness close to the wavelength of light, a situation can be created where there is only a guided mode with a large electric field amplitude.

If a periodic structure is located on or near the photoluminescent layer, the electric field of the guided mode interacts with the periodic structure to form a quasi-guided mode. Even if the photoluminescent layer is composed of multiple layers, a quasi-guided mode is formed as long as the electric field of the guided mode reaches the periodic structure. Not all of the photoluminescent layer needs to be formed of a photoluminescent material, provided that at least a portion of the photoluminescent layer functions to emit light.

If the periodic structure is made of a metal, a mode due to a guided mode and plasmon resonance is formed. This mode has different properties from the quasi-guided mode described above and is less effective in enhancing emission because a large loss occurs due to high absorption by the metal. Thus, it is desirable to form the periodic structure using a dielectric material having low absorptivity.

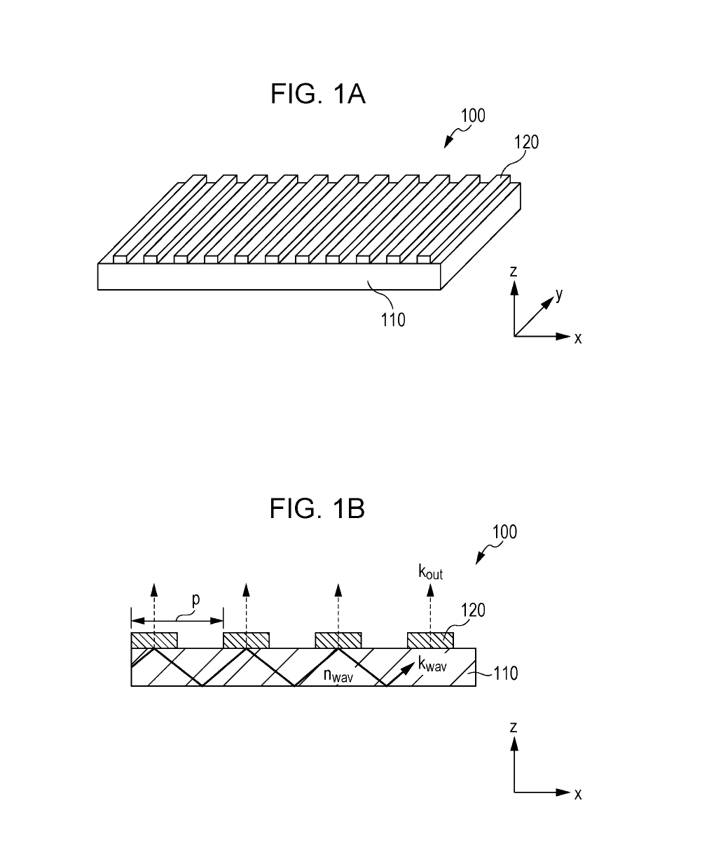

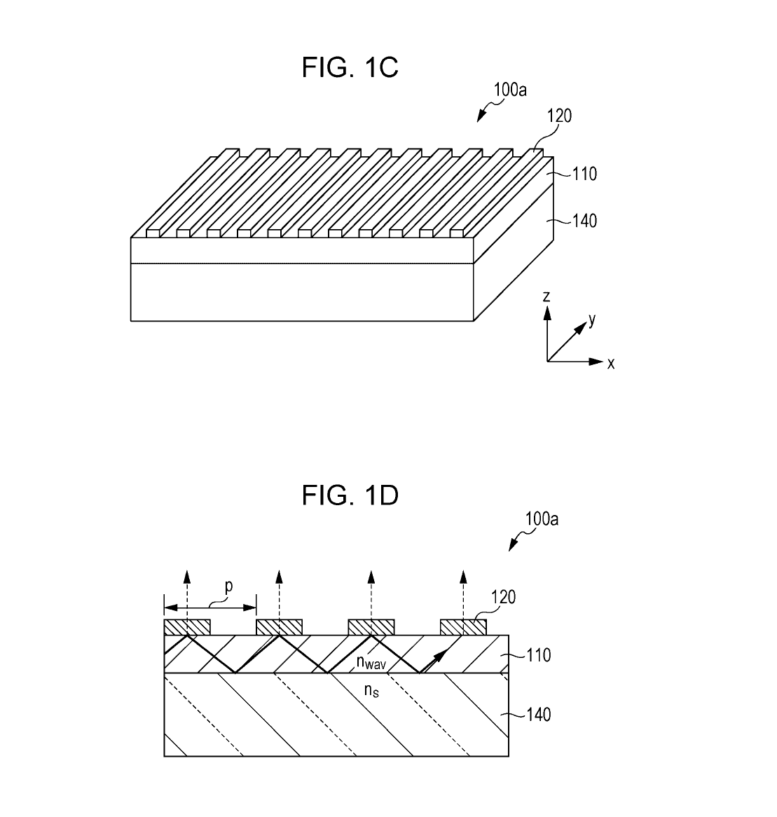

The present inventors have studied coupling of light to a quasi-guided mode that can be emitted as light propagating in a particular angular direction using a periodic structure formed on a waveguide. FIG. 1A is a schematic perspective view of a light-emitting device 100 including a waveguide (for example, a photoluminescent layer) 110 and a periodic structure (for example, part of a light-transmissive layer) 120. The light-transmissive layer 120 may be hereinafter referred to as a “periodic structure 120” if the light-transmissive layer 120 has a periodic structure (that is, if a submicron structure is defined on the light-transmissive layer 120). In this example, the periodic structure 120 is a one-dimensional periodic structure in which stripe-shaped projections extending in the y direction are arranged at regular intervals in the x direction. FIG. 1B is a cross-sectional view of the light-emitting device 100 taken along a plane parallel to the xz plane. If a periodic structure 120 having a period p is provided in contact with the waveguide 110, a quasi-guided mode having a wave number k_{wav} in the in-plane direction is converted into light propagating outside the waveguide 110. The wave number kₒᵤₜ of the light can be represented by the formula (2):

$${k}_{out} = {k}_{wav} - m \frac{2 π}{p} \qquad ( 2 )$$

In the formula (2), m is an integer indicating the diffraction order.

For simplicity, light guided in the waveguide 110 is assumed to be a ray of light propagating at an angle θ_{way}. This approximation gives the formulae (3) and (4):

$$\begin{matrix}\frac{{k}_{wav} {λ}_{0}}{2 π} = {n}_{wav} sin {θ}_{wav} & ( 3 ) \\ \frac{{k}_{out} {λ}_{0}}{2 π} = {n}_{out} sin {θ}_{out} & ( 4 )\end{matrix}$$

In these formulae, λ₀ denotes the wavelength of the light in air, n_{wav} denotes the refractive index of the waveguide 110, Nₒᵤₜ denotes the refractive index of the medium on the light emission side, and θₒᵤₜ denotes the angle at which the light is emitted from the waveguide 110 to a substrate or to the air. From the formulae (2) to (4), the output angle θₒᵤₜ can be represented by the equation (5):

nₒᵤₜ sin θₒᵤₜ=n_{wav} sin θ_{wav}−mλ₀/p (5)

If n_{wav} sin θ_{wav}=mλ₀/p in the formula (5), this results in θₒᵤₜ=0, meaning that the light can be emitted in the direction perpendicular to the plane of the waveguide 110 (that is, in the front direction).

Based on this principle, light can be coupled to a particular quasi-guided mode and be converted into light having a particular output angle using the periodic structure to emit intense light in that direction.

There are some constraints to achieving the above situation. First, to form a quasi-guided mode, light propagating through the waveguide 110 has to be totally reflected. The conditions therefor are represented by the formula (6):

nₒᵤₜ<n_{wav} sin θ_{wav} (6)

To diffract a quasi-guided mode using the periodic structure and thereby emit light from the waveguide 110, −1<sin θₒᵤₜ<1 has to be satisfied in the formula (5). Hence, the following formula (7) has to be satisfied:

$$- 1 < \frac{{n}_{wav}}{{n}_{out}} sin {θ}_{wav} - \frac{m {λ}_{0}}{{n}_{out} p} < 1 \qquad ( 7 )$$

Taking into account the formula (6), the formula (8) has to be satisfied:

$$\frac{m {λ}_{0}}{2 {n}_{out}} < p \qquad ( 8 )$$

Furthermore, to emit light from the waveguide 110 in the front direction (θₒᵤₜ=0), as can be seen from the formula (5), the formula (9) has to be satisfied:

p=mλ₀/(n_{wav} sin θ_{wav}) (9)

As can be seen from the formulae (9) and (6), the required conditions are represented by the formula (10):

$$\frac{m {λ}_{0}}{{n}_{wav}} < p < \frac{m {λ}_{0}}{{n}_{out}} \qquad ( 10 )$$

The periodic structure as illustrated in FIGS. 1A and 1B may be designed based on first-order diffracted light (that is, m=1) because higher-order diffracted light having m of 2 or more has low diffraction efficiency. In this embodiment, the period p of the periodic structure 120 is determined so as to satisfy the formula (11), which is given by substituting m=1 into the formula (10):

$$\frac{{λ}_{0}}{{n}_{wav}} < p < \frac{{λ}_{0}}{{n}_{out}} \qquad ( 11 )$$

If the waveguide (photoluminescent layer) 110 is not in contact with a transparent substrate, as illustrated in FIGS. 1A and 1B, nₒᵤₜ is equal to the refractive index of air (approximately 1.0). Thus, the period p is determined so as to satisfy the formula (12):

$$\frac{{λ}_{0}}{{n}_{wav}} < p < {λ}_{0} \qquad ( 12 )$$

Alternatively, a structure as illustrated in FIGS. 10 and 1D may be employed in which the photoluminescent layer 110 and the periodic structure 120 are formed on a transparent substrate 140. The refractive index nₛ of the transparent substrate 140 is higher than the refractive index of air. Thus, the period p is determined so as to satisfy the formula (13), which is given by substituting nₒᵤₜ=nₛ into the formula (11):

$$\frac{{λ}_{0}}{{n}_{wav}} < p < \frac{{λ}_{0}}{{n}_{s}} \qquad ( 13 )$$

Although m=1 is assumed in the formula (10) to give the formulae (12) and (13), m may be 2 or more. That is, if both surfaces of the light-emitting device 100 are in contact with air layers, as shown in FIGS. 1A and 1B, the period p is determined so as to satisfy the formula (14): wherein m is an integer of 1 or more.

$$\frac{m {λ}_{0}}{{n}_{wav}} < p < m {λ}_{0} \qquad ( 14 )$$

Similarly, if the photoluminescent layer 110 is formed on the transparent substrate 140, as in the light-emitting device 100a illustrated in FIGS. 1C and 1D, the period p may be determined so as to satisfy the formula (15):

$$\frac{m {λ}_{0}}{{n}_{wav}} < p < \frac{m {λ}_{0}}{{n}_{s}} \qquad ( 15 )$$

By determining the period p of the periodic structure so as to satisfy the above formulae, light from the photoluminescent layer 110 can be emitted in the front direction. Thus, a directional light emitting apparatus can be provided.

### 4. CALCULATIONAL VERIFICATION

4-1. Period and Wavelength Dependence

The present inventors verified, by optical analysis, whether light emission in a particular direction as described above is actually possible. The optical analysis was performed by calculations using DiffractMOD available from Cybernet Systems Co., Ltd. In these calculations, the change in the absorption of external light incident perpendicular to a light-emitting device by a photoluminescent layer was calculated to determine an enhancement of light emitted perpendicularly to the light-emitting device. The calculation of the process by which external incident light is coupled to a quasi-guided mode and is absorbed by the photoluminescent layer corresponds to the calculation of a process opposite to the process by which light emitted from the photoluminescent layer is coupled to a quasi-guided mode and is converted into propagating light emitted perpendicularly to the light-emitting device. Similarly, the electric field distribution of a quasi-guided mode was calculated from the electric field of external incident light.

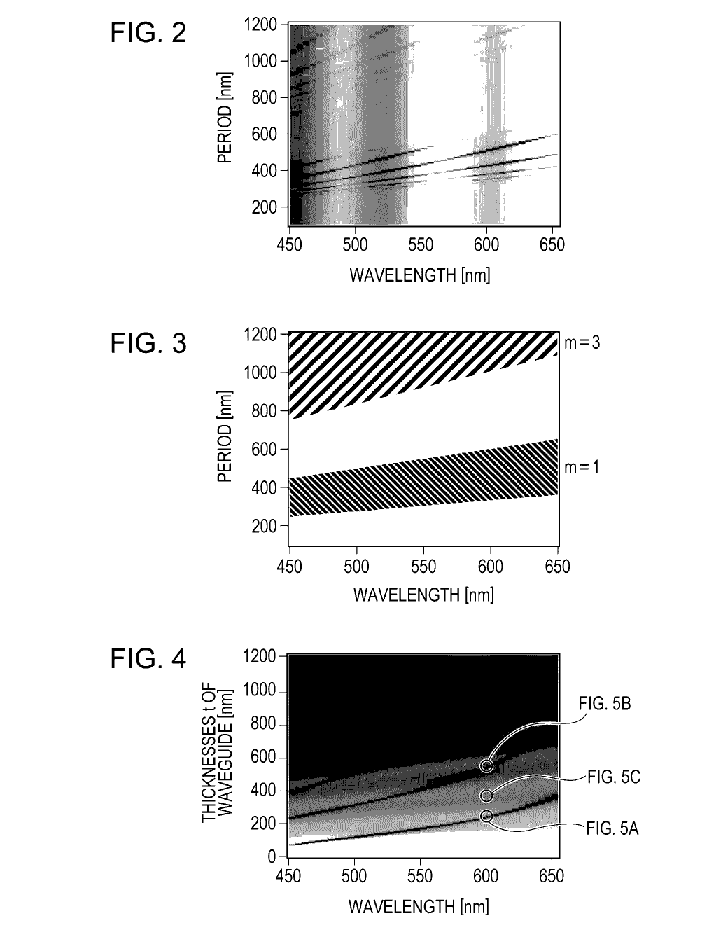

FIG. 2 shows the calculation results of enhancement of light emitted in the front direction with varying emission wavelengths and varying periods of the periodic structure. The photoluminescent layer had a thickness of 1 μm and a refractive index n_{wav} of 1.8, and the periodic structure had a height of 50 nm and a refractive index of 1.5. In these calculations, the periodic structure was a one-dimensional periodic structure uniform in the y direction, as illustrated in FIG. 1A, and the polarization of light was in the TM mode, which has an electric field component parallel to the y direction. The results in FIG. 2 show that there are enhancement peaks at certain combinations of wavelength and period. In FIG. 2, the magnitude of the enhancement is expressed by different shades of color; a darker color (black) indicates a higher enhancement, whereas a lighter color (white) indicates a lower enhancement.

In the above calculations, the periodic structure had a rectangular cross-section, as illustrated in FIG. 1B. FIG. 3 is a graph illustrating the conditions for m=1 and m=3 in the formula (10). A comparison between FIGS. 2 and 3 shows that the peaks in FIG. 2 are located within the regions corresponding to m=1 and m=3. The intensity is higher for m=1 because first-order diffracted light has a higher diffraction efficiency than third- or higher-order diffracted light. There is no peak for m=2 because of low diffraction efficiency in the periodic structure.

In FIG. 2, a plurality of lines are observed in each of the regions corresponding to m=1 and m=3 in FIG. 3. This indicates the presence of a plurality of quasi-guided modes.

### 4-2. Thickness Dependence

FIG. 4 is a graph showing the calculation results of enhancement of light emitted in the front direction with varying emission wavelengths and varying thicknesses t of the photoluminescent layer. The photoluminescent layer had a refractive index n_{wav} of 1.8, and the periodic structure had a period of 400 nm, a height of 50 nm, and a refractive index of 1.5. FIG. 4 shows that enhancement of light is highest at a particular thickness t of the photoluminescent layer.

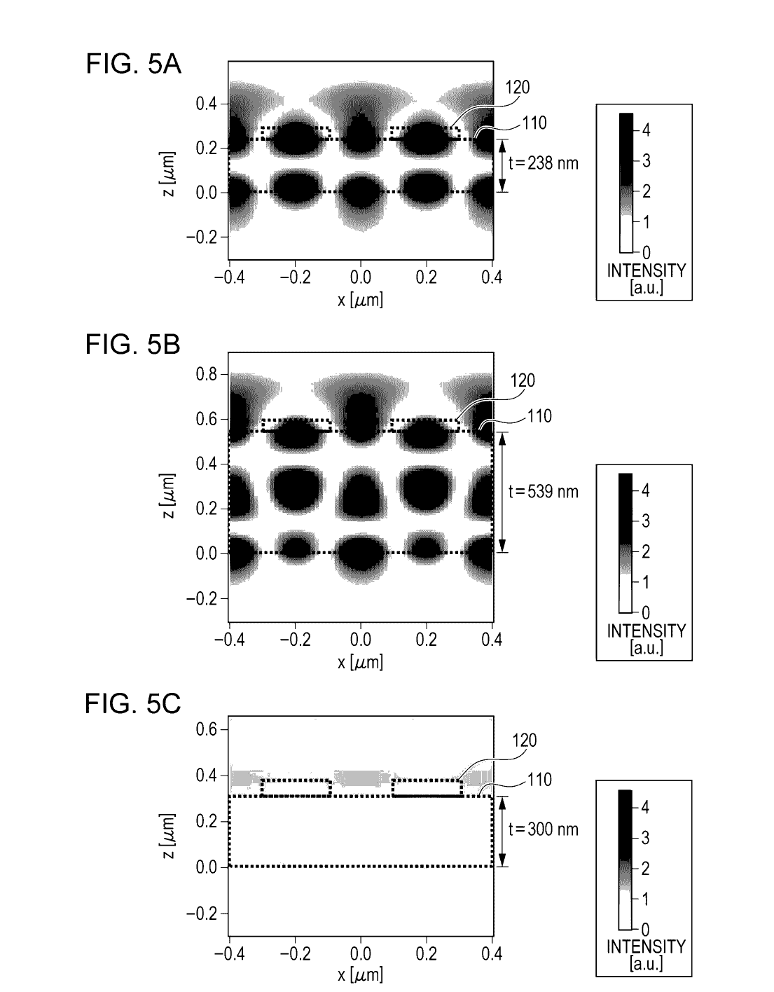

FIGS. 5A and 5B show the calculation results of the electric field distributions in a mode to guide light in the x direction for a wavelength of 600 nm and thicknesses t of 238 nm and 539 nm, respectively, at which there are peaks in FIG. 4. For comparison, FIG. 5C shows the results of similar calculations for a thickness t of 300 nm, at which there is no peak. In these calculations, as in the above calculations, the periodic structure was a one-dimensional periodic structure uniform in the y direction. In each figure, a darker region has higher electric field strength, and a lighter region has lower electric field strength. Whereas the results for t=238 nm and t=539 nm show high electric field strength, the results for t=300 nm show low electric field strength as a whole. This is because there is a guided mode in the case of t=238 or 539 nm, so that light is strongly confined. Furthermore, regions with the highest electric field intensity (antinodes) are necessarily present in or directly below the projections, indicating the correlation between the electric field and the periodic structure 120. Thus, the resulting guided mode depends on the arrangement of the periodic structure 120. A comparison between the results for t=238 nm and t=539 nm shows that these modes differ by one in the number of nodes (white regions) of the electric field in the z direction.

### 4-3. Polarization Dependence

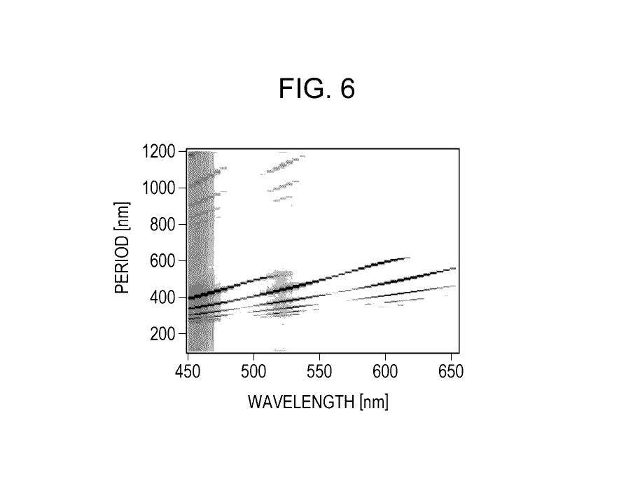

To examine the polarization dependence, enhancement of light was calculated under the same conditions as in FIG. 2 except that the polarization of light was in the TE mode, which has an electric field component perpendicular to the y direction. FIG. 6 shows the calculation results. Although the peaks in FIG. 6 differ slightly in position from the peaks for the TM mode (FIG. 2), they are located within the regions shown in FIG. 3. This demonstrates that the structure according to this embodiment is effective for both the TM mode and the TE mode.

### 4-4. Two-Dimensional Periodic Structure

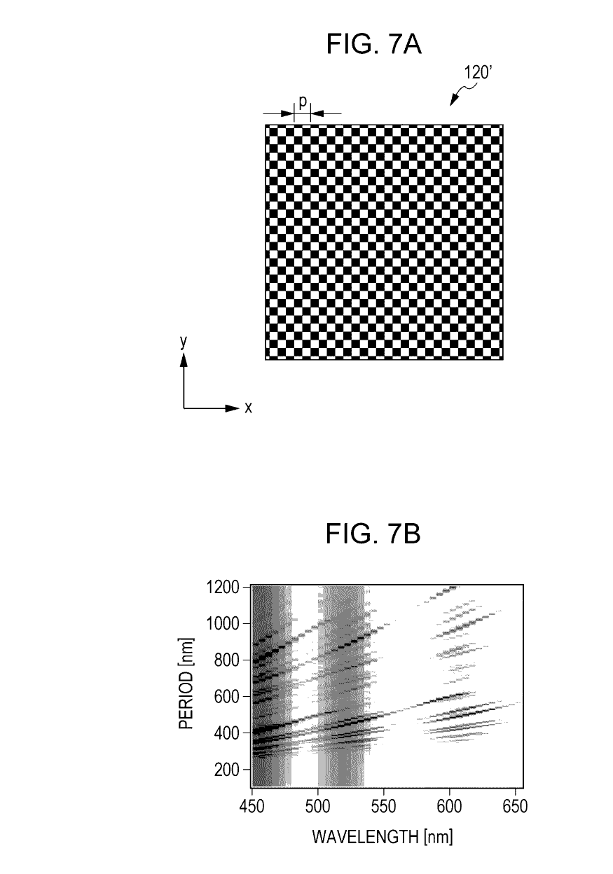

The effect of a two-dimensional periodic structure has also been studied. FIG. 7A is a partial plan view of a two-dimensional periodic structure 120′ including recesses and projections arranged in both the x direction and the y direction. In FIG. 7A, black regions represent projections, and white regions represent recesses. For a two-dimensional periodic structure, both the diffraction in the x direction and the diffraction in the y direction have to be taken into account. Although the diffraction only in the x or y direction is similar to that in a one-dimensional periodic structure, a two-dimensional periodic structure can be expected to give different results from the one-dimensional periodic structure because diffraction also occurs in a direction containing both an x component and a y component (for example, at an angle of 45 degrees). FIG. 7B shows the calculation results of enhancement of light for the two-dimensional periodic structure. The calculations were performed under the same conditions as in FIG. 2 except for the type of periodic structure. As shown in FIG. 7B, peaks matching the peaks for the TE mode in FIG. 6 were observed in addition to peaks matching the peaks for the TM mode in FIG. 2. These results demonstrate that the two-dimensional periodic structure also converts and outputs the TE mode by diffraction. For a two-dimensional periodic structure, diffraction that simultaneously satisfies the first-order diffraction conditions in both the x direction and the y direction also has to be taken into account. Such diffracted light is emitted at an angle corresponding to √2 times (that is, 2^{1/2} times) the period p. Thus, peaks will occur at √2 times the period p in addition to peaks that occur in a one-dimensional periodic structure. Such peaks are also observed in FIG. 7B.

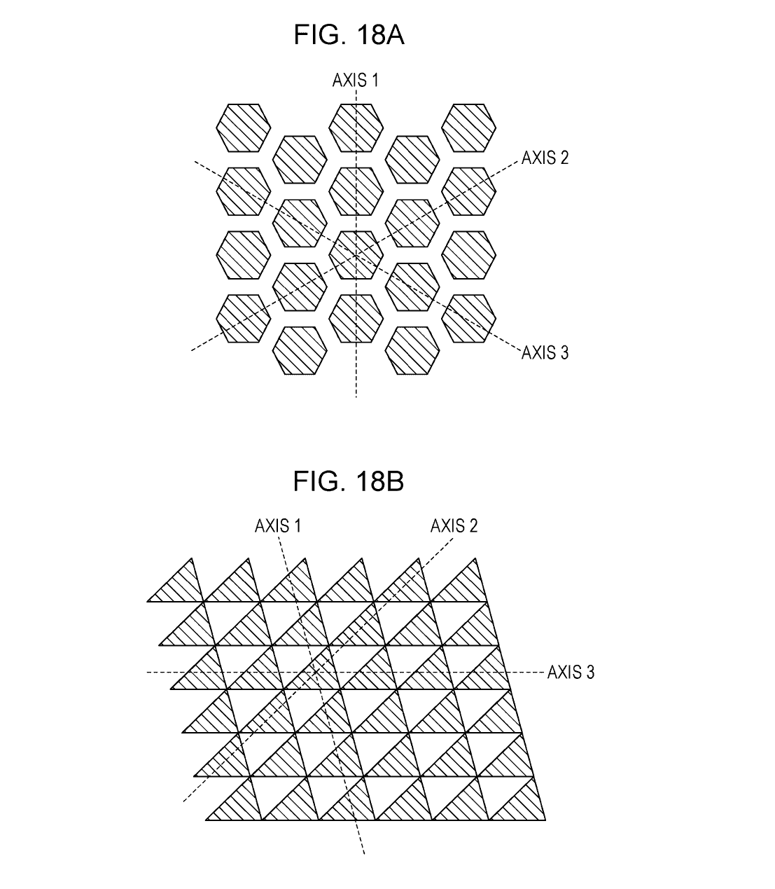

The two-dimensional periodic structure does not have to be a square grid structure having equal periods in the x direction and the y direction, as illustrated in FIG. 7A, but may be a hexagonal grid structure, as illustrated in FIG. 18A, or a triangular grid structure, as illustrated in FIG. 18B. The two-dimensional periodic structure may have different periods in different directions (for example, in the x direction and the y direction for a square grid structure).

In this embodiment, as demonstrated above, light in a characteristic quasi-guided mode formed by the periodic structure and the photoluminescent layer can be selectively emitted only in the front direction through diffraction by the periodic structure. With this structure, the photoluminescent layer can be excited with excitation light, such as ultraviolet light or blue light, to emit directional light.

### 5. STUDY ON CONSTRUCTIONS OF PERIODIC STRUCTURE AND PHOTOLUMINESCENT LAYER

The effects of changes in various conditions such as the constructions and refractive indices of the periodic structure and the photoluminescent layer will now be described.

### 5-1. Refractive Index of Periodic Structure

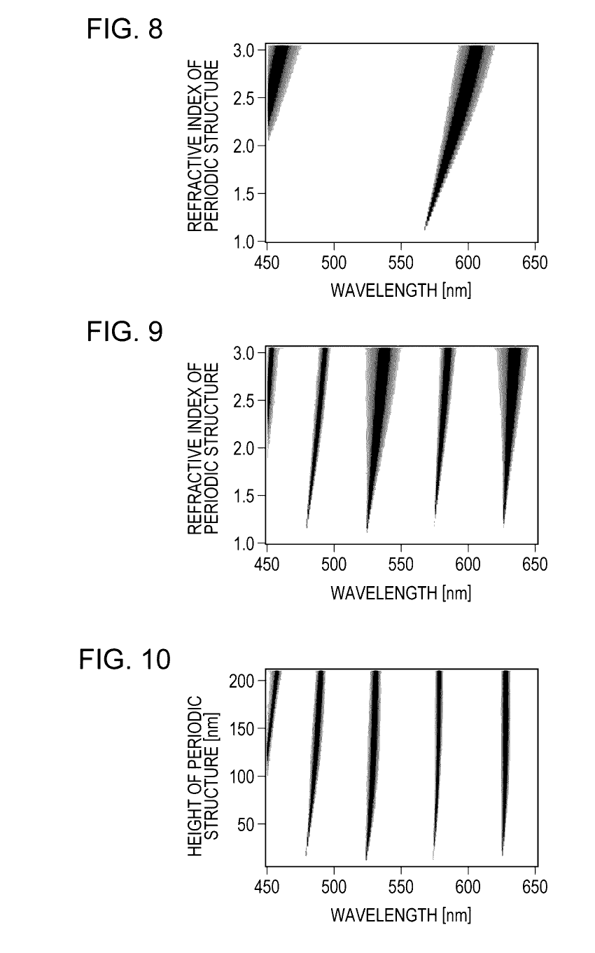

The refractive index of the periodic structure has been studied. In the calculations performed herein, the photoluminescent layer had a thickness of 200 nm and a refractive index n_{wav} of 1.8, the periodic structure was a one-dimensional periodic structure uniform in the y direction, as illustrated in FIG. 1A, and had a height of 50 nm and a period of 400 nm, and the polarization of light was the TM mode, which has an electric field component parallel to the y direction. FIG. 8 shows the calculation results of enhancement of light emitted in the front direction with varying emission wavelengths and varying refractive indices of the periodic structure. FIG. 9 shows the results obtained under the same conditions except that the photoluminescent layer had a thickness of 1,000 nm.

The results show that the photoluminescent layer having a thickness of 1,000 nm (FIG. 9) results in a smaller shift in the wavelength at which the light intensity is highest (the wavelength is hereinafter referred to as a peak wavelength) with the change in the refractive index of the periodic structure than the photoluminescent layer having a thickness of 200 nm (FIG. 8). This is because the quasi-guided mode is more affected by the refractive index of the periodic structure as the photoluminescent layer is thinner. Specifically, a periodic structure having a higher refractive index increases the effective refractive index and thus shifts the peak wavelength toward longer wavelengths, and this effect is more noticeable as the photoluminescent layer is thinner. The effective refractive index is determined by the refractive index of a medium present in the region where the electric field of a quasi-guided mode is distributed.

The results also show that a periodic structure having a higher refractive index results in a broader peak and lower intensity. This is because a periodic structure having a higher refractive index emits light in a quasi-guided mode at a higher rate and is therefore less effective in confining light, that is, has a lower Q value. To maintain high peak intensity, a structure may be employed in which light is moderately emitted using a quasi-guided mode that is effective in confining light (that is, has a high Q value). This means that it is undesirable to use a periodic structure formed of a material having a much higher refractive index than the photoluminescent layer. Thus, in order to increase the peak intensity and Q value, the refractive index of a dielectric material constituting the periodic structure (that is, the light-transmissive layer) can be lower than or similar to the refractive index of the photoluminescent layer. This is also true if the photoluminescent layer contains materials other than photoluminescent materials.

### 5-2. Height of Periodic Structure

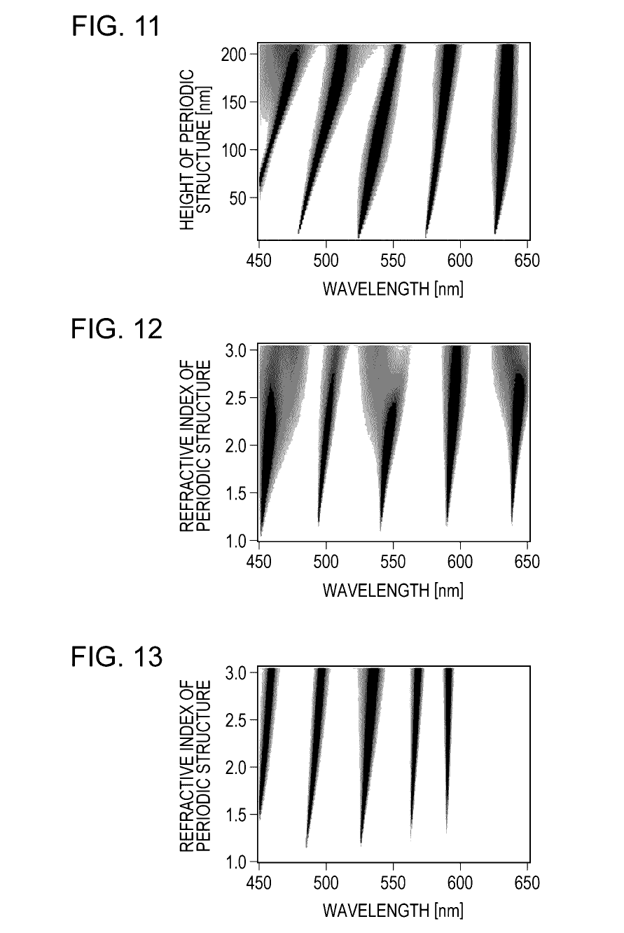

The height of the periodic structure has been studied. In the calculations performed herein, the photoluminescent layer had a thickness of 1,000 nm and a refractive index n_{wav} of 1.8, the periodic structure was a one-dimensional periodic structure uniform in the y direction, as illustrated in FIG. 1A, and had a refractive index nₚ of 1.5 and a period of 400 nm, and the polarization of the light was the TM mode, which has an electric field component parallel to the y direction. FIG. 10 shows the calculation results of enhancement of light emitted in the front direction with varying emission wavelengths and varying heights of the periodic structure. FIG. 11 shows the results of calculations performed under the same conditions except that the periodic structure has a refractive index nₚ of 2.0. Whereas the results in FIG. 10 show that the peak intensity and the Q value (that is, the peak line width) do not change when the periodic structure has at least a certain height, the results in FIG. 11 show that the peak intensity and the Q value decrease with increasing height of the periodic structure. If the refractive index n_{wav} of the photoluminescent layer is higher than the refractive index nₚ of the periodic structure (FIG. 10), light is totally reflected, and only a leaking (evanescent) portion of the electric field of a quasi-guided mode interacts with the periodic structure. If the periodic structure has a sufficiently large height, the influence of the interaction between the evanescent portion of the electric field and the periodic structure remains constant irrespective of the height. In contrast, if the refractive index n_{wav} of the photoluminescent layer is lower than the refractive index nₚ of the periodic structure (FIG. 11), light reaches the surface of the periodic structure without being totally reflected and is therefore more influenced by the periodic structure with a larger height. As shown in FIG. 11, a height of approximately 100 nm is sufficient, and the peak intensity and the Q value decrease above a height of 150 nm. Thus, if the refractive index n_{wav} of the photoluminescent layer is lower than the refractive index nₚ of the periodic structure, the periodic structure may have a height of 150 nm or less to achieve a high peak intensity and Q value.

### 5-3. Polarization Direction

The polarization direction has been studied. FIG. 12 shows the results of calculations performed under the same conditions as in FIG. 9 except that the polarization of light was in the TE mode, which has an electric field component perpendicular to the y direction. The TE mode is more influenced by the periodic structure than the TM mode because the electric field of a quasi-guided mode leaks more largely in the TE mode than in the TM mode. Thus, the peak intensity and the Q value decrease more significantly in the TE mode than in the TM mode if the refractive index nₚ of the periodic structure is higher than the refractive index n_{wav} of the photoluminescent layer.

### 5-4. Refractive Index of Photoluminescent Layer

The refractive index of the photoluminescent layer has been studied. FIG. 13 shows the results of calculations performed under the same conditions as in FIG. 9 except that the photoluminescent layer had a refractive index n_{wav} of 1.5. The results for the photoluminescent layer having a refractive index n_{wav} of 1.5 are similar to the results in FIG. 9. However, light having a wavelength of 600 nm or more was not emitted in the front direction. This is because, from the formula (10), λ₀<n_{wav}×p/m=1.5×400 nm/1=600 nm.

The above analysis demonstrates that a high peak intensity and Q value can be achieved if the periodic structure has a refractive index lower than or similar to the refractive index of the photoluminescent layer or if the periodic structure has a higher refractive index than the photoluminescent layer and a height of 150 nm or less.

### 6. MODIFIED EXAMPLES

Modified examples of the present embodiment will be described below.

### 6-1. Structure Including Substrate

As described above, the light-emitting device may have a structure in which the photoluminescent layer 110 and the periodic structure 120 are formed on the transparent substrate 140, as illustrated in FIGS. 1C and 1D. Such a light-emitting device 100a may be produced by forming a thin film of the photoluminescent material for the photoluminescent layer 110 (optionally containing a matrix material; the same applies hereinafter) on the transparent substrate 140 and then forming the periodic structure 120 thereon. In this structure, the refractive index nₛ of the transparent substrate 140 has to be lower than or equal to the refractive index n_{wav} of the photoluminescent layer 110 so that the photoluminescent layer 110 and the periodic structure 120 function to emit light in a particular direction. If the transparent substrate 140 is provided in contact with the photoluminescent layer 110, the period p has to be set to satisfy the formula (15), which is given by replacing the refractive index nₒᵤₜ of the output medium in the formula (10) by nₛ.

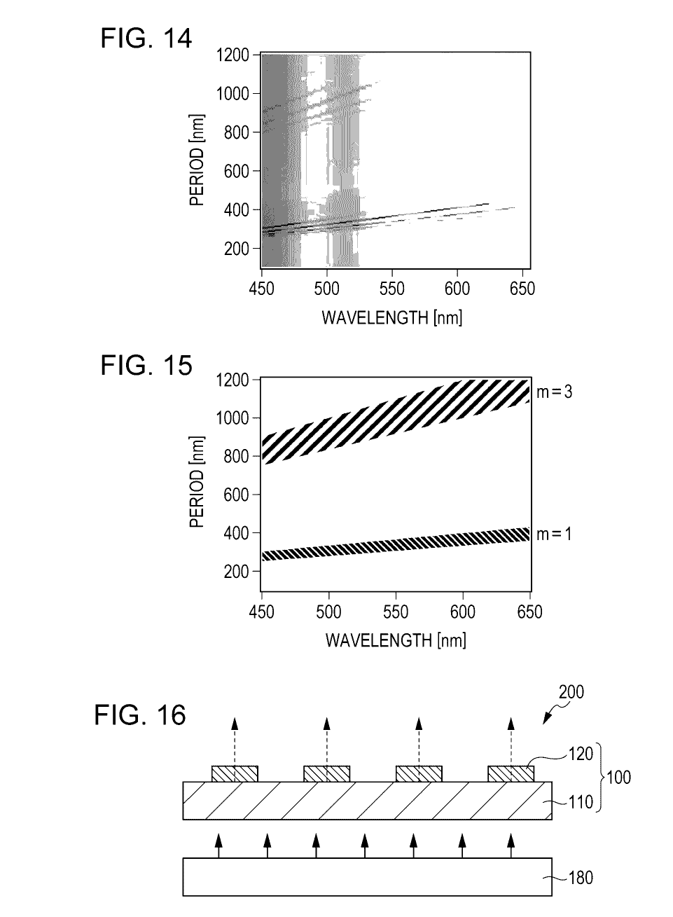

To demonstrate this, calculations were performed under the same conditions as in FIG. 2 except that the photoluminescent layer 110 and the periodic structure 120 were located on a transparent substrate 140 having a refractive index of 1.5. FIG. 14 shows the calculation results. As in the results in FIG. 2, light intensity peaks are observed at particular periods for each wavelength, although the ranges of periods where peaks appear differ from those in FIG. 2. FIG. 15 is a graph illustrating the condition represented by the formula (15), which is given by substituting nₒᵤₜ=nₛ into the formula (10). In FIG. 14, light intensity peaks are observed in the regions corresponding to the ranges shown in FIG. 15.

Thus, for the light-emitting device 100a, in which the photoluminescent layer 110 and the periodic structure 120 are located on the transparent substrate 140, a period p that satisfies the formula (15) is effective, and a period p that satisfies the formula (13) is significantly effective.

### 6-2. Light-Emitting Apparatus Including Excitation Light Source

FIG. 16 is a schematic view of a light-emitting apparatus 200 including the light-emitting device 100 illustrated in FIGS. 1A and 1B and a light source 180 that emits excitation light to the photoluminescent layer 110. In this embodiment, as described above, the photoluminescent layer can be excited with excitation light, such as ultraviolet light or blue light, and emit directional light. The light-emitting apparatus 200 including the light source 180 that can emit such excitation light can emit directional light. Although the wavelength of excitation light emitted from the light source 180 is typically in the ultraviolet or blue range, it is not necessarily within these ranges, but may be determined depending on the photoluminescent material for the photoluminescent layer 110. Although the light source 180 illustrated in FIG. 16 is configured to direct excitation light into the bottom surface of the photoluminescent layer 110, it may be configured otherwise, for example, to direct excitation light into the top surface of the photoluminescent layer 110. Excitation light may be directed at an angle (that is, obliquely) with respect to a direction perpendicular to a main surface (the top surface or the bottom surface) of the photoluminescent layer 110. Excitation light directed obliquely so as to be totally reflected in the photoluminescent layer 110 can more efficiently induce light emission.

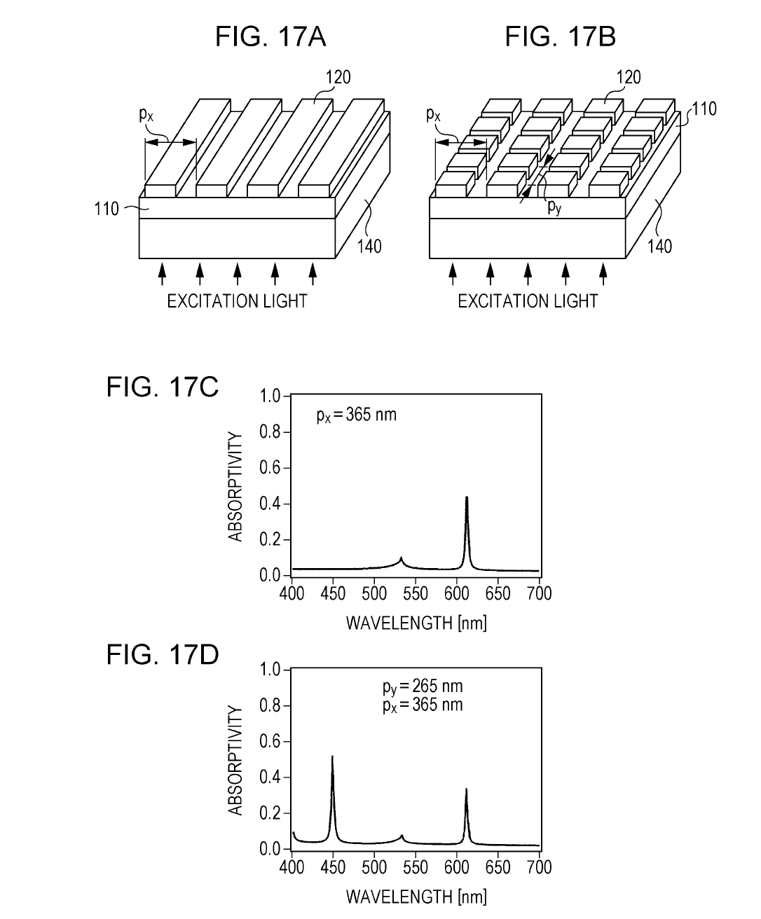

Excitation light may be coupled to a quasi-guided mode to efficiently emit light. FIGS. 17A to 17D illustrate such a method. In this example, as in the structure illustrated in FIGS. 1C and 1D, the photoluminescent layer 110 and the periodic structure 120 are formed on the transparent substrate 140. As illustrated in FIG. 17A, the period pₓ in the x direction is first determined so as to enhance light emission. As illustrated in FIG. 17B, the period p_{y} in the y direction is then determined so as to couple excitation light to a quasi-guided mode. The period pₓ is determined so as to satisfy the condition given by replacing p by pₓ in the formula (10). The period p_{y} is determined so as to satisfy the formula (16): wherein m is an integer of 1 or more, _{Xex} denotes the wavelength of excitation light, and nₒᵤₜ denotes the refractive index of a medium having the highest refractive index of the media in contact with the photoluminescent layer 110 except the periodic structure 120.

$$\frac{m {λ}_{ex}}{{n}_{wav}} < {p}_{y} < \frac{m {λ}_{ex}}{{n}_{out}} \qquad ( 16 )$$

In the example in FIG. 17B, nₒᵤₜ denotes the refractive index nₛ of the transparent substrate 140. For a structure including no transparent substrate 140, as illustrated in FIG. 16, nₒᵤₜ denotes the refractive index of air (approximately 1.0).

In particular, excitation light can be more effectively converted into a quasi-guided mode if m=1, that is, if the period p_{y} is determined so as to satisfy the formula (17):

$$\frac{{λ}_{ex}}{{n}_{wav}} < {p}_{y} < \frac{{λ}_{ex}}{{n}_{out}} \qquad ( 17 )$$

Thus, excitation light can be converted into a quasi-guided mode if the period p_{y} is set to satisfy the condition represented by the formula (16) (particularly, the condition represented by the formula (17)). As a result, the photoluminescent layer 110 can efficiently absorb excitation light having the wavelength λₑₓ.

FIGS. 17C and 17D are the calculation results of the proportion of absorbed light to light incident on the structures shown in FIGS. 17A and 17B, respectively, for each wavelength. In these calculations, pₓ=365 nm, p_{y}=265 nm, the photoluminescent layer 110 had an emission wavelength λ of about 600 nm, excitation light had a wavelength λₑₓ of about 450 nm, and the photoluminescent layer 110 had an extinction coefficient of 0.003. FIG. 17D shows high absorptivity not only for light emitted from the photoluminescent layer 110 but also for excitation light of approximately 450 nm. This indicates that incident light is effectively converted into a quasi-guided mode and thereby increases the proportion of light absorbed into the photoluminescent layer 110. The photoluminescent layer 110 also has high absorptivity for the emission wavelength, that is, approximately 600 nm. This indicates that light having a wavelength of approximately 600 nm incident on this structure is similarly effectively converted into a quasi-guided mode. The periodic structure 120 illustrated in FIG. 17B is a two-dimensional periodic structure including structures having different periods (periodic components) in the x direction and the y direction. Such a two-dimensional periodic structure including multiple periodic components allows for high excitation efficiency and high output intensity. Although the excitation light is incident on the transparent substrate 140 in FIGS. 17A and 17B, the same effect can be achieved if the excitation light is incident on the periodic structure 120.

Also available are two-dimensional periodic structures including periodic components as illustrated in FIGS. 18A and 18B. The structure illustrated in FIG. 18A includes periodically arranged projections or recesses having a hexagonal planar shape. The structure illustrated in FIG. 18B includes periodically arranged projections or recesses having a triangular planar shape. These structures have major axes (axes 1 to 3 in these examples) that can be assumed to be periodic. Thus, the structures can have different periods in different axial directions. These periods may be set to increase the directionality of light beams of different wavelengths or to efficiently absorb excitation light. In any case, each period is set to satisfy the condition corresponding to the formula (10).

### 6-3. Periodic Structure on Transparent Substrate

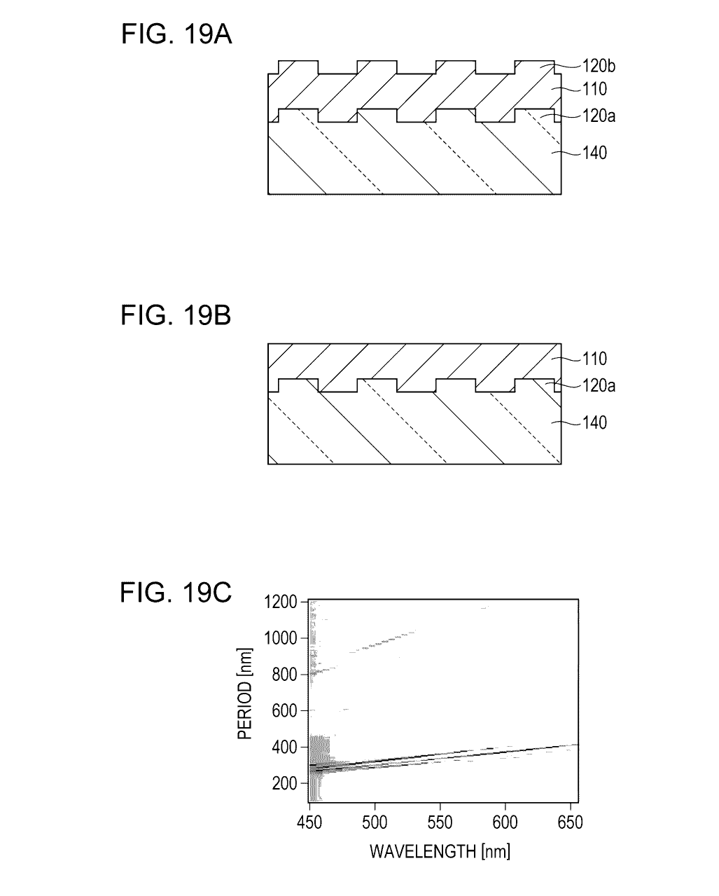

As illustrated in FIGS. 19A and 19B, a periodic structure 120a may be formed on a transparent substrate 140, and a photoluminescent layer 110 may be located on the periodic structure. In the example in FIG. 19A, the photoluminescent layer 110 is formed along the texture of the periodic structure 120a on the transparent substrate 140. As a result, a periodic structure 120b with the same period as the textured periodic structure is formed on the photoluminescent layer 110. In the example in FIG. 19B, the surface of the photoluminescent layer 110 is flattened. In these examples, directional light emission can be achieved by setting the period p of the periodic structure 120a so as to satisfy the formula (15).

To verify the effect of these structures, enhancement of light emitted from the structure illustrated in FIG. 19A in the front direction was calculated with varying emission wavelengths and varying periods of the periodic structure. In these calculations, the photoluminescent layer 110 had a thickness of 1,000 nm and a refractive index n_{wav} of 1.8, the periodic structure 120a was a one-dimensional periodic structure uniform in the y direction and had a height of 50 nm, a refractive index nₚ of 1.5, and a period of 400 nm, and the polarization of light was in the TM mode, which has an electric field component parallel to the y direction. FIG. 19C shows the calculation results. Also in these calculations, light intensity peaks were observed at the periods that satisfy the condition represented by the formula (15).

### 6-4. Powder

These embodiments show that light of any wavelength can be enhanced by adjusting the period of the periodic structure and/or the thickness of the photoluminescent layer. For example, if the structure illustrated in FIGS. 1A and 1B is formed from a photoluminescent material that emits light over a wide wavelength range, only light having a certain wavelength can be enhanced. The structure of the light-emitting device 100 as illustrated in FIGS. 1A and 1B may be provided in powder form for use as a fluorescent material. Alternatively, the light-emitting device 100 as illustrated in FIGS. 1A and 1B may be embedded in resin or glass.

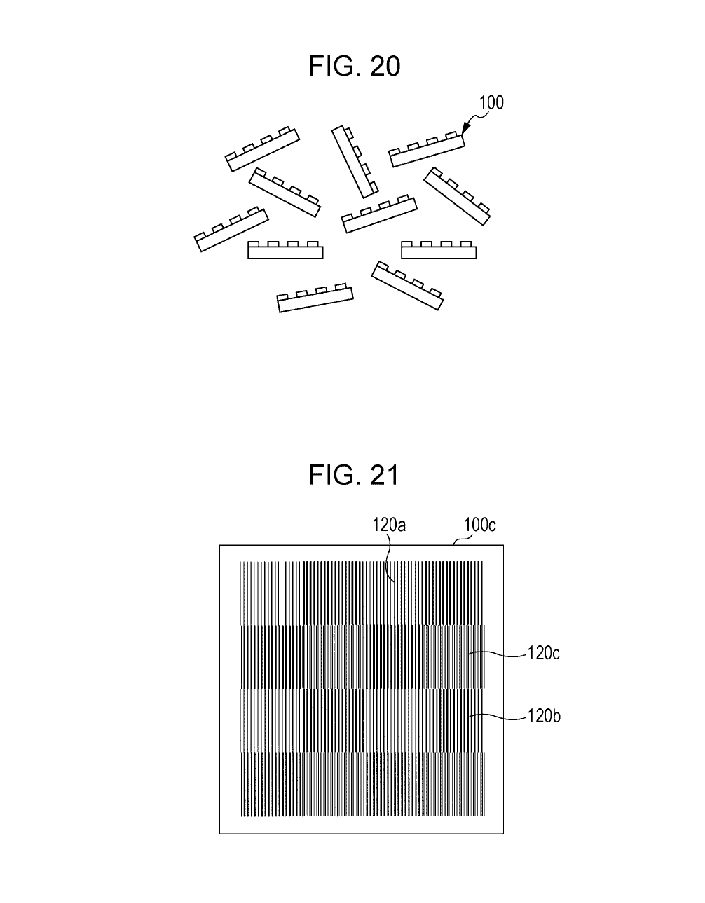

The single structure as illustrated in FIGS. 1A and 1B can emit only light having a certain wavelength in a particular direction and is therefore not suitable for light having a wide wavelength spectrum, such as white light. As shown in FIG. 20, light-emitting devices 100 that differ in the conditions such as the period of the periodic structure and the thickness of the photoluminescent layer may be mixed in powder form to provide a light-emitting apparatus with a wide wavelength spectrum. In such a case, the individual light-emitting devices 100 have sizes of, for example, several micrometers to several millimeters in one direction and can include, for example, one- or two-dimensional periodic structures with several periods to several hundreds of periods.

6-5. Array of Structures with Different Periods

FIG. 21 is a plan view of a two-dimensional array of periodic structures having different periods on a photoluminescent layer. In this example, three types of periodic structures 120a, 120b, and 120c are arranged without any space therebetween. The periods of the periodic structures 120a, 120b, and 120c are set to emit, for example, light in the red, green, and blue wavelength ranges, respectively, in the front direction. Such structures having different periods can be arranged on the photoluminescent layer to emit directional light having a wide wavelength spectrum. The periodic structures are not necessarily formed as described above, but may be formed in any manner.

### 6-6. Layered Structure

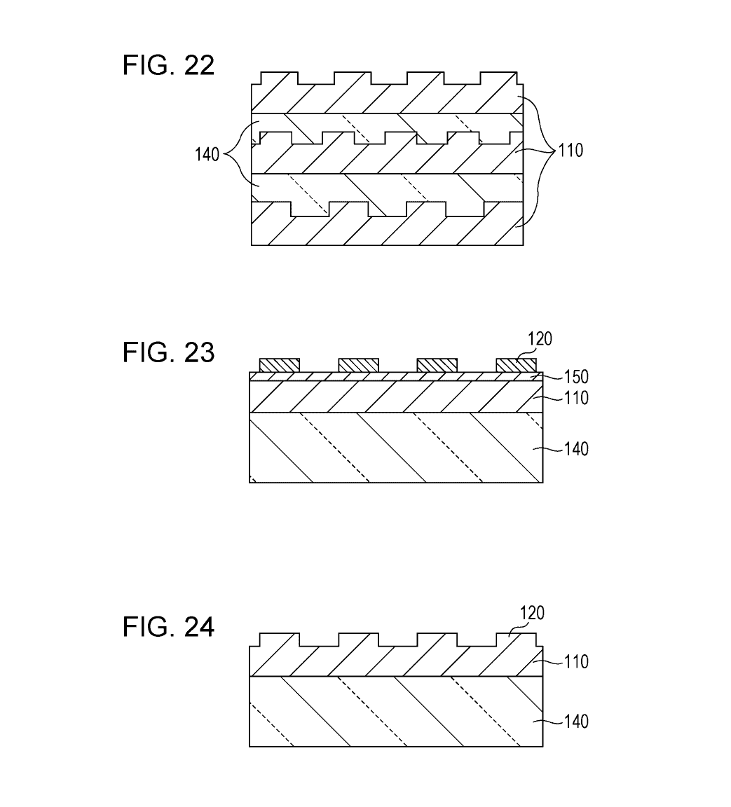

FIG. 22 illustrates a light-emitting device including photoluminescent layers 110 each having a textured surface. A transparent substrate 140 is located between the photoluminescent layers 110. The texture on each of the photoluminescent layers 110 corresponds to the periodic structure or the submicron structure. The example in FIG. 22 includes three periodic structures having different periods. The periods of these periodic structures are set to emit light in the red, green, and blue wavelength ranges in the front direction. The photoluminescent layer 110 in each layer is formed of a material that emits light having the color corresponding to the period of the periodic structure in that layer. Thus, periodic structures having different periods can be stacked on top of each other to emit directional light having a wide wavelength spectrum.

The number of layers and the constructions of the photoluminescent layer 110 and the periodic structure in each layer are not limited to those described above, but may be selected as appropriate. For example, for a structure including two layers, first and second photoluminescent layers are formed opposite each other with a light-transmissive substrate therebetween, and first and second periodic structures are formed on the surfaces of the first and second photoluminescent layers, respectively. In such a case, the first photoluminescent layer and the first periodic structure satisfy the condition represented by the formula (15), and the second photoluminescent layer and the second periodic structure satisfy the condition represented by the formula (15). For a structure including three or more layers, the photoluminescent layer and the periodic structure in each layer satisfy the condition represented by the formula (15). The positional relationship between the photoluminescent layers and the periodic structures in FIG. 22 may be reversed. Although the layers have different periods in FIG. 22, all the layers may have the same period. In such a case, although the spectrum cannot be broadened, the emission intensity can be increased.

### 6-7. Structure Including Protective Layer

FIG. 23 is a cross-sectional view of a structure including a protective layer 150 between the photoluminescent layer 110 and the periodic structure 120. The protective layer 150 may be provided to protect the photoluminescent layer 110. However, if the protective layer 150 has a lower refractive index than the photoluminescent layer 110, the electric field of light leaks into the protective layer 150 only by about half the wavelength. Thus, if the protective layer 150 has a thickness greater than the wavelength, no light reaches the periodic structure 120. As a result, there is no quasi-guided mode, and the function of emitting light in a particular direction cannot be achieved. If the protective layer 150 has a refractive index higher than or similar to that of the photoluminescent layer 110, light reaches the interior of the protective layer 150; therefore, there is no limitation on the thickness of the protective layer 150. Nevertheless, a thinner protective layer 150 is desirable because more light is emitted if most of the portion in which light is guided (this portion is hereinafter referred to as a “waveguide layer”) is formed of a photoluminescent material. The protective layer 150 may be formed of the same material as the periodic structure (light-transmissive layer) 120. In such a case, the light-transmissive layer 120 having the periodic structure also functions as a protective layer. The light-transmissive layer 120 desirably has a lower refractive index than the photoluminescent layer 110.

### 7. MATERIALS

Directional light emission can be achieved if the photoluminescent layer (or waveguide layer) and the periodic structure are formed of materials that satisfy the above conditions. The periodic structure may be formed of any material. However, a photoluminescent layer (or waveguide layer) or a periodic structure formed of a medium with high light absorption is less effective in confining light and therefore results in a lower peak intensity and Q value. Thus, the photoluminescent layer (or waveguide layer) and the periodic structure may be formed of media with relatively low light absorption.

For example, the periodic structure may be formed of a dielectric material having low light absorptivity. Examples of candidate materials for the periodic structure include magnesium fluoride (MgF₂), lithium fluoride (LiF), calcium fluoride (CaF₂), quartz (SiO₂), glasses, resins, magnesium oxide (MgO), indium tin oxide (ITO), titanium oxide (TiO₂), silicon nitride (SiN), tantalum pentoxide (Ta₂O₅), zirconia (ZrO₂), zinc selenide (ZnSe), and zinc sulfide (ZnS). To form a periodic structure having a lower refractive index than the photoluminescent layer, as described above, MgF₂, LiF, CaF₂, SiO₂, glasses, and resins can be used, which have refractive indices of approximately 1.3 to 1.5.

The term “photoluminescent material” encompasses fluorescent materials and phosphorescent materials in a narrow sense, encompasses inorganic materials and organic materials (for example, dyes), and encompasses quantum dots (that is, tiny semiconductor particles). In general, fluorescent materials containing an inorganic host material tend to have a higher refractive index. Examples of fluorescent materials that emit blue light include M₁₀(PO₄)₆Cl₂:Eu²⁺ (wherein M is at least one element selected from Ba, Sr, and Ca), BaMgAl₁₀O₁₇:Eu²⁺, M₃MgSi₂O₈:Eu²⁺ (wherein M is at least one element selected from Ba, Sr, and Ca), and M₅SiO₄Cl₆:Eu²⁺ (wherein M is at least one element selected from Ba, Sr, and Ca). Examples of fluorescent materials that emit green light include M₂MgSi₂O₇:Eu²⁺ (wherein M is at least one element selected from Ba, Sr, and Ca), SrSi₅AlO₂N₇:Eu²⁺, SrSi₂O₂N₂:Eu²⁺, BaAl₂O₄:Eu²⁺, BaZrSi₃O₉:Eu²⁺, M₂SiO₄:Eu²⁺ (wherein M is at least one element selected from Ba, Sr, and Ca), BaSi₃O₄N₂:Eu²⁺, Ca₈Mg(SiO₄)₄Cl₂:Eu²⁺, Ca₃SiO₄Cl₂:Eu²⁺, CaSi₁₂₋₍ₘ₊ₙ₎Al₍ₘ₊ₙ₎OₙN₁₆₋ₙ:Ce³⁺, and β-SiAlON:Eu²⁺. Examples of fluorescent materials that emit red light include CaAlSiN₃:Eu²⁺, SrAlSi₄O₇:Eu²⁺, M₂Si₅N₈:Eu²⁺ (wherein M is at least one element selected from Ba, Sr, and Ca), MSiN₂:Eu²⁺ (wherein M is at least one element selected from Ba, Sr, and Ca), MSi₂O₂N₂:Yb²⁺ (wherein M is at least one element selected from Sr and Ca), Y₂O₂S:Eu³⁺, Sm³⁺, La₂O₂S:Eu³⁺, Sm³⁺, CaWO₄:Li¹⁺, Eu³⁺, Sm³⁺, M₂SiS₄:Eu²⁺ (wherein M is at least one element selected from Ba, Sr, and Ca), and M₃SiO₅:Eu²⁺ (wherein M is at least one element selected from Ba, Sr, and Ca). Examples of fluorescent materials that emit yellow light include Y₃Al₅O₁₂:Ce³⁺, CaSi₂O₂N₂:Eu²⁺, Ca₃Sc₂Si₃O₁₂:Ce³⁺, CaSc₂O₄:Ce³⁺, α-SiAlON:Eu²⁺, MSi₂O₂N₂:Eu²⁺ (wherein M is at least one element selected from Ba, Sr, and Ca), and M₇(SiO₃)₆Cl₂:Eu²⁺ (wherein M is at least one element selected from Ba, Sr, and Ca).

Examples of quantum dots include materials such as CdS, CdSe, core-shell CdSe/ZnS, and alloy CdSSe/ZnS. Light having various wavelengths can be emitted depending on the material. Examples of matrices for quantum dots include glasses and resins.

The transparent substrate 140, as illustrated in, for example, FIGS. 1C and 1D, is formed of a light-transmissive material having a lower refractive index than the photoluminescent layer 110. Examples of such materials include magnesium fluoride (MgF₂), lithium fluoride (LiF), calcium fluoride (CaF₂), quartz (SiO₂), glasses, and resins. In structures in which excitation light enters the photoluminescent layer 110 without passing through the substrate 140, the substrate 140 is not necessarily transparent.

### 8. PRODUCTION METHOD

Exemplary production methods will be described below.

A method for forming the structure illustrated in FIGS. 1C and 1D includes forming a thin film of the photoluminescent layer 110 on the transparent substrate 140, for example, by evaporation, sputtering, or coating of a fluorescent material, forming a dielectric film, and then patterning the dielectric film, for example, by photolithography to form the periodic structure 120. Alternatively, the periodic structure 120 may be formed by nanoimprinting. As illustrated in FIG. 24, the periodic structure 120 may also be formed by partially processing the photoluminescent layer 110. In such a case, the periodic structure 120 is formed of the same material as the photoluminescent layer 110.

The light-emitting device 100 illustrated in FIGS. 1A and 1B can be manufactured, for example, by fabricating the light-emitting device 100a illustrated in FIGS. 10 and 1D and then stripping the photoluminescent layer 110 and the periodic structure 120 from the substrate 140.

The structure illustrated in FIG. 19A can be produced, for example, by forming the periodic structure 120a on the transparent substrate 140 by a process such as a semiconductor manufacturing process or nanoimprinting and then depositing thereon the material of the photoluminescent layer 110 by a process such as evaporation or sputtering. The structure illustrated in FIG. 19B can be formed by filling the recesses of the periodic structure 120a with the photoluminescent layer 110 by coating.

These production methods are for illustrative purposes only, and the light-emitting devices according to the embodiments of the present disclosure may be produced by other methods.

### 9. EXPERIMENTAL EXAMPLES

The following examples illustrate light-emitting devices produced according to embodiments of the present disclosure.

A sample light-emitting device having the structure as illustrated in FIG. 19A was prepared and evaluated for its properties. The light-emitting device was prepared as described below.

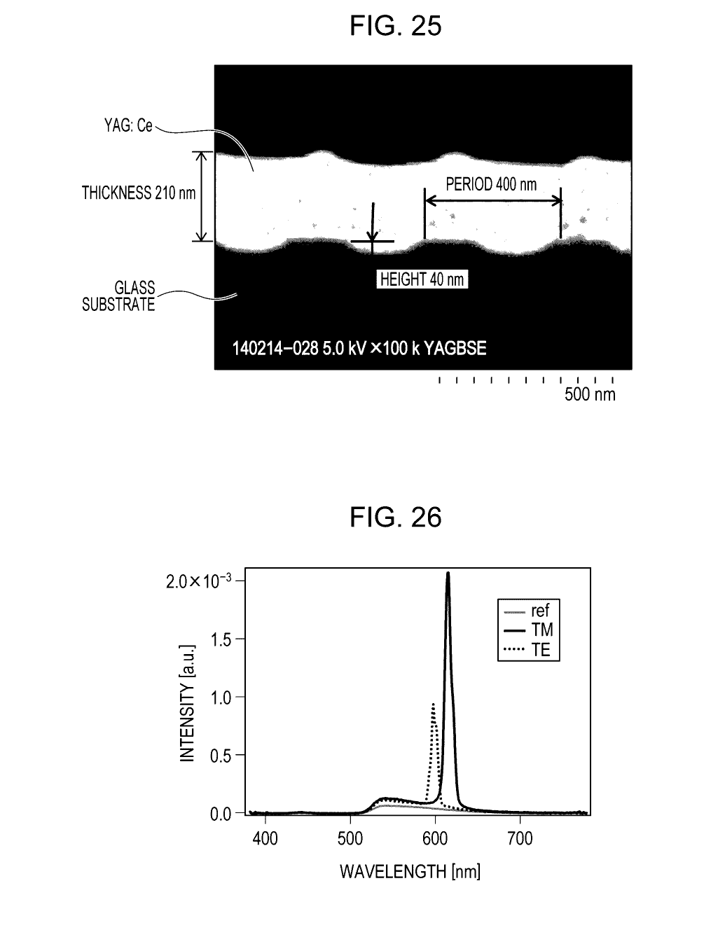

A one-dimensional periodic structure (stripe-shaped projections) having a period of 400 nm and a height of 40 nm was formed on a glass substrate, and a photoluminescent material YAG:Ce was deposited thereon to a thickness of 210 nm. FIG. 25 shows a cross-sectional transmission electron microscopy (TEM) image of the resulting light-emitting device. FIG. 26 shows the measurement results of the spectrum of light emitted from the light-emitting device in the front direction when YAG:Ce was excited with an LED having an emission wavelength of 450 nm. FIG. 26 shows the results (ref) for a light-emitting device including no periodic structure, the results for the TM mode, and the results for the TE mode. The TM mode has a polarization component parallel to the one-dimensional periodic structure. The TE mode has a polarization component perpendicular to the one-dimensional periodic structure. The results show that the intensity of light of a particular wavelength is significantly higher in the presence of the periodic structure than in the absence of the periodic structure. The results also show that the light enhancement effect is greater in the TM mode, which has a polarization component parallel to the one-dimensional periodic structure.

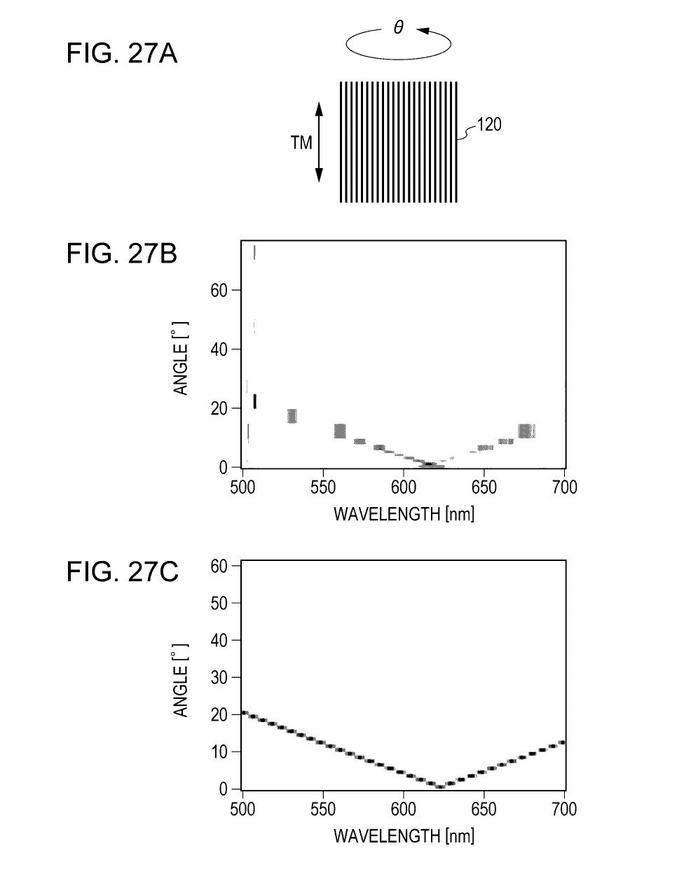

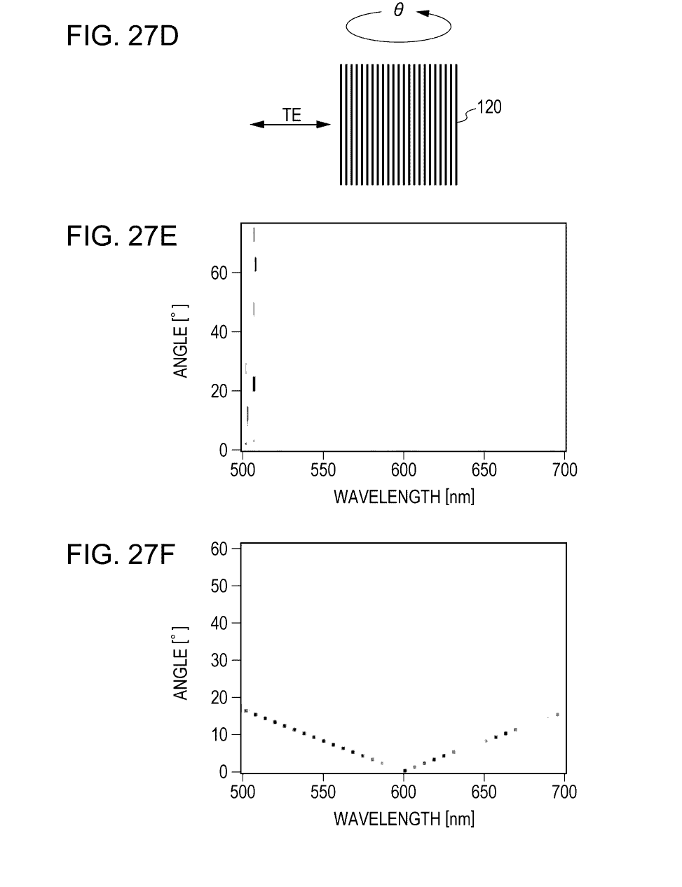

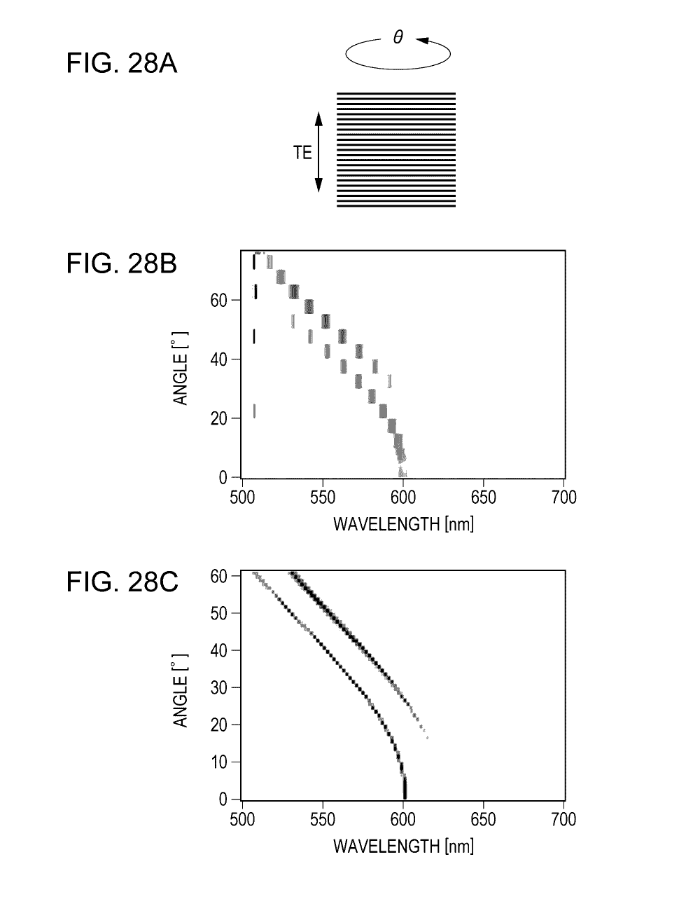

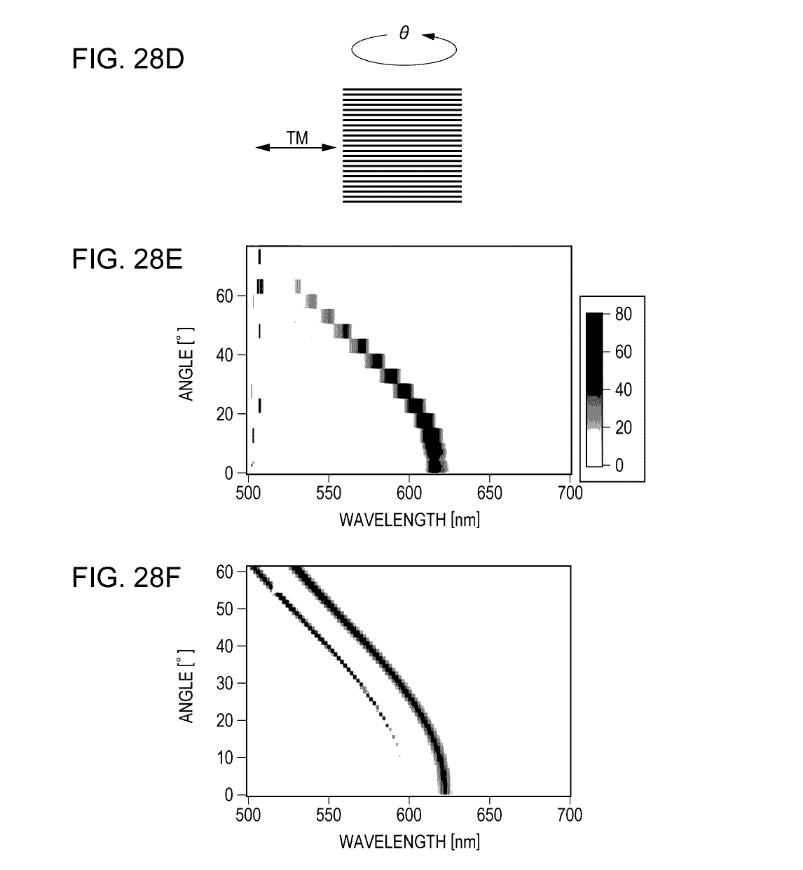

FIGS. 27A to 27F and FIGS. 28A to 28F show the results of measurements and calculations of the angular dependence of the intensity of light emitted from the same sample. FIG. 27A illustrates a light-emitting device that can emit linearly polarized light in the TM mode, rotated about an axis parallel to the line direction of the one-dimensional periodic structure 120. FIGS. 27B and 27C show the results of measurements and calculations for the rotation. FIG. 27D illustrates a light-emitting device that can emit linearly polarized light in the TE mode, rotated about an axis parallel to the line direction of the one-dimensional periodic structure 120. FIGS. 27E and 27F show the results of measurements and calculations for the rotation. FIG. 28A illustrates a light-emitting device that can emit linearly polarized light in the TE mode, rotated about an axis perpendicular to the line direction of the one-dimensional periodic structure 120. FIGS. 28B and 28C show the results of measurements and calculations for the rotation. FIG. 28D illustrates a light-emitting device that can emit linearly polarized light in the TM mode, rotated about an axis perpendicular to the line direction of the one-dimensional periodic structure 120. FIGS. 28E and 28F show the results of measurements and calculations for the rotation.

As is clear from FIGS. 27A to 27F and FIGS. 28A to 28F, the enhancement effect is greater for the TM mode. The wavelength of enhanced light shifts with angle. For example, light having a wavelength of 610 nm is observed only in the TM mode and in the front direction, indicating that the light is directional and polarized. Furthermore, the measurement results and the calculation results match each other in FIGS. 27B and 27C, FIGS. 27E and 27F, FIGS. 28B and 28C, and FIGS. 28E and 28F. Thus, the validity of the above calculations was experimentally demonstrated.

FIG. 29 shows the angular dependence of the intensity of light having a wavelength of 610 nm for rotation about an axis perpendicular to the line direction, as illustrated in FIG. 28D. The results show that the light was significantly enhanced in the front direction and was little enhanced at other angles. The directional angle of light emitted in the front direction is less than 15 degrees. As described above, the directional angle is the angle at which the intensity is 50% of the maximum intensity and is expressed as the angle of one side with respect to the direction with the maximum intensity. The results shown in FIG. 29 demonstrates that directional light emission was achieved. In addition, all the light was in the TM mode, which demonstrates that polarized light emission was simultaneously achieved.

These verification experiments were performed with YAG:Ce, which can emit light over a wide wavelength range. Directional polarized light emission can also be achieved in similar experiments using a photoluminescent material that emits light in a narrow wavelength range. Such a photoluminescent material does not emit light having other wavelengths and can therefore be used to provide a light source that does not emit light in other directions or in other polarized states.

### 10. OTHER MODIFICATIONS

Other modified examples of a light-emitting device and a light-emitting apparatus according to the present disclosure will be described below.

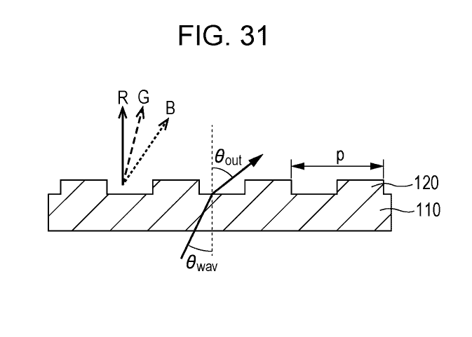

As described above, the wavelength and emission direction of light under the light enhancement effect depend on the submicron structure of a light-emitting device according to the present disclosure. FIG. 31 illustrates a light-emitting device having a periodic structure 120 on a photoluminescent layer 110. The periodic structure 120 is formed of the same material as the photoluminescent layer 110 and is the same as the one-dimensional periodic structure 120 illustrated in FIG. 1A. Light to be enhanced by the one-dimensional periodic structure 120 satisfies p×n_{wav}×sin θ_{wav}−p×nₒᵤₜ×sin θₒᵤₜ=mλ (see the formula (5)), wherein p (nm) denotes the period of the one-dimensional periodic structure 120, n_{wav} denotes the refractive index of the photoluminescent layer 110, nₒᵤₜ denotes the refractive index of an outer medium toward which the light is emitted, θ_{wav} denotes the incident angle on the one-dimensional periodic structure 120, and θₒᵤₜ denotes the angle at which the light is emitted from one-dimensional periodic structure 120 to the outer medium. λ denotes the light wavelength in air, and m is an integer.

The formula can be transformed into θₒᵤₜ=arcsin[(n_{wav}×sin θ_{wav}−mλ/p)/nₒᵤₜ]. Thus, in general, the output angle θₒᵤₜ of light under the light enhancement effect varies with the wavelength λ. Consequently, as schematically illustrated in FIG. 31, the color of visible light varies with the observation direction.

This visual angle dependency can be reduced by determining n_{wav} and nₒᵤₜ so as to make (n_{wav}×sin θ_{wav}−mλ/p)/nₒᵤₜ constant for any wavelength λ. The refractive indices of substances have wavelength dispersion (wavelength dependence). Thus, a material to be selected should have the wavelength dispersion characteristics of n_{wav} and nₒᵤₜ such that (n_{wav}×sin θ_{wav}−mλ/p)/nₒᵤₜ is independent of the wavelength λ. For example, if the outer medium is air, nₒᵤₜ is approximately 1.0 irrespective of the wavelength. Thus, it is desirable that the material of the photoluminescent layer 110 and the one-dimensional periodic structure 120 be a material having narrow wavelength dispersion of the refractive index n_{wav}. It is also desirable that the material have reciprocal dispersion, and the refractive index n_{wav} decrease with decreasing wavelength of light.

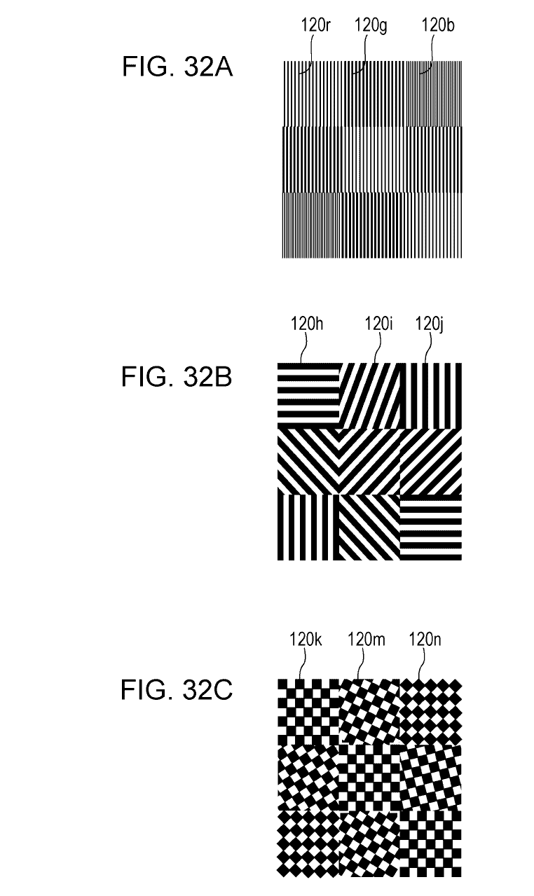

As illustrated in FIG. 32A, an array of periodic structures having different wavelengths at which the light enhancement effect is produced can emit white light. In the example illustrated in FIG. 32A, a periodic structure 120r that can enhance red light (R), a periodic structure 120g that can enhance green light (G), and a periodic structure 120b that can enhance blue light (B) are arranged in a matrix. Each of the periodic structures 120r, 120g, and 120b may be a one-dimensional periodic structure. The projections of the periodic structures 120r, 120g, and 120b are arranged in parallel. Thus, the red light, green light, and blue light have the same polarization characteristics. Light beams of three primary colors emitted from the periodic structures 120r, 120g, and 120b under the light enhancement effect are mixed to produce linearly polarized white light.

Each of the periodic structures 120r, 120g, and 120b arranged in a matrix is referred to as a unit periodic structure (or pixel). The size (the length of one side) of the unit periodic structure may be at least three times the period. It is desirable that the unit periodic structures be not perceived by the human eye in order to produce the color mixing effect. For example, it is desirable that the length of one side be less than 1 mm. Although each of the unit periodic structures is square in FIG. 32A, adjacent periodic structures 120r, 120g, and 120b may be in the shape other than square, such as rectangular, triangular, or hexagonal.

A photoluminescent layer under each of the periodic structures 120r, 120g, and 120b may be the same or may be formed of different photoluminescent materials corresponding to each color of light.

As illustrated in FIG. 32B, the projections of the one-dimensional periodic structures (including periodic structures 120h, 120i, and 120j) may extend in different directions. Light emitted from each of the periodic structures under the light enhancement effect may have the same wavelength or different wavelengths. For example, the same periodic structures arranged as illustrated in FIG. 32B can produce unpolarized light. The periodic structures 120r, 120g, and 120b in FIG. 32A arranged as illustrated in FIG. 32B can produce unpolarized white light as a whole.

As a matter of course, the periodic structures are not limited to one-dimensional periodic structures and may be two-dimensional periodic structures (including periodic structures 120k, 120m, and 120n), as illustrated in FIG. 32C. The period and direction of each of the periodic structures 120k, 120m, and 120n may be the same or different, as described above, and may be appropriately determined as required.

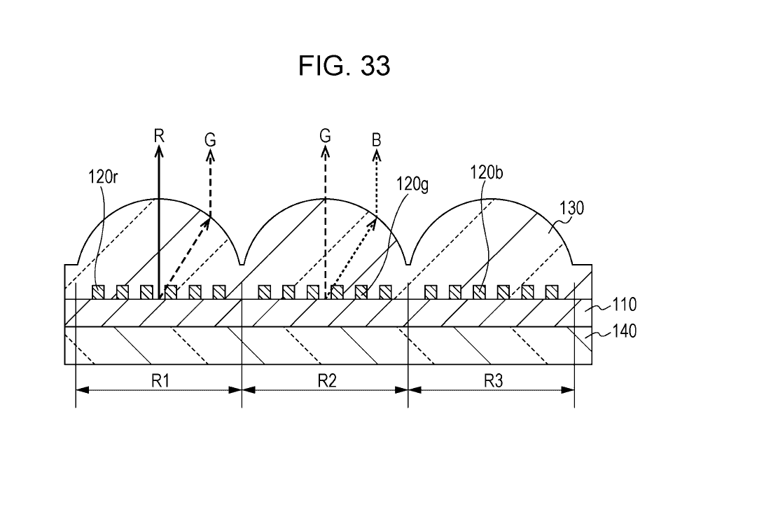

As illustrated in FIG. 33, for example, an array of microlenses 130 may be located on a light emission side of a light-emitting device. The array of microlenses 130 can refract oblique light in the normal direction and thereby produce the color mixing effect.

The light-emitting device illustrated in FIG. 33 includes regions R1, R2, and R3, which include the periodic structures 120r, 120g, and 120b, respectively, illustrated in FIG. 32A. In the region R1, the periodic structure 120r outputs red light R in the normal direction and, for example, outputs green light G in an oblique direction. The microlens 130 refracts the oblique green light G in the normal direction. Consequently, a mixture of red light R and green light G is observed in the normal direction. Thus, the microlenses 130 can reduce difference in light wavelength depending on the angle. Although the microlens array including microlenses corresponding to the periodic structures is described here, another microlens array is also possible. As a matter of course, periodic structures to be tiled are not limited to those described above and may be the same periodic structures or the structures illustrated in FIG. 32B or 32C.

A lenticular lens may also be used as an optical element for refracting oblique light instead of the microlens array. In addition to lenses, prisms may also be used. A prism array may also be used. A prism corresponding to each periodic structure may be arranged. Prisms of any shape may be used. For example, a triangular or pyramidal prism may be used.

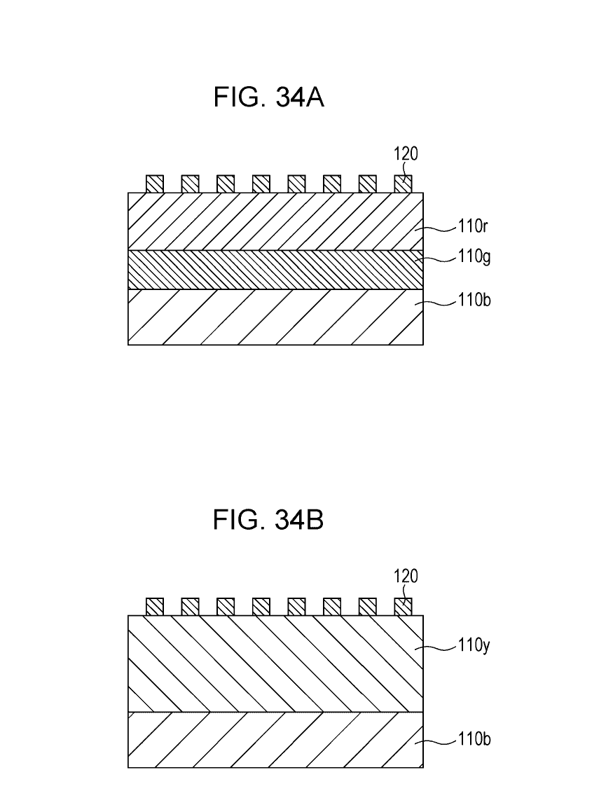

White light (or light having a broad spectral width) may be produced by using the periodic structure described above or a photoluminescent layer as illustrated in FIG. 34A or 34B. As illustrated in FIG. 34A, photoluminescent layers 110b, 110g, and 110r having different emission wavelengths may be stacked to produce white light. The stacking sequence is not limited to that illustrated in the figure. As illustrated in FIG. 34B, a photoluminescent layer 110y that emits yellow light may be located on a photoluminescent layer 110b that emits blue light. The photoluminescent layer 110y may be formed of YAG.

When photoluminescent materials, such as fluorescent dyes, to be mixed with a matrix (host) material are used, photoluminescent materials having different emission wavelengths may be mixed with the matrix material to emit white light from a single photoluminescent layer. Such a photoluminescent layer that can emit white light may be used in tiled unit periodic structures as illustrated in FIGS. 32A to 32C.

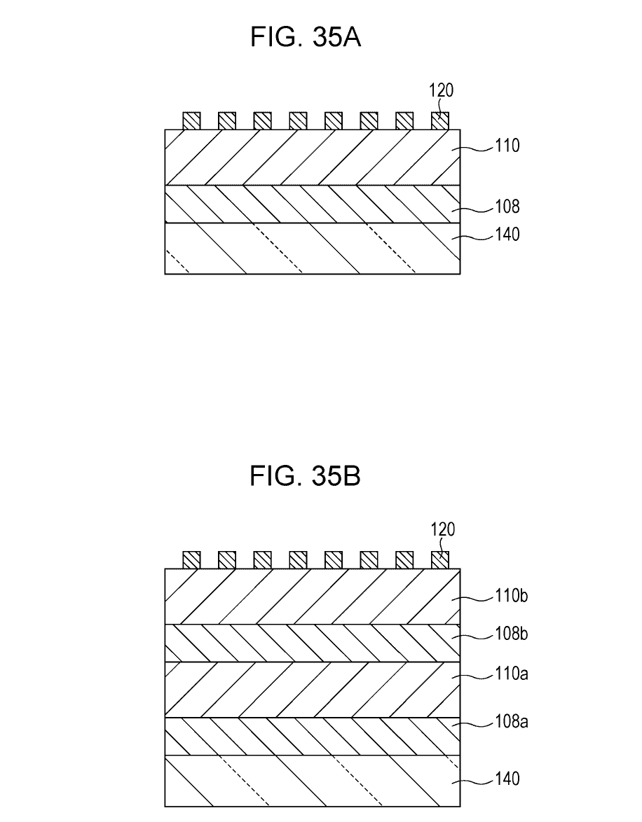

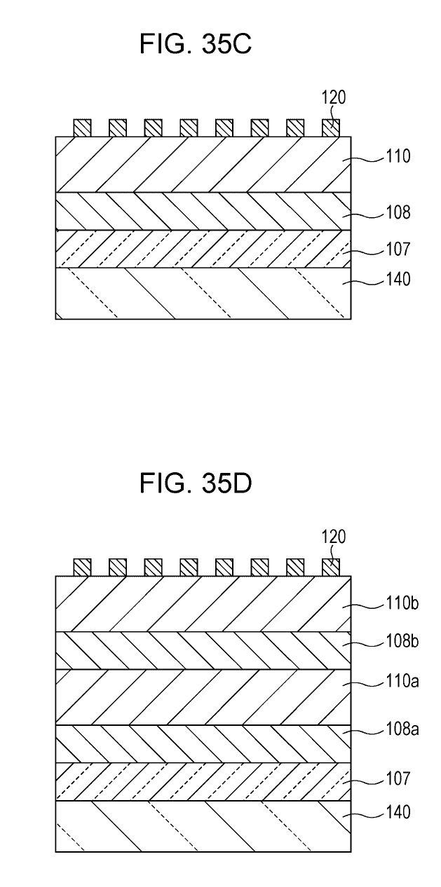

When an inorganic material (for example, YAG) is used as a material of the photoluminescent layer 110, the inorganic material may be subjected to heat treatment at more than 1000° C. in the production process. During the production process, impurities may diffuse from an underlayer (typically, a substrate) and affect the light-emitting properties of the photoluminescent layer 110. In order to prevent impurities from diffusing into the photoluminescent layer 110, a diffusion-barrier layer (barrier layer) 108 may be located under the photoluminescent layer 110, as illustrated in FIGS. 35A to 35D. As illustrated in FIGS. 35A to 35D, the diffusion-barrier layer 108 is located under the photoluminescent layer 110 in the structures described above.

For example, as illustrated in FIG. 35A, the diffusion-barrier layer 108 is located between a substrate 140 and the photoluminescent layer 110. As illustrated in FIG. 35B, when there are photoluminescent layers 110a and 110b, diffusion-barrier layers 108a and 108b are located under the photoluminescent layers 110a and 110b, respectively.

When the substrate 140 has a higher refractive index than the photoluminescent layer 110, a low-refractive-index layer 107 may be formed on the substrate 140, as illustrated in FIGS. 35C and 35D. When the low-refractive-index layer 107 is located on the substrate 140, as illustrated in FIG. 35C, the diffusion-barrier layer 108 is formed between the low-refractive-index layer 107 and the photoluminescent layer 110. As illustrated in FIG. 35D, when there are photoluminescent layers 110a and 110b, diffusion-barrier layers 108a and 108b are located under the photoluminescent layers 110a and 110b, respectively.

The low-refractive-index layer 107 may be formed if the substrate 140 has a refractive index greater than or equal to the refractive index of the photoluminescent layer 110. The low-refractive-index layer 107 has a lower refractive index than the photoluminescent layer 110. The low-refractive-index layer 107 may be formed of MgF₂, LiF, CaF₂, BaF₂, SrF₂, quartz, a resin, or a room-temperature curing glass, such as hydrogen silsesquioxane (HSQ) spin-on glass (SOG). It is desirable that the thickness of the low-refractive-index layer 107 be greater than the light wavelength. For example, the substrate 140 is formed of MgF₂, LiF, CaF₂, BaF₂, SrF₂, a glass (for example, a soda-lime glass), a resin, MgO, MgAl₂O₄, sapphire (Al₂O₃), SrTiO₃, LaAIO₃, TiO₂, Gd₃Ga₅O₁₂, LaSrAlO₄, LaSrGaO₄, LaTaO₃, SrO, yttria-stabilized zirconia (YSZ, ZrO₂.Y₂O₃), YAG, or Tb₃Ga₅O₁₂.

It is desirable that the diffusion-barrier layers 108, 108a, and 108b be selected in a manner that depends on the type of element to be prevented from diffusion. For example, the diffusion-barrier layers 108, 108a, and 108b may be formed of strongly covalent oxide crystals or nitride crystals. Each of the diffusion-barrier layers 108, 108a, and 108b may have a thickness of 50 nm or less.

In structures that include a layer adjacent to the photoluminescent layer 110, such as the diffusion-barrier layer 108 or a crystal growth layer 106 described later, when the adjacent layer has a higher refractive index than the photoluminescent layer 110, the refractive index n_{wav} is the average of the refractive indices of the layer having the higher refractive index and the photoluminescent layer 110 weighted by their respective volume fractions. This situation is optically equivalent to a photoluminescent layer composed of layers of different materials.

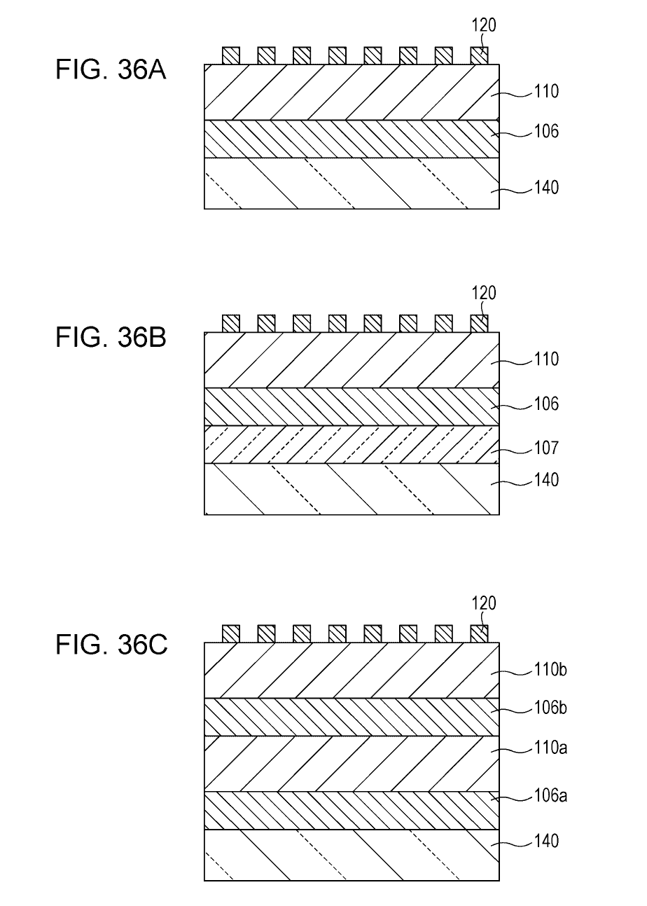

When the photoluminescent layer 110 is formed of an inorganic material, the photoluminescent layer 110 may have poor light-emitting properties due to low crystallinity of the inorganic material. In order to increase the crystallinity of the inorganic material of the photoluminescent layer 110, a crystal growth layer (hereinafter also referred to as a “seed layer”) 106 may be formed under the photoluminescent layer 110, as illustrated in FIG. 36A. The material of the crystal growth layer 106 is lattice-matched to the crystals of the overlying photoluminescent layer 110. It is desirable that the lattice matching be within ±5%. If the substrate 140 has a higher refractive index than the photoluminescent layer 110, the crystal growth layer 106 can advantageously have a lower refractive index than the photoluminescent layer 110.

If the substrate 140 has a higher refractive index than the photoluminescent layer 110, a low-refractive-index layer 107 may be formed on the substrate 140, as illustrated in FIG. 36B. In this case, because the crystal growth layer 106 is in contact with the photoluminescent layer 110, the crystal growth layer 106 is formed on the low-refractive-index layer 107, which is located on the substrate 140. In structures that include photoluminescent layers 110a and 110b, as illustrated in FIG. 36C, crystal growth layers 106a and 106b can be advantageously formed on the photoluminescent layers 110a and 110b, respectively. Each of the crystal growth layers 106, 106a, and 106b may have a thickness of 50 nm or less.

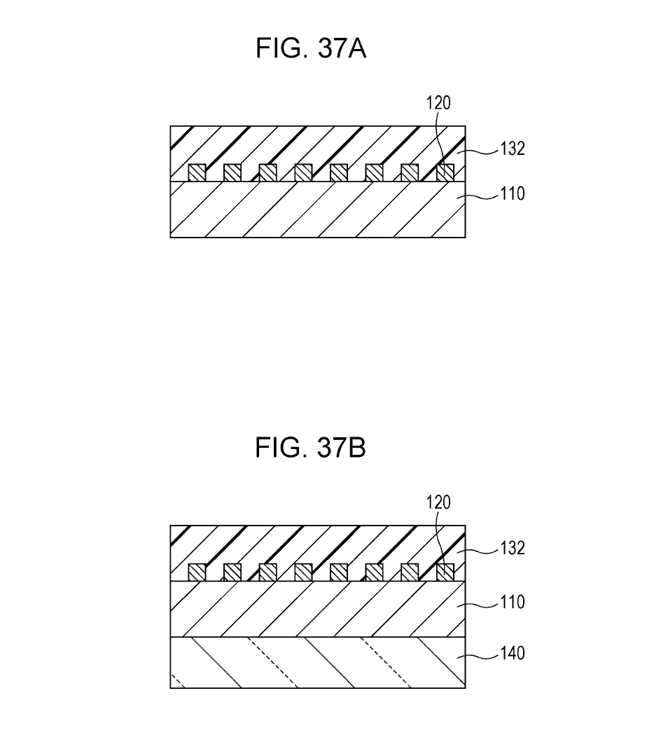

As illustrated in FIGS. 37A and 37B, a surface protective layer 132 may be formed to protect the periodic structure 120. In FIGS. 37A and 37B, the surface protective layer 132 covers the periodic structure 120 and has a flat surface opposite the photoluminescent layer 110.

The surface protective layer 132 may be formed in a light-emitting device with or without the substrate 140, as illustrated in FIGS. 37A and 37B. In the light-emitting device without the substrate as illustrated in FIG. 37A, a surface protective layer may also be formed under the photoluminescent layer 110. The surface protective layer 132 may be formed on any surface of the light-emitting devices described above. The periodic structure 120 is not limited to those illustrated in FIGS. 37A and 37B and may be of any of the types described above. For example, the periodic structure 120 may be formed of the material of the photoluminescent layer 110 (see FIG. 24). In this case, an air layer may serve as a light-transmissive layer.

The surface protective layer 132 may be formed of a resin, a hard coat material, SiO₂, alumina (Al₂O₃), silicon oxycarbide (SiOC), or diamond-like carbon (DLC). The surface protective layer 132 may have a thickness in the range of 100 nm to 10 μm.

The surface protective layer 132 can protect the light-emitting device from the external environment and suppress the degradation of the light-emitting device. The surface protective layer 132 can protect the surface of the light-emitting device from scratches, water, oxygen, acids, alkalis, or heat. The material and thickness of the surface protective layer 132 may be appropriately determined for each use.

The material of the substrate 140 sometimes deteriorates due to heat. Heat is mostly generated by the nonradiative loss or Stokes loss of the photoluminescent layer 110. For example, the thermal conductivity of quartz (1.6 W/m·K) is lower by an order of magnitude than the thermal conductivity of YAG (11.4 W/m·K). Thus, heat generated by the photoluminescent layer (for example, a YAG layer) 110 is not fully dissipated via the substrate (for example, a quartz substrate) 140 and increases the temperature of the photoluminescent layer 110, thereby possibly causing thermal degradation.

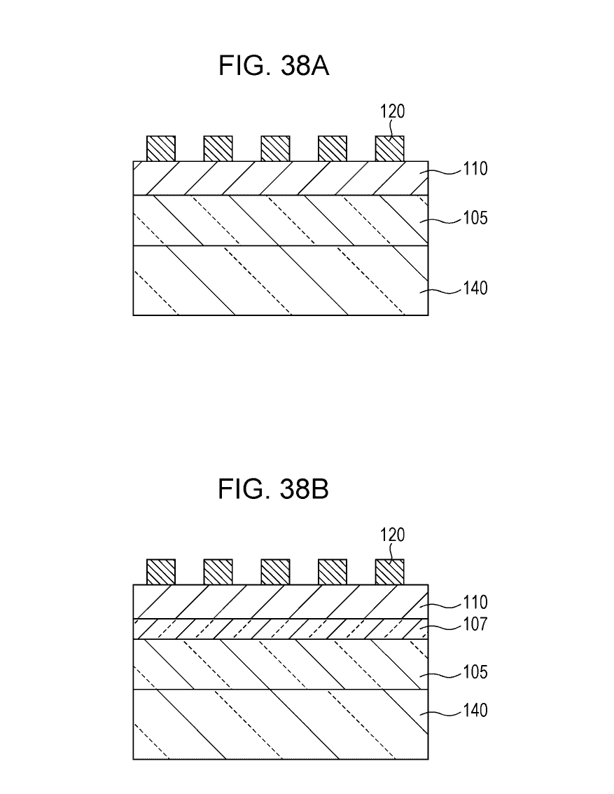

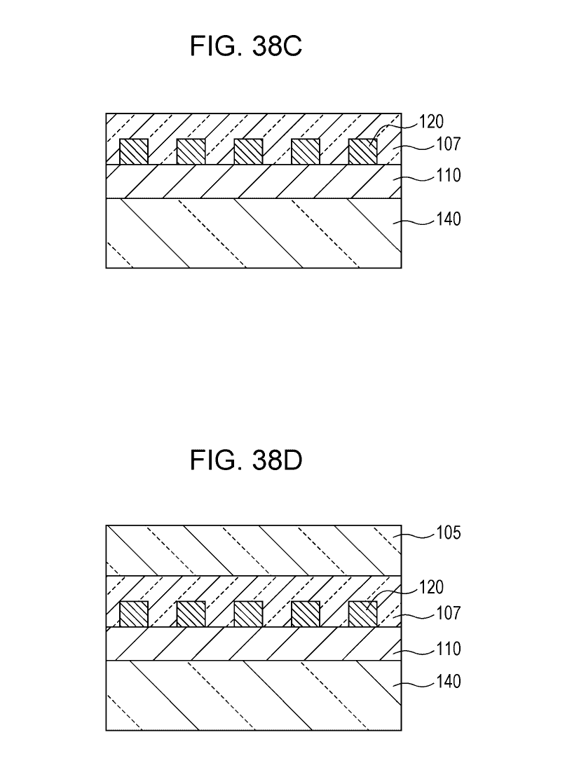

As illustrated in FIG. 38A, a transparent thermally conductive layer 105 between the photoluminescent layer 110 and the substrate 140 can efficiently dissipate heat of the photoluminescent layer 110 and prevent temperature rise. It is desirable that the transparent thermally conductive layer 105 have a lower refractive index than the photoluminescent layer 110. If the substrate 140 has a lower refractive index than the photoluminescent layer 110, the transparent thermally conductive layer 105 may have a higher refractive index than the photoluminescent layer 110. In such a case, the transparent thermally conductive layer 105, together with the photoluminescent layer 110, forms a waveguide layer, and therefore advantageously has a thickness of 50 nm or less. When the material of the substrate 140 is a soda-lime glass, the material of the transparent thermally conductive layer 105 can be selected with the refractive index of the substrate 140 taken into account. As illustrated in FIG. 38B, in the presence of a low-refractive-index layer 107 between the photoluminescent layer 110 and the transparent thermally conductive layer 105, a thick transparent thermally conductive layer 105 may be used.

As illustrated in FIG. 38C, the periodic structure 120 may be covered with a low-refractive-index layer 107 having high thermal conductivity. As illustrated in FIG. 38D, a transparent thermally conductive layer 105 may be formed on the low-refractive-index layer 107 covering the periodic structure 120. In this case, the low-refractive-index layer 107 does not necessarily have high thermal conductivity.

The material of the transparent thermally conductive layer 105 may be Al₂O₃, MgO, Si₃N₄, ZnO, AlN, Y₂O₃, diamond, graphene, CaF₂, or BaF₂. Among these, CaF₂ and BaF₂ can be used for the low-refractive-index layer 107 due to their low refractive indices.

### 11. OTHER EMBODIMENTS OF LIGHT-EMITTING DEVICE

### 11-1. Increase in Amount of Light to be Emitted

As described above, a narrow-angle light distribution can be achieved without an optical element, such as a reflector or lens. For example, in accordance with at least one of the embodiments, the directional angle of light of a particular wavelength emitted in the front direction can be decreased to approximately 15 degrees. The embodiments are particularly useful for optical devices that require a relatively small directional angle. Optical devices are also used in applications that do not require high directionality, such as lighting fixtures for general illumination and vehicle headlights and taillights. In such applications, it is advantageous to emit brighter light from light-emitting devices.

In a light-emitting device according to the present disclosure, high directionality of light of a particular wavelength is probably achieved by forming a quasi-guided mode in a photoluminescent layer and by extracting light in the quasi-guided mode from the light-emitting device utilizing an interaction between the quasi-guided mode and a periodic structure. Thus, the emission rate of light in the quasi-guided mode can be improved to increase the amount of light emitted from the light-emitting device.

As illustrated in FIGS. 8 to 11, the emission rate of light in a quasi-guided mode depends on the refractive index of the material of a periodic structure and the height of the periodic structure. As illustrated in FIGS. 8 and 9, an increased refractive index of a periodic structure is less effective in confining light (resulting in a low Q value). Thus, an increased refractive index of a periodic structure can result in an increased amount of light emitted from the light-emitting device. Likewise, an increased height of a periodic structure can also result in an increased emission rate of light in a quasi-guided mode emitted from the light-emitting device. Furthermore, it is advantageous to decrease the proportion of higher-order light emitted from the light-emitting device.

11-2. Relationship between Cross-Section of Surface Profile and Directionality

The present inventors have found that the proportion of higher-order light emitted from a light-emitting device can be estimated from a higher-order term in a Fourier series representing a cross-section of a periodic structure. A study of the present inventors shows that the order of light of a particular wavelength emitted from a light-emitting device is related to the order of a frequency component in a Fourier series expansion of a cross-section of a periodic structure. More specifically, if a Fourier series expansion of a cross-section of a periodic structure includes a higher-order frequency component, the light-emitting device emits higher-order light depending on the number of terms of the Fourier series.

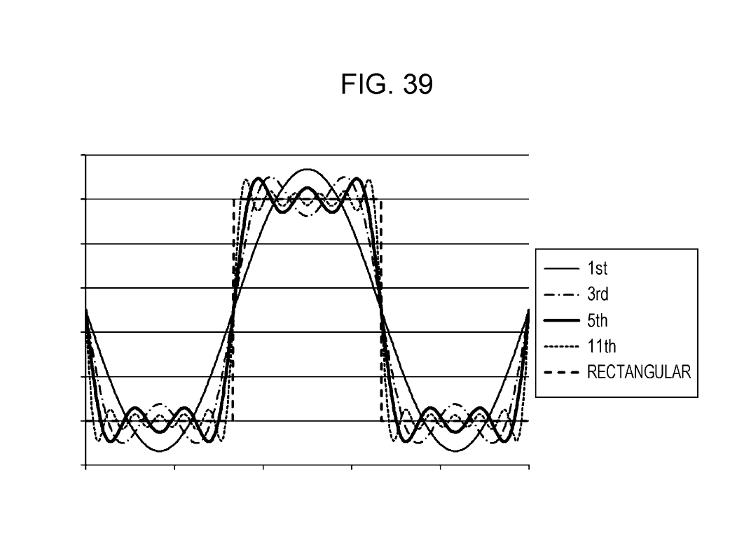

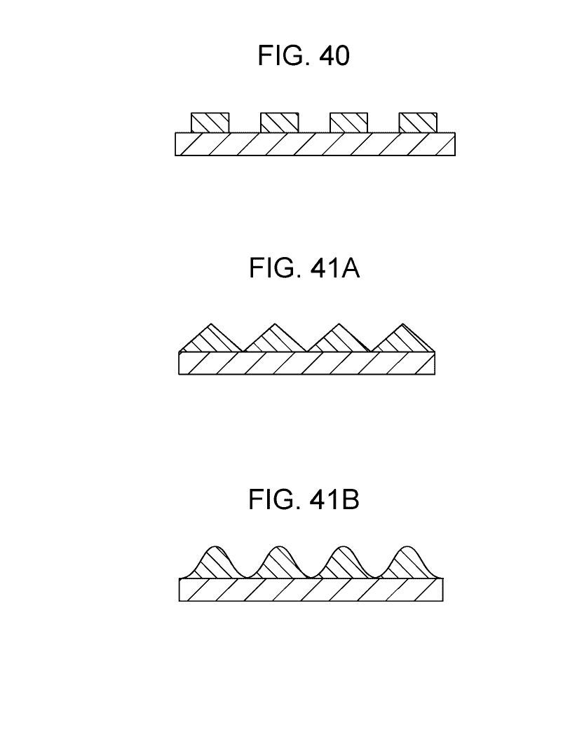

FIG. 39 is a graph showing the calculation results of a trigonometric series including only a first-order term (a sine wave) or including up to third-, fifth-, or 11th-order terms. FIG. 39 also shows a rectangular wave. The line of the trigonometric series approaches the rectangular wave as the number of high-frequency components increases. Thus, as illustrated in FIG. 40, a light-emitting device having a periodic structure including projections (or recesses) having a rectangular cross-section emits many higher-order light beams of different orders. Thus, the proportion of first-order light emitted from such a light-emitting device is relatively low.

A smaller number of higher-order terms in a Fourier series expansion of a cross-section of a periodic structure is advantageous in increasing the proportion of first-order light. In order to increase the proportion of first-order light, a periodic structure including projections having a triangular cross-section (FIG. 41A), which has a smaller number of higher-order terms in a Fourier series expansion, has an advantage over a periodic structure including projections having a rectangular cross-section (FIG. 40). A sine wave is composed only of a first-order frequency component (see FIG. 39). Thus, the proportion of first-order light emitted in a particular direction can be increased as a cross-section of a periodic structure approaches the sine wave (FIG. 41B).

### 11-3. Light-Emitting Device

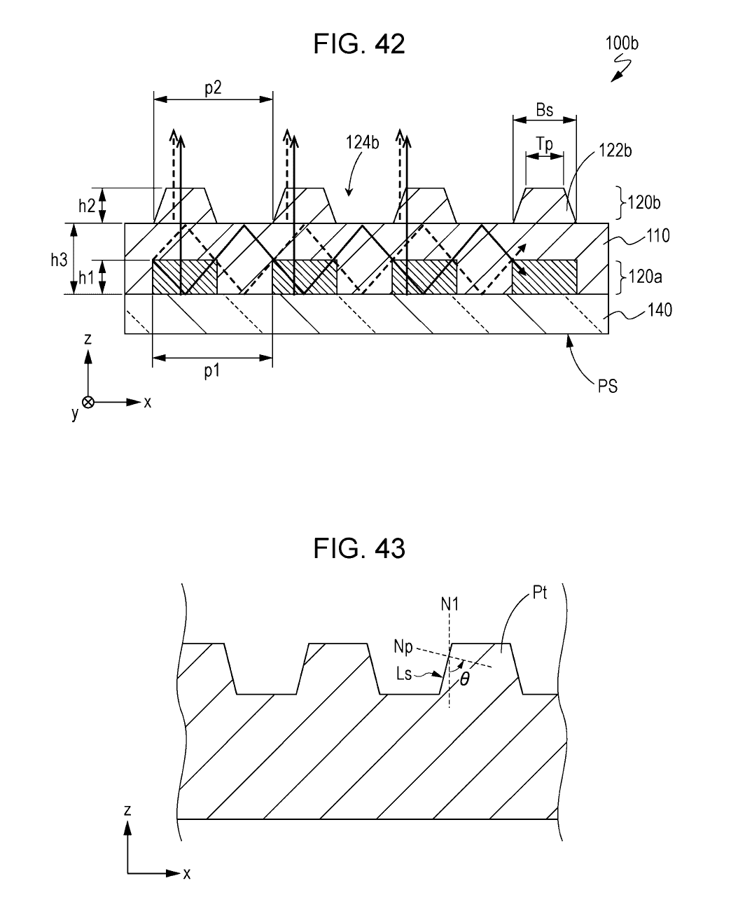

FIG. 42 is a schematic cross-sectional view of a light-emitting device according to another embodiment of the present disclosure. A light-emitting device 100b illustrated in FIG. 42 includes a substrate 140 and a photoluminescent layer 110 supported by the substrate 140. In FIG. 42, the photoluminescent layer 110 has a periodic structure 120b opposite the substrate 140. As in the structure illustrated in FIG. 19A, the substrate 140 has a periodic structure 120a facing the photoluminescent layer 110. The periodic structure 120a and the periodic structure 120b limit the directional angle of light of a particular wavelength emitted from the photoluminescent layer 110.

The substrate 140 is generally planar. The substrate 140 typically has a flat main surface PS opposite the photoluminescent layer 110 and parallel to the xy plane. The substrate 140 and the photoluminescent layer 110 are stacked in the z direction. FIG. 42 schematically illustrates a cross-section (a vertical cross-section) of the light-emitting device 100b perpendicular to the photoluminescent layer 110 and parallel to the array direction of projections of the periodic structure 120b.

The periodic structure 120b on the photoluminescent layer 110 has projections. The projections of the periodic structure 120b include at least one projection having a base wider than its top in the vertical cross-section. The periodic structure 120b may locally include at least one projection having a base wider than its top in the cross-section. Two or more of the projections may have a base wider than its top.

In the figure, four projections arranged in the x direction have a trapezoidal cross-section. For example, the rightmost projection 122b has a base width Bs greater than a top width Tp.

At least one projection having a base wider than its top in the vertical cross-section of the periodic structure 120b can reduce a sudden change in height in the array direction. Thus, at least one projection having a base wider than its top in the vertical cross-section of the periodic structure 120b can make the cross-section of the periodic structure 120b closer to the sine wave and thereby increase the proportion of first-order light emitted in a particular direction.

As illustrated in the figure, the projection 122b may have an inclined side surface with respect to a direction perpendicular to the photoluminescent layer 110 (parallel to the z direction). In other words, the periodic structure 120b may have at least one projection, the area of a section of which parallel to the photoluminescent layer 110 (the xy plane) increases as the section approaches the substrate 140. The area of a section of the projection 122b parallel to the photoluminescent layer 110 is largest when the section is closest to the photoluminescent layer 110. The area of a section of a projection parallel to the photoluminescent layer 110 may increase monotonously from the top to the base or may increase at a portion between the top and the base.

When the periodic structure 120b has recesses, at least one of the recesses has an opening wider than its bottom in the vertical cross-section. The periodic structure 120b may locally have at least one recess having such a cross-section, or two or more of the recesses may have an opening wider than their bottoms. In FIG. 42, if the periodic structure 120b is interpreted to include a recess 124b, the recess 124b has an inclined side surface with respect to a direction perpendicular to the photoluminescent layer 110. It can also be said that the opening area of the recess 124b in a section of the periodic structure 120b parallel to the photoluminescent layer 110 decreases as the section approaches the substrate 140. The opening area of the recess 124b in a section of the periodic structure 120b parallel to the photoluminescent layer 110 is smallest when the section is closest to the substrate 140. At least one recess having an opening wider than its bottom in the vertical cross-section of the periodic structure 120b has substantially the same effects as at least one projection having a base wider than its top in the vertical cross-section of the periodic structure 120b. The periodic structure 120b may be formed of the material of the photoluminescent layer 110 or another material.

As described above, the periodic structure 120a is formed on the substrate 140. The periodic structure 120a has projections. The periodic structure 120a may be formed of the material of the substrate 140 or another material. The photoluminescent layer 110 covers these projections on the substrate 140. In FIG. 42, the projections of the periodic structure 120b on the photoluminescent layer 110 are located above the corresponding projections of the periodic structure 120a located on the substrate 140.

In FIG. 42, the substrate 140 is typically transparent and can function as a light-transmissive layer located on or near the photoluminescent layer 110. In this embodiment, the substrate 140 serving as a light-transmissive layer is in contact with the photoluminescent layer 110, and the periodic structure 120a is located at the boundary between the light-transmissive layer and the photoluminescent layer 110. Since the periodic structure 120b is formed on the photoluminescent layer 110, it can also be said that the light-emitting device 100b includes another light-transmissive layer on the photoluminescent layer 110 opposite the substrate 140.

As illustrated in FIGS. 35A to 35D, FIGS. 36A to 36C, and FIGS. 38A and 38B, an intermediate layer, such as a diffusion-barrier layer 108, a low-refractive-index layer 107, a crystal growth layer 106, and/or a transparent thermally conductive layer 105, may be located between the photoluminescent layer 110 and the substrate 140. In such a case, the periodic structure 120a is located at the boundary between a light-transmissive layer and the photoluminescent layer 110. If the intermediate layer has a higher refractive index than the photoluminescent layer, n_{wav} may be the average of the refractive indices of the intermediate layer and the photoluminescent layer weighted by their respective volume fractions. If the intermediate layer has a lower refractive index than the photoluminescent layer, the intermediate layer negligibly affects the guided mode, and therefore the refractive index of the intermediate layer can be ignored.

In FIG. 42, thick solid arrows indicate light emitted from the light-emitting device 100b due to an interaction with the periodic structure 120a on the substrate 140, and thick broken arrows indicate light emitted from the light-emitting device 100b due to an interaction with the periodic structure 120b on the photoluminescent layer 110. In this embodiment, the periodic structure 120a is located on a surface of the light-transmissive layer (the substrate 140) facing the photoluminescent layer 110, and the periodic structure 120b is located on a surface of the photoluminescent layer 110 opposite the light-transmissive layer. In such a structure, as schematically illustrated in FIG. 42, the traveling direction of light is changed to a particular direction by the interaction with the periodic structures 120a and 120b before emission from the light-emitting device 100b. In other words, such a structure practically has the same effect as an increased height or refractive index of the periodic structure 120a or 120b. The periodic structures located on a surface of the light-transmissive layer facing the photoluminescent layer 110 and on a surface of the photoluminescent layer 110 opposite the light-transmissive layer can increase the amount of light emitted from the light-emitting device 100b as a whole. Thus, such a light-emitting device can find wider applications.

The period p1 of the periodic structure 120a (equal to the center-to-center distance between two adjacent projections) may be the same as or different from the period p2 of the periodic structure 120b (equal to the center-to-center distance between two adjacent projections). The period p1 equal to the period p2 can result in a high emission intensity at a particular wavelength, and the period p1 different from the period p2 can result in a broader spectrum. The periods p1 and p2 can be determined using the formula (15).

The periodic structure 120a on the substrate 140 serving as a light-transmissive layer and the periodic structure 120b on the photoluminescent layer 110, in combination with the cross-section of the periodic structure 120b on the photoluminescent layer 110, produce a synergistic effect. This can more enhance light of a particular wavelength emitted in a particular direction. It goes without saying that methods for increasing the height or refractive index of the periodic structure 120a and/or the height or refractive index of the periodic structure 120b may be combined.

The “inclination angle” of side surfaces are defined for projections or recesses of a periodic structure. FIG. 43 is a schematic view of part of a vertical cross-section of a periodic structure having projections Pt. The angle θ between an axis N1 perpendicular to the photoluminescent layer 110 and a normal line Np of each side surface Ls of projections Pt in a region of selected out of the projections Pt of the periodic structure is determined (0≦θ≦90 degrees). The arithmetic mean of the angles θ is defined as the “inclination angle” of the side surfaces. It should be noted that θ is an angle measured from the axis N1 toward the normal line Np. If a side surface Ls is composed of a plurality of planes, for example, if a side surface Ls has a stepped cross-section, the angles θ of the planes are averaged. The angle θ can be measured by fitting in a cross-sectional image of a light-emitting device.

If an outline of a side surface Ls in the vertical cross-section includes a curved portion, the angle θ of the curved portion is determined by averaging the angles θ measured from the starting point to the end point of the curved portion. If a periodic structure includes recesses, the “inclination angle” is defined in the same manner as in a periodic structure including projections.

In FIG. 42, four projections on the photoluminescent layer 110 arranged in the x direction have a trapezoidal cross-section, and four projections on the substrate 140 arranged in the x direction have a rectangular cross-section. The inclination angle of each side surface of the projections of the periodic structure 120b on the photoluminescent layer 110 is smaller than the inclination angle (90 degrees) of each side surface of the projections of the periodic structure 120a located on the substrate 140. If each of the periodic structure 120b and the periodic structure 120a includes recesses, the inclination angle of each side surface of the recesses of the periodic structure 120b may be smaller than the inclination angle of each side surface of the recesses of the periodic structure 120a.

11-4. Relationship between Inclination Angle of Side Surface and Light Enhancement

The present inventors have performed optical analysis using DiffractMOD available from Cybernet Systems Co., Ltd. and have examined the influence of the cross-section of a periodic structure on light enhancement. In the same manner as the calculation illustrated in FIG. 2, the change in the absorption of external light incident perpendicular to a light-emitting device by a photoluminescent layer was calculated to determine an enhancement of light emitted perpendicularly to the light-emitting device. A cross-section illustrated in FIG. 43 was used for the calculation.

In the following calculation, the projections of the periodic structure 120b on the photoluminescent layer 110 were assumed to have the same (trapezoidal) cross-section. The projections of the periodic structure 120a on the substrate 140 were also assumed to have the same (rectangular) cross-section. Thus, the calculation model is a one-dimensional periodic structure uniform in the y direction.

In the following calculation, the substrate 140 had a refractive index of 1.5, and the photoluminescent layer 110 had a refractive index of 1.8. In the calculation, the material of the periodic structure 120b was the same as the material of the photoluminescent layer 110, and the material of the periodic structure 120a was the same as the material of the substrate 140. The distance h3 between the base of the projections of the periodic structure 120a and the base of the projections of the periodic structure 120b was 240 nm, and the height h1 of the projections of the periodic structure 120a and the height h2 of the projections of the periodic structure 120b were 100 nm. The period p1 of the periodic structure 120a and the period p2 of the periodic structure 120b were 400 nm.

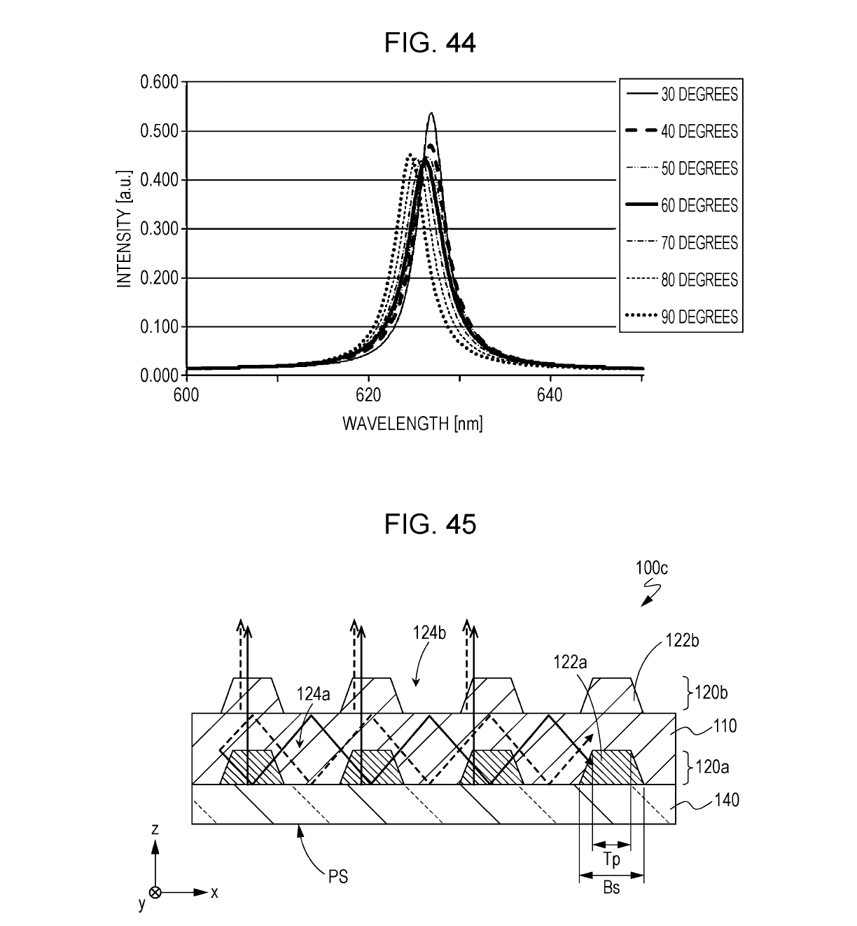

FIG. 44 shows the calculation results of enhancement of light emitted in the front direction for different inclination angles of each side surface of projections of the periodic structure 120b. The calculation was performed for polarization in the TM mode, which has an electric field component parallel to the y direction. When the inclination angle of each side surface of the projections was changed, the top and base areas were adjusted such that each of the projections in a vertical cross-section had a constant area.

FIG. 44 shows that the inclination angle of each side surface of the projections on the photoluminescent layer 110 can be decreased to approximately 40 degrees to improve the light enhancement effect at a particular wavelength. This is probably because the cross-section of the periodic structure approached the sine wave, and thereby the proportion of first-order light emitted in a particular direction was increased. Thus, the light enhancement effect can be improved at a particular wavelength, for example, by making the inclination angle of each side surface of the projections of the periodic structure 120b smaller than the inclination angle of each side surface of the projections of the periodic structure 120a.

### 11-5. Modified Example of Light-Emitting Device

FIG. 45 illustrates another example of a light-emitting device that includes a periodic structure including projections having inclined side surfaces on a photoluminescent layer 110. A light-emitting device 100c illustrated in FIG. 45 differs from the light-emitting device 100b illustrated in FIG. 42 in that the periodic structure 120a located on the substrate 140 in the light-emitting device 100c has projections having inclined side surfaces.

In the periodic structure 120a illustrated in FIG. 45, four projections arranged in the x direction have a trapezoidal cross-section. For example, the rightmost projection 122a has a base width Bs greater than its top width Tp, as in the corresponding projection 122b. Likewise, the periodic structure 120a on the substrate 140 may have at least one projection having a base wider than its top. Each side surface of the projection 122a is inclined with respect to a direction perpendicular to the photoluminescent layer 110.

It can also be understood that the periodic structure 120a on the substrate 140 has recesses. In this case, for example, a recess 124a of the periodic structure 120a has an opening wider than its bottom in a vertical cross-section. The periodic structure 120a may have at least one recess having such a cross-section. Each side surface of the recess 124a is inclined with respect to a direction perpendicular to the photoluminescent layer 110, and the opening area of the recess 124a in a section of the periodic structure 120a parallel to the photoluminescent layer 110 decreases as the section becomes more distant from the periodic structure 120b. The opening area of the recess 124a in a section of the periodic structure 120b parallel to the photoluminescent layer 110 is smallest when the section is closest to the substrate 140.

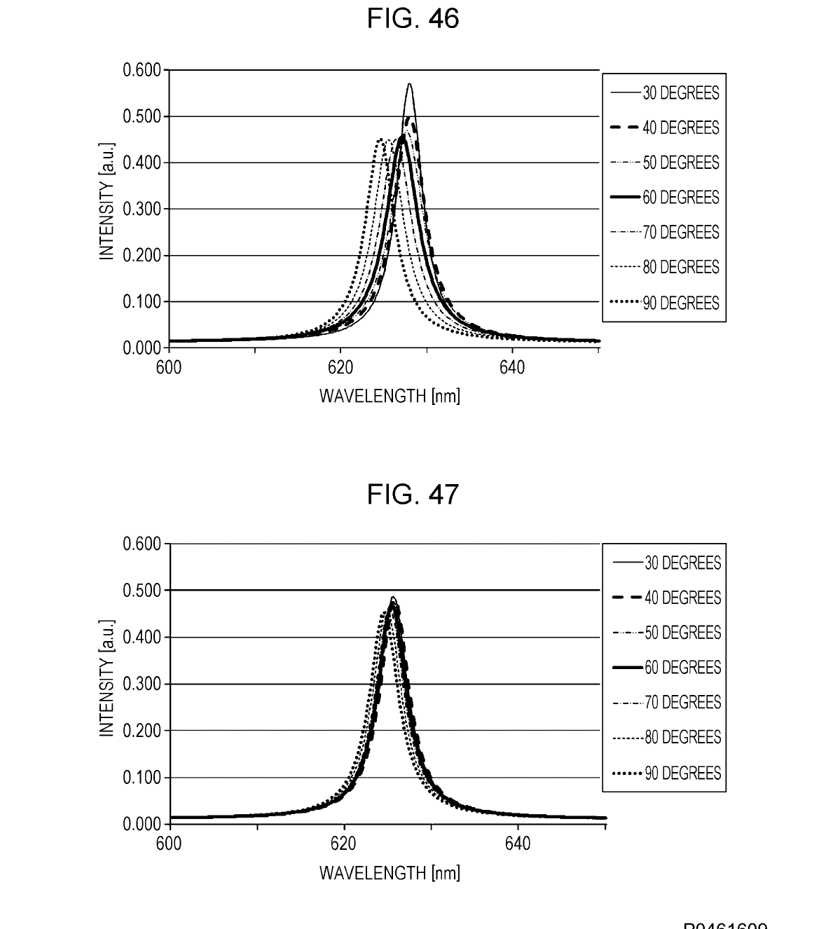

FIG. 46 shows the calculation results of enhancement of light emitted in the front direction for different inclination angles of each side surface of the projections of the periodic structure 120b located on the photoluminescent layer 110 and of the periodic structure 120a located on the substrate 140. On the assumption that each projection of the periodic structure 120b on the photoluminescent layer 110 has the same (trapezoidal) cross-section as each projection of the periodic structure 120a on the substrate 140, the calculation was performed by the optical analysis in the same manner as illustrated in FIG. 44. FIG. 46 shows that the inclination angle of each side surface of the projections can be decreased to approximately 40 degrees to improve the light enhancement effect at a particular wavelength.

FIG. 47 shows the calculation results for the case that each projection of the periodic structure 120b on the photoluminescent layer 110 has a rectangular cross-section and each projection of the periodic structure 120a on the substrate 140 has a trapezoidal cross-section. FIG. 47 shows that enhancement of light of a particular wavelength tends to increase with decreasing inclination angle of each side surface of the projections of the periodic structure 120a located on the substrate 140 with respect to a direction perpendicular to the photoluminescent layer 110.

### 11-6. Other Exemplary Cross-Sections in Periodic Structure

Each projection of the periodic structure 120a and the periodic structure 120b may also have any cross-section other than rectangular and trapezoidal.

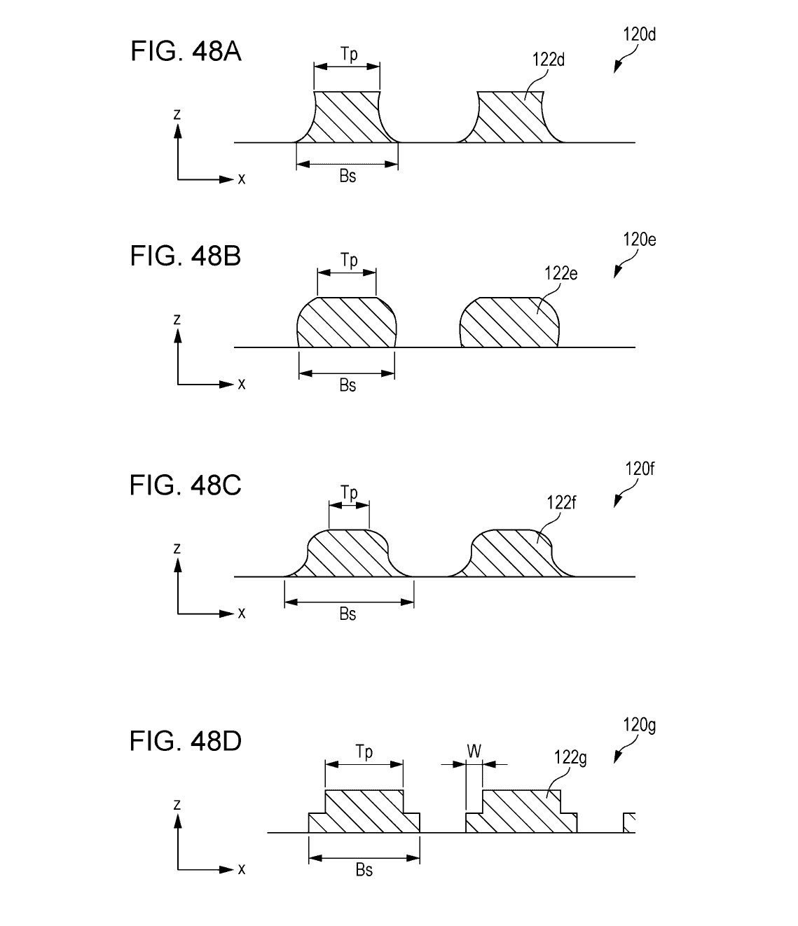

FIGS. 48A to 48D illustrate other cross-sections of periodic structures. The periodic structure 120d illustrated in FIG. 48A, the periodic structure 120e illustrated in FIG. 48B, and the periodic structure 120f illustrated in FIG. 48C have projections 122d, projections 122e, and projections 122f, respectively. In FIG. 48A, each side surface of the projections 122d has a curved portion near the bases of the projections 122d. In FIG. 48B, each side surface of the projections 122e has a curved portion near the tops of the projections 122e. In FIG. 48C, each side surface of the projections 122f has a curved portion near the tops and bases of the projections 122f. Likewise, a vertical cross-section of each projection (or recess) of a periodic structure may have a curved portion. If at least part of each side surface of the projections (or recesses) of the periodic structure 120b on the photoluminescent layer 110 and/or at least part of each side surface of the projections (or recesses) of the periodic structure 120a on the substrate 140 is inclined with respect to a direction perpendicular to the photoluminescent layer 110, the proportion of higher-order light in light of a particular wavelength emitted in a particular direction can be reduced. In the projections 122d, projections 122e, and projections 122f, the base width Bs is greater than the top width Tp.

A periodic structure 120g illustrated in FIG. 48D have projections 122g. Each vertical cross-section of the projections 122g has stepped side surfaces. Likewise, each side surface of the projections (or recesses) of the periodic structure 120a and/or each side surface of the projections (or recesses) of the periodic structure 120b may have a stepped portion. Although the right side surface and the left side surface of each projection are symmetrical in these embodiments, the projections may have different cross-sections. The left and right side surfaces of each projection may have different shapes.

In illustrated in FIG. 48D, each of the projections 122g appears to include two stacked projections each having a rectangular cross-section. The height of such a cross-section changes suddenly in the array direction. However, a large positional discrepancy w between the two rectangles in the array direction produces an effect similar to the effect of a side surface having a small inclination angle. Thus, the proportion of higher-order light in light of a particular wavelength emitted in a particular direction from the light-emitting device can be reduced. The stepped side surface may have any number of steps. A larger number of steps of the stepped side surface makes a cross-section of the projection closer to a triangular cross-section and can reduce the proportion of higher-order light.

### 11-7. Method for Controlling Cross-Section of Surface Structure

As described above, the periodic structure 120a can be formed on the substrate 140 by a semiconductor manufacturing process or nanoimprinting. A fluorescent material film can then be formed on the substrate 140, for example, by sputtering to form the photoluminescent layer 110 and the periodic structure 120b, which has projections (or recesses) corresponding to projections (or recesses) of the periodic structure 120a.

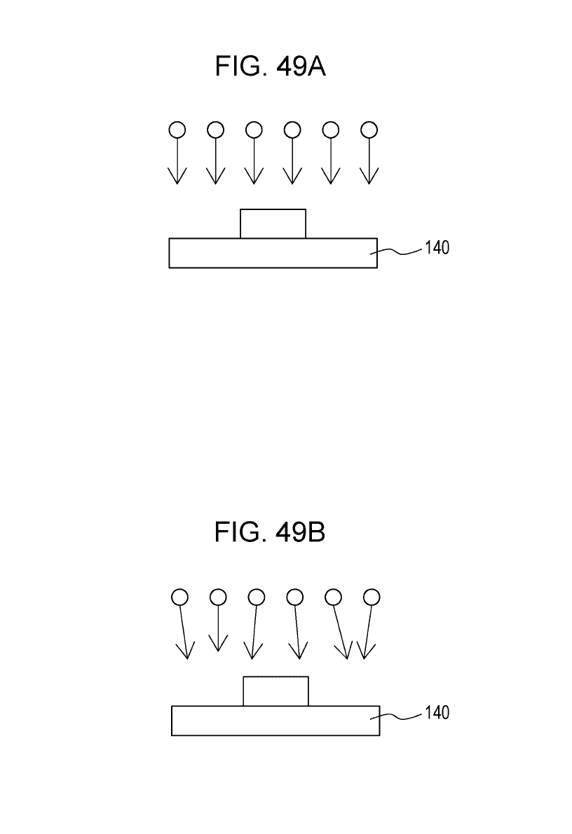

The cross-section of each projection (or recess) of the periodic structure 120b can be controlled by adjusting the pressure of the atmosphere gas (for example, argon gas) for sputtering in the formation of the periodic structure 120b. At a relatively low sputtering pressure, ballistic transport is dominant, and material particles emitted from a target collide almost perpendicularly with the substrate 140, as schematically illustrated in FIG. 49A. Thus, a cross-section of each projection of the periodic structure 120a on the substrate 140 is easily reflected in a cross-section of each projection of the periodic structure 120b. Furthermore, molecules of the atmosphere gas tend to act in the same manner as in dry etching, thus resulting in a sharper edge. In contrast, at a relatively high sputtering pressure, diffusive transport is dominant, and the proportion of material particles colliding obliquely with the substrate 140 increases, as schematically illustrated in FIG. 49B. This tends to result in a smoother surface.

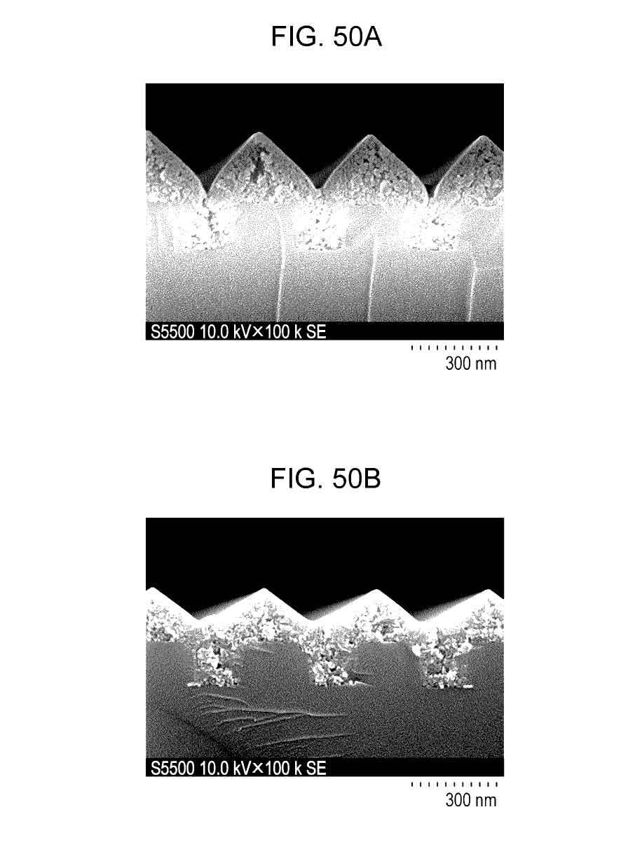

FIGS. 50A and 50B are vertical cross-sectional images of a sample produced by depositing YAG:Ce by sputtering on a quartz substrate having a periodic structure (period: 400 nm) including projections having a rectangular cross-section and having a height of 170 nm. FIGS. 50A and 50B show cross-sections of a sample deposited at an atmosphere gas pressure of 0.3 and 0.5 Pa, respectively. In the samples in FIGS. 50A and 50B, the deposition was performed while the quartz substrate was placed directly under an erosion region of a target (an area of the target from which material particles are sputtered).

The size relationship between the top width of each projection (or the opening width of each recess) of the periodic structure 120a located on the substrate 140 and the base width of each projection (or the bottom width of each recess) of the periodic structure 120b located on the photoluminescent layer 110 can be controlled by adjusting the height of each projection (or the depth of each recess) of the periodic structure 120a.

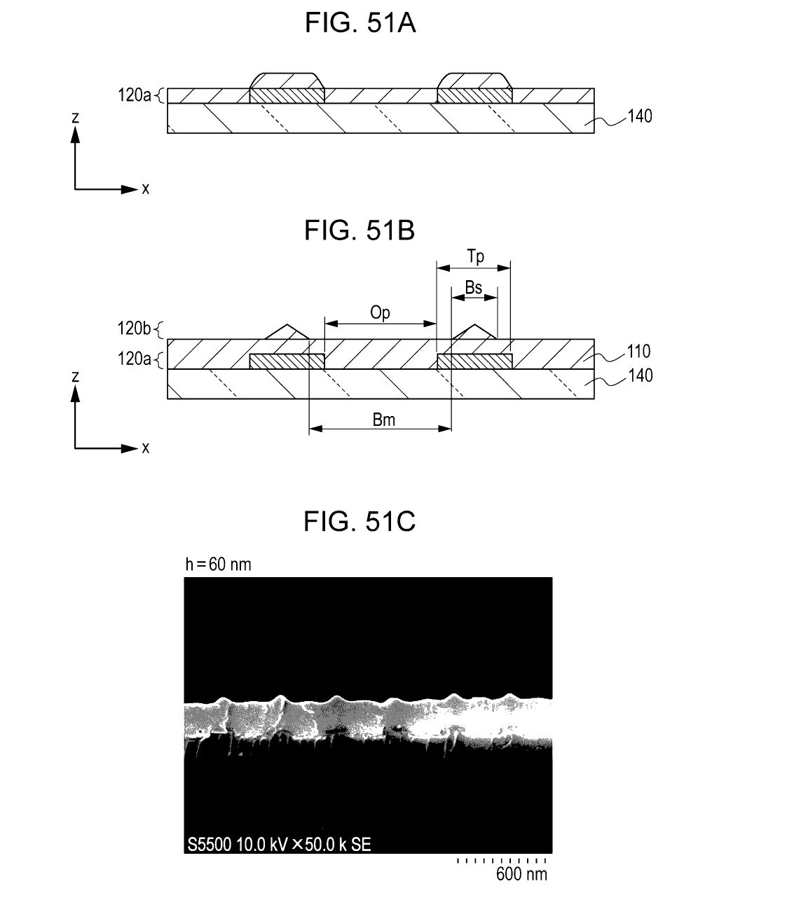

FIGS. 51A and 51B schematically illustrate a cross-section of a photoluminescent material film on a substrate 140 having a periodic structure 120a including relatively low projections. In FIG. 51B, a photoluminescent material is further deposited on the structure illustrated in FIG. 51A. In FIG. 51B, a projection of the periodic structure 120a and a corresponding projection of the periodic structure 120b are focused on. If the projection of the periodic structure 120a has a relatively small height, the base width Bs of the projection of the periodic structure 120b tends to be smaller than the top width Tp of the projection of the periodic structure 120a. If the periodic structure 120a has a recess between two adjacent projections, and the periodic structure 120b has a corresponding recess between two adjacent projections, the bottom width Bm of the recess of the periodic structure 120b is greater than the opening width Op of the recess of the periodic structure 120a.

FIG. 51C is a vertical cross-sectional image of a sample produced by depositing YAG:Ce by sputtering on a quartz substrate having a periodic structure (period: 400 nm) including projections having a rectangular cross-section and having a height of 60 nm. The atmosphere gas pressure for sputtering was 0.5 Pa, and the quartz substrate was placed directly under an erosion region of a target.

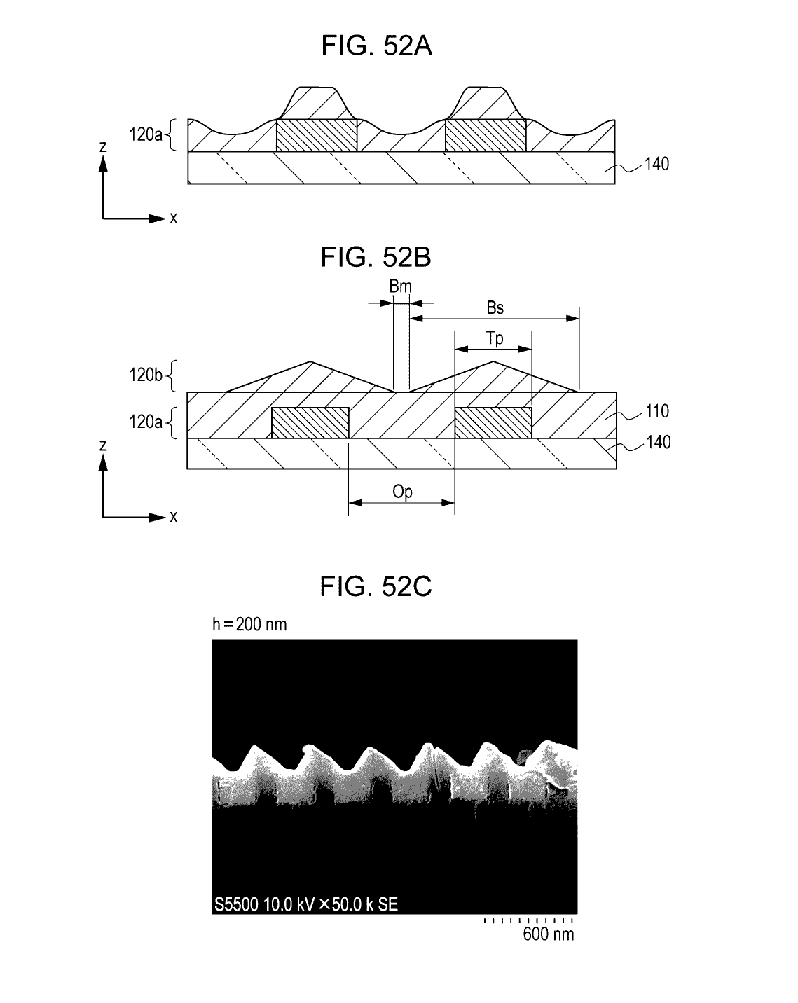

FIGS. 52A and 52B schematically illustrate a cross-section of a photoluminescent material film on a substrate 140 having a periodic structure 120a including relatively high projections. In FIG. 52B, a photoluminescent material is further deposited on the structure illustrated in FIG. 52A. In FIG. 52B, a projection of the periodic structure 120a and a corresponding projection of the periodic structure 120b are focused on. If the projection of the periodic structure 120a has a relatively large height, the base width Bs of the projection of the periodic structure 120b tends to be greater than the top width Tp of the projection of the periodic structure 120a. If the periodic structure 120a has a recess between two adjacent projections, and the periodic structure 120b has a corresponding recess between two adjacent projections, the bottom width Bm of the recess of the periodic structure 120b is smaller than the opening width Op of the recess of the periodic structure 120a.

FIG. 52C is a vertical cross-sectional image of a sample produced by depositing YAG:Ce by sputtering on a quartz substrate having a periodic structure (period: 400 nm) including projections having a rectangular cross-section and having a height of 200 nm. The atmosphere gas pressure for sputtering was 0.5 Pa. The quartz substrate was slightly separated from a place directly under an erosion region of a target during deposition. Thus, the position of the center of gravity of each lower projection (each projection on the quartz substrate) is slightly different in the array direction from the position of the center of gravity of each upper projection (each projection on the YAG layer).

11-8. Difference in Position between Periodic Structure 120a and Periodic Structure 120b

In FIGS. 42 and 45, each projection of the periodic structure 120b is located directly above each projection of the periodic structure 120a. However, as illustrated in FIG. 52C, the center of each projection (or recess) on the substrate 140 does not necessarily coincide with the center of each corresponding projection (or recess) on the photoluminescent layer 110. As described below, when there is a difference in position in the array direction between the periodic structure 120a on the substrate 140 and the periodic structure 120b on the photoluminescent layer 110, the light enhancement effect may be increased.

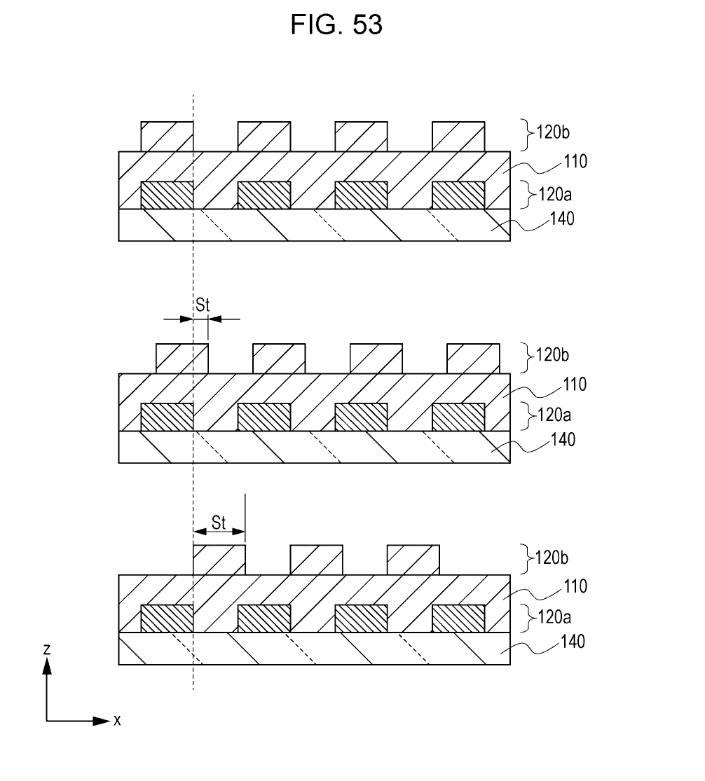

The present inventors have examined by optical analysis how the difference in position in the array direction between the periodic structure 120a on the substrate 140 and the periodic structure 120b on the photoluminescent layer 110 influences light enhancement. DiffractMOD available from Cybernet Systems Co., Ltd. was used for the optical analysis. The calculation model as illustrated in FIG. 44 was used. More specifically, the calculation model included a one-dimensional periodic structure uniform in the y direction on the substrate 140 and on the photoluminescent layer 110. In the calculation model, each projection of the periodic structure 120a and the periodic structure 120b had a rectangular cross-section (the inclination angle of side surfaces was 90 degrees), as illustrated in FIG. 53.

FIG. 53 is a schematic cross-sectional view illustrates the difference in position between the periodic structure 120a and the periodic structure 120b. The difference in position between periodic structures can be represented by the positional discrepancy in the array direction relative to the period of the periodic structures. For example, as illustrated in the figure, the positional discrepancy in the array direction is defined by the distance St in the array direction between the right end of a base of a projection of the periodic structure 120a and the right end of a base of a corresponding projection of the periodic structure 120b. In FIG. 53, the difference in position St is zero in the upper figure and 50% of the period in the lower figure. In the present specification, when the positional discrepancy in the array direction between a projection (or recess) of the periodic structure 120a and a projection (or recess) of the periodic structure 120b is less than 50% of the period, one of the projections “corresponds” to the other.

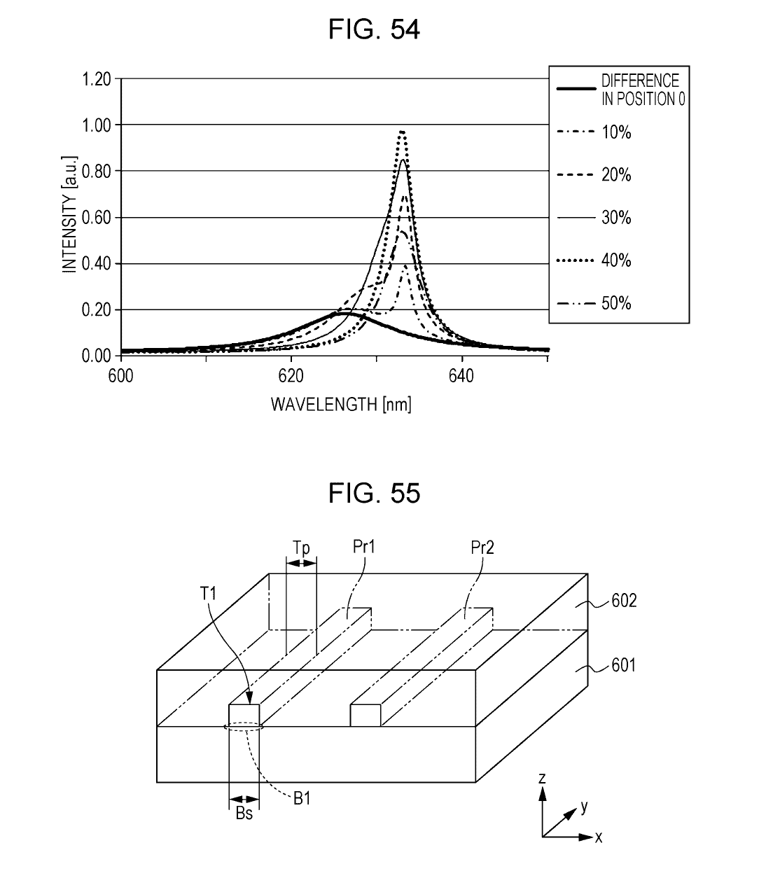

FIG. 54 shows the calculation results of enhancement of light emitted in the front direction for various differences in position between the periodic structure 120a and the periodic structure 120b. FIG. 54 shows that the light emission peak increases with increasing difference in position. However, the peak height is lower when the difference in position is 50% of the period of the periodic structures than when the difference in position is 40% of the period of the periodic structures. The light enhancement effect is significant when the difference in position is 30% or 40% of the period.

FIG. 54 shows that when the difference in position in the array direction between the periodic structure 120a on the substrate 140 and the periodic structure 120b on the photoluminescent layer 110 is 50% or less of the period, light of a particular wavelength can be more strongly enhanced. Thus, the center of each projection (or recess) of the periodic structure 120a on the substrate 140 does not necessarily coincide with the center of each corresponding projection (or recess) of the periodic structure 120b on the photoluminescent layer 110, and some difference in position between the periodic structures is allowable.

Light-emitting devices and light-emitting apparatuses according to the present disclosure can be applied to various optical devices, such as lighting fixtures, displays, and projectors.

What is claimed is:

1. A light-emitting device comprising:
a light-transmissive layer having a first surface; and
a photoluminescent layer located on the first surface, wherein the photoluminescent layer has a second surface facing the light-transmissive layer and a third surface opposite the second surface, and emits light containing first light having a wavelength X, in air from the third surface upon receiving excitation light,
the photoluminescent layer has a first surface structure located on the third surface, the first surface structure having projections arranged along a first direction,
the light-transmissive layer has a second surface structure located on the first surface, the second surface structure having projections corresponding to the projections of the first surface structure,
the first surface structure and the second surface structure limit a directional angle of the first light emitted from the third surface,
the projections of the first surface structure include a first projection, and the first projection has a base width greater than a top width in a cross-section perpendicular to the photoluminescent layer and parallel to the first direction.

2. The light-emitting device according to claim 1, wherein side surfaces of the projections of the first surface structure have a smaller inclination angle than side surfaces of the projections of the second surface structure.

3. The light-emitting device according to claim 1, wherein
the second surface structure has a second projection corresponding to the first projection, and
the first projection has a base width smaller than a top width of the second projection in the cross-section.

4. The light-emitting device according to claim 1, wherein
the second surface structure has a second projection corresponding to the first projection, and
the first projection has a base width greater than a top width of the second projection in the cross-section.

5. The light-emitting device according to claim 1, wherein
the projections of the second surface structure include a second projection corresponding to the first projection, and
the second projection has a base width greater than a top width of the second projection in the cross-section.

6. The light-emitting device according to claim 5, wherein
at least part of the side surfaces of the projections of the first surface structure are inclined with respect to a direction perpendicular to the photoluminescent layer, and
at least part of the side surfaces of the projections of the second surface structure are inclined with respect to the direction perpendicular to the photoluminescent layer.

7. The light-emitting device according to claim 5, wherein at least part of the side surfaces of the projections of the first surface structure, or at least part of the side surfaces of the projections of the second surface structure, or both are stepped.

8. The light-emitting device according to claim 1, wherein a distance D1ᵢₙₜ between two adjacent projections of the first surface structure, a distance D2ᵢₙₜ between two adjacent projections of the second surface structure, and a refractive index n_{wav-a} of the photoluminescent layer for the first light satisfy λₐ/n_{wav-a}<D1ᵢₙₜ<λₐ and λₐ/n_{wav-a}<D2ᵢₙₜ<λₐ.

9. A light-emitting device comprising:
a light-transmissive layer having a first surface; and
a photoluminescent layer located on the first surface, wherein
the photoluminescent layer has a second surface facing the light-transmissive layer and a third surface opposite the second surface, and emits light containing first light having a wavelength λₐ in air from the third surface upon receiving excitation light,
the photoluminescent layer has a first surface structure located on the third surface, the first structure having recesses arranged along a first direction,
the light-transmissive layer has a second surface structure located on the first surface and having recesses corresponding to the recesses of the first surface structure,
the first surface structure and the second surface structure limit a directional angle of the first light emitted from the third surface,
the recesses of the first surface structure include a first recess, and
the first recess has an opening width greater than a bottom width in a cross-section perpendicular to the photoluminescent layer and parallel to the first direction.

10. The light-emitting device according to claim 9, wherein side surfaces of the recesses of the first surface structure have a smaller inclination angle than side surfaces of the recesses of the second surface structure.

11. The light-emitting device according to claim 9, wherein
the second surface structure has a second recess corresponding to the first recess, and
the first recess has a bottom width smaller than an opening width of the second recess in the cross-section.

12. The light-emitting device according to claim 9, wherein
the second surface structure has a second recess corresponding to the first recess, and
the first recess has a bottom width greater than an opening width of the second recess in the cross-section.

13. The light-emitting device according to claim 9, wherein
the recesses of the second surface structure include a second recess corresponding to the first recess, and
the second recess has an opening width greater than a bottom width of the second recess in the cross-section.

14. The light-emitting device according to claim 13, wherein
at least part of the side surfaces of the recesses of the first surface structure are inclined with respect to a direction perpendicular to the photoluminescent layer, and
at least part of the side surfaces of the recesses of the second surface structure are inclined with respect to the direction perpendicular to the photoluminescent layer.

15. The light-emitting device according to claim 13, wherein at least part of the side surfaces of the recesses of the first surface structure, or at least part of the side surfaces of the recesses of the second surface structure, or both are stepped.

16. The light-emitting device according to claim 9, wherein a distance D1ᵢₙₜ between two adjacent recesses of the first surface structure, a distance D2ᵢₙₜ between two adjacent recesses of the second surface structure, and a refractive index n_{wav-a} of the photoluminescent layer for the first light satisfy λₐ/n_{wav-a}<D1ᵢₙₜ<λₐ and λₐ/n_{wav-a}<D2ᵢₙₜ<λₐ.

17. The light-emitting device according to claim 8, wherein the D1ᵢₙₜ is equal to the D2ᵢₙₜ.

18. The light-emitting device according to claim 1, wherein
the first surface structure has at least one first periodic structure,
the second surface structure has at least one second periodic structure, and
a period p1ₐ of the at least one first periodic structure, a period p2ₐ of the at least one second periodic structure, and a refractive index n_{wav-a} of the photoluminescent layer for the first light satisfy λₐ/n_{wav-a}<p1ₐ<λₐ and λₐ/n_{wav-a}<p2ₐ<λₐ.

19. The light-emitting device according to claim 1, wherein the first surface structure and the second surface structure form a quasi-guided mode in the photoluminescent layer, and
the quasi-guided mode causes the first light emitted from the third surface to have a maximum intensity in a first direction defined by the first surface structure and the second surface structure.

20. The light-emitting device according to claim 19, wherein the first light emitted in the first direction is linearly polarized light.

21. The light-emitting device according to claim 1, wherein the first surface structure and the second surface structure limit a directional angle of the first light emitted from the third surface to less than 15 degrees.

22. The light-emitting device according to claim 1, wherein the photoluminescent layer includes a phosphor.

23. The light-emitting device according to claim 1, wherein 380 nm≦λₐ≦780 nm is satisfied.

24. The light-emitting device according to claim 1, wherein the light-transmissive layer is located indirectly on the photoluminescent layer.

25. The light-emitting device according to claim 8, wherein the thickness of the photoluminescent layer, the refractive index n_{wav-a}, and the distances D1ᵢₙₜ and D2ᵢₙₜ are set to allow an electric field to be formed in the photoluminescent layer, in which antinodes of the electric field are located in areas, the areas each corresponding to respective one of the projections and/or recesses.

26. The light-emitting device according to claim 8, wherein the thickness of the photoluminescent layer, the refractive index n_{wav-a}, and the distances D1ᵢₙₜ and D2ᵢₙₜ are set to allow an electric field to be formed in the photoluminescent layer, in which antinodes of the electric field are located at, or adjacent to, at least the projections or recesses.
